(19) United States
(12) Patent Application Publication
(10) Pub. No.: US 2026/0013125 A1
(43) Pub. Date: Jan. 8, 2026

(54) THREE-DIMENSIONAL MEMORY DEVICE WITH THROUGH-STACK CONTACT VIA STRUCTURES AND METHODS FOR FORMING THE SAME

(71) Applicant: Sandisk Technologies, Inc., Milpitas, CA (US)

(72) Inventors: Ruogu Matthew ZHU, San Jose, CA (US); Koichi MATSUNO, Fremont, CA (US); Jixin YU, San Jose, CA (US); Johann ALSMEIER, San Jose, CA (US)

(21) Appl. No.: 18/763,704

(22) Filed: Jul. 3, 2024

(51) Int. Cl. H10B 43/27; H01L 23/00; H01L 25/00; H01L 25/065; H01L 25/18; H10B 80/00

(52) U.S. Cl. CPC H10B 43/27; H01L 24/08; H01L 24/80; H01L 25/0657; H01L 25/18; H01L 25/50; H10B 80/00; H01L 2224/08145; H01L 2224/80895; H01L 2224/80896; H01L 2924/1431; H01L 2924/14511

(57) ABSTRACT

A device structure includes at least one alternating stack of respective layers and electrically conductive layers, a memory opening vertically extending through each layer within the at least one alternating stack, a memory opening fill structure located in the memory opening, and a contact via structure in contact with a first electrically conductive layer of the electrically conductive layers. An outer blocking dielectric layer contacts the first electrically conductive layer, laterally surrounds the contact via structure, and vertically extends continuously through the alternating stack and the at least one retro-stepped dielectric material portion.

### FIELD

The present disclosure relates generally to the field of semiconductor devices, and particularly to a three-dimensional memory device including through-stack contact via structures and methods for forming the same.

### BACKGROUND

A three-dimensional memory device including three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an embodiment of the present disclosure, a device structure comprises: at least one alternating stack of insulating layers and electrically conductive layers; a memory opening vertically extending through each layer within the at least one alternating stack; a memory opening fill structure located in the memory opening and comprising a vertical stack of memory elements and a vertical semiconductor channel, wherein each of the electrically conductive layers is laterally spaced from the memory opening fill structure by an outer blocking dielectric layer; and a contact via structure in contact with a first electrically conductive layer of the electrically conductive layers within the at least one alternating stack, wherein the outer blocking dielectric layer contacts the first electrically conductive layer, laterally surrounds the contact via structure, and vertically extends continuously at least from a first horizontal plane including a bottommost surface of the at least one alternating stack and at least to a second horizontal plane including a topmost surface of the memory opening fill structure.

According to another aspect of the present disclosure, a method of forming a device structure is provided, which comprises: forming an alternating stack of insulating layers and sacrificial material layers over a substrate; forming stepped surfaces by patterning the alternating stack in a staircase region; forming a memory opening through the alternating stack; forming a memory opening fill structure in the memory opening, wherein the memory opening fill structure comprises a vertical stack of memory elements and a vertical semiconductor channel; forming a contact via cavity through the retro-stepped dielectric material portion and a subset of the sacrificial material layers within the alternating stack, wherein the subset of the sacrificial material layers comprises a first sacrificial material layer which is a topmost sacrificial material layer of the subset of the sacrificial material layers and further comprises second sacrificial material layers that underlie the first sacrificial material layer; forming lateral isolation trenches through the alternating stack; replacing the sacrificial material layers with replacement material portions that comprise electrically conductive layers employing both the lateral isolation trenches and at least one additional opening as conduits for an etchant that removes the sacrificial material layers and as conduits for a reactant that deposits the electrically conductive layers, wherein a first electrically conductive layer is formed in a volume of the first sacrificial material layer; and forming a contact via structure in the contact via cavity in contact with the first electrically conductive layer.

### BRIEF DESCRIPTION OF THE DRAWINGS

FIG. 1A is a plan view of a configuration of an exemplary semiconductor die including multiple three-dimensional memory array regions according to an embodiment of the present disclosure. FIG. 1B is a schematic see-through top-down view of region M1 of FIG. 1A. FIG. 1C is a schematic vertical cross-sectional view of a region of the exemplary semiconductor die along the vertical plane C-C′ of FIG. 1B. The vertical plane E-E′ is the cut plane of the schematic vertical cross-sectional view of FIG. 1E. FIG. 1D is a schematic vertical cross-sectional view of a region of the exemplary semiconductor die along the vertical plane D-D′ of FIG. 1B. FIG. 1E is a schematic vertical cross-sectional view of a region of the exemplary semiconductor die along the vertical plane E-E′ of FIG. 1B. The vertical plane C-C′ is the cut plane of the schematic vertical cross-sectional view of FIG. 1C.

FIG. 2A is a schematic vertical cross-sectional view of an exemplary structure for forming a semiconductor die after formation of a vertically alternating sequence of first-tier continuous insulating layers and first-tier continuous sacrificial material layers, and a first-tier stepped cavity according to an embodiment of the present disclosure. FIG. 2B is a schematic vertical cross-sectional view of the exemplary structure along the vertical plane B-B′ of FIG. 2A. The vertical plane A-A′ is the cut plane of the vertical cross-sectional view of FIG. 2A. FIG. 2C is a magnified view of a region of the exemplary structure around a portion of a first-tier stepped cavity in FIG. 2B.

FIGS. 3A and 3B are sequential vertical cross-sectional views of a region of the exemplary structure during thickening of physically-exposed portions of the first-tier sacrificial material layers according to an embodiment of the present disclosure. FIG. 3C is a top-down view a region of the exemplary structure after the processing steps of FIG. 3B according to an embodiment of the present disclosure.

FIG. 4A is a schematic vertical cross-sectional view of the exemplary structure after formation of a first-tier retro-stepped dielectric material portion according to an embodiment of the present disclosure. FIG. 4B is a schematic vertical cross-sectional view of the exemplary structure along the vertical plane B-B′ of FIG. 4A. The vertical plane A-A′ is the cut plane of the vertical cross-sectional view of FIG. 4A. FIG. 4C is a magnified view of a region of the exemplary structure around a thickened portion of a first-tier sacrificial material layer in FIG. 4B.

FIG. 5A is a schematic vertical cross-sectional view of the exemplary structure after formation of various first-tier openings and various first-tier sacrificial opening fill structures according to an embodiment of the present disclosure. FIG. 5B is a schematic vertical cross-sectional view of the exemplary structure along the vertical plane B-B′ of FIG. 5A. The vertical plane A-A′ is the cut plane of the vertical cross-sectional view of FIG. 5A.

FIG. 6A is a schematic vertical cross-sectional view of the exemplary structure after formation of a vertically alternating sequence of second-tier continuous insulating layers and second-tier continuous sacrificial material layers, a second-tier stepped cavity, and a second-tier retro-stepped dielectric material portion according to an embodiment of the present disclosure. FIG. 6B is a schematic vertical cross-sectional view of the exemplary structure along the vertical plane B-B′ of FIG. 6A. The vertical plane A-A′ is the cut plane of the vertical cross-sectional view of FIG. 6A. FIG. 6C is a see-through top-down view a region of the exemplary structure of FIGS. 6A and 6B.

FIG. 7A is a schematic vertical cross-sectional view of the exemplary structure after formation of various second-tier openings and various second-tier sacrificial opening fill structures according to an embodiment of the present disclosure. FIG. 7B is a schematic vertical cross-sectional view of the exemplary structure along the vertical plane B-B′ of FIG. 7A. The vertical plane A-A′ is the cut plane of the vertical cross-sectional view of FIG. 7A.

FIG. 8A is a schematic vertical cross-sectional view of the exemplary structure after formation of a vertically alternating sequence of third-tier continuous insulating layers and third-tier continuous sacrificial material layers, a third-tier stepped cavity, and a third-tier retro-stepped dielectric material portion according to an embodiment of the present disclosure. FIG. 8B is a schematic vertical cross-sectional view of the exemplary structure along the vertical plane B-B′ of FIG. 8A. The vertical plane A-A′ is the cut plane of the vertical cross-sectional view of FIG. 8A.

FIG. 9A is a schematic vertical cross-sectional view of the exemplary structure after formation of various third-tier openings and various third-tier sacrificial opening fill structures according to an embodiment of the present disclosure. FIG. 9B is a schematic vertical cross-sectional view of the exemplary structure along the vertical plane B-B′ of FIG. 9A. The vertical plane A-A′ is the cut plane of the vertical cross-sectional view of FIG. 9A.

FIG. 10 is a schematic vertical cross-sectional view of the exemplary structure after removal of sacrificial support opening fill structures according to an embodiment of the present disclosure.

FIG. 11 is a schematic vertical cross-sectional view of the exemplary structure after formation of support pillar structures according to an embodiment of the present disclosure.

FIG. 12 is a schematic vertical cross-sectional view of the exemplary structure after formation of memory opening according to an embodiment of the present disclosure.

FIGS. 13A-13F illustrate sequential vertical cross-sectional views of a memory opening during formation of a memory opening fill structure according to an embodiment of the present disclosure.

FIG. 14A is a schematic vertical cross-sectional view of the exemplary structure after formation of memory opening fill structures according to an embodiment of the present disclosure. FIG. 14B is a schematic vertical cross-sectional view of the exemplary structure along the vertical plane B-B′ of FIG. 14A. The vertical plane A-A′ is the cut plane of the vertical cross-sectional view of FIG. 14A. FIG. 14C is a magnified view of a region of the exemplary structure around a thickened portion of a first-tier sacrificial material layer in FIG. 14B.

FIG. 15A is a schematic vertical cross-sectional view of the exemplary structure after formation of a contact-level dielectric layer and contact via cavities according to an embodiment of the present disclosure. FIG. 15B is a schematic vertical cross-sectional view of the exemplary structure along the vertical plane B-B′ of FIG. 15A. The vertical plane A-A′ is the cut plane of the vertical cross-sectional view of FIG. 15A. FIG. 15C is a magnified view of a region of the exemplary structure around a bottom corner of a first-tier stepped cavity in FIG. 15B.

FIGS. 16A-16H are sequential vertical cross-sectional views of a region of the exemplary structure during formation of annular dielectric spacers according to an embodiment of the present disclosure.

FIG. 17A is a schematic vertical cross-sectional view of the exemplary structure after removal of etch-stop annular plates according to an embodiment of the present disclosure. FIG. 17B is a schematic vertical cross-sectional view of the exemplary structure along the vertical plane B-B′ of FIG. 17A. The vertical plane A-A′ is the cut plane of the vertical cross-sectional view of FIG. 17A. FIG. 17C is a magnified view of a region of the exemplary structure around a contact via cavity in FIG. 17B.

FIG. 18A is a schematic vertical cross-sectional view of the exemplary structure after formation of lateral isolation trenches according to an embodiment of the present disclosure. FIG. 18B is a schematic vertical cross-sectional view of the exemplary structure along the vertical plane B-B′ of FIG. 18A. The vertical plane A-A′ is the cut plane of the vertical cross-sectional view of FIG. 18A. FIG. 18C is a magnified view of a region of the exemplary structure around a contact via cavity in FIG. 18B.

FIG. 19A is a schematic vertical cross-sectional view of the exemplary structure after formation of semiconductor oxide spacer liners according to an embodiment of the present disclosure. FIG. 19B is a schematic vertical cross-sectional view of the exemplary structure along the vertical plane B-B′ of FIG. 19A. The vertical plane A-A′ is the cut plane of the vertical cross-sectional view of FIG. 19A. FIG. 19C is a magnified view of a region of the exemplary structure around a contact via cavity in FIG. 19B.

FIG. 20A is a schematic vertical cross-sectional view of the exemplary structure after formation of lateral recesses according to an embodiment of the present disclosure. FIG. 20B is a schematic vertical cross-sectional view of the exemplary structure along the vertical plane B-B′ of FIG. 20A. The vertical plane A-A′ is the cut plane of the vertical cross-sectional view of FIG. 20A. FIG. 20C is a magnified view of a region of the exemplary structure around a contact via cavity in FIG. 20B.

FIGS. 21A-21C are sequential vertical cross-sectional views of a region of the exemplary structure during formation of an outer blocking dielectric layer, a metal-line metallic barrier liner, and a metal-line metal fill material layer according to an embodiment of the present disclosure.

FIG. 22A is a schematic vertical cross-sectional view of the exemplary structure after formation of electrically conductive layers according to an embodiment of the present disclosure. FIG. 22B is a schematic vertical cross-sectional view of the exemplary structure along the vertical plane B-B′ of FIG. 22A. The vertical plane A-A′ is the cut plane of the vertical cross-sectional view of FIG. 22A. FIG. 22C is a magnified view of a region of the exemplary structure around a contact via cavity in FIG. 22B. FIG. 22D is a vertical cross-sectional view of a region of the exemplary structure of FIGS. 22A-22C around a memory opening fill structure.

FIG. 23A is a schematic vertical cross-sectional view of the exemplary structure after formation of sacrificial contact via structures and sacrificial lateral isolation trench fill structures according to an embodiment of the present disclosure. FIG. 23B is a schematic vertical cross-sectional view of the exemplary structure along the vertical plane B-B′ of FIG. 23A. The vertical plane A-A′ is the cut plane of the vertical cross-sectional view of FIG. 23A. FIG. 23C is a magnified view of a region of the exemplary structure around an upper portion of a finned support assembly in FIG. 23B.

FIG. 24A is a schematic vertical cross-sectional view of the exemplary structure after removal of the sacrificial lateral isolation trench fill structures according to an embodiment of the present disclosure. FIG. 24B is a schematic vertical cross-sectional view of the exemplary structure along the vertical plane B-B′ of FIG. 24A. The vertical plane A-A′ is the cut plane of the vertical cross-sectional view of FIG. 24A. FIG. 24C is a magnified view of a region of the exemplary structure around an upper portion of a finned support assembly in FIG. 24B.

FIG. 25A is a schematic vertical cross-sectional view of the exemplary structure after formation of lateral isolation trench fill structures according to an embodiment of the present disclosure. FIG. 25B is a schematic vertical cross-sectional view of the exemplary structure along the vertical plane B-B′ of FIG. 25A. The vertical plane A-A′ is the cut plane of the vertical cross-sectional view of FIG. 25A. FIG. 25C is a magnified view of a region of the exemplary structure around an upper portion of a finned support assembly in FIG. 25B.

FIG. 26A is a schematic vertical cross-sectional view of the exemplary structure after removal of the sacrificial contact via structures according to an embodiment of the present disclosure. FIG. 26B is a schematic vertical cross-sectional view of the exemplary structure along the vertical plane B-B′ of FIG. 26A. The vertical plane A-A′ is the cut plane of the vertical cross-sectional view of FIG. 26A. FIG. 26C is a magnified view of a region of the exemplary structure around an upper portion of a finned support assembly in FIG. 26B.

FIG. 27A is a schematic vertical cross-sectional view of the exemplary structure after formation of layer contact via structures according to an embodiment of the present disclosure. FIG. 27B is a schematic vertical cross-sectional view of the exemplary structure along the vertical plane B-B′ of FIG. 27A. The vertical plane A-A′ is the cut plane of the vertical cross-sectional view of FIG. 27A. FIG. 27C is a magnified view of a region of the exemplary structure around an upper portion of a finned support assembly in FIG. 27B.

FIG. 28 is a schematic vertical cross-sectional view of the exemplary structure after formation of drain contact via structures according to an embodiment of the present disclosure.

FIG. 29 is a schematic vertical cross-sectional view of the exemplary structure after formation of a memory die, bonding of the memory die to a logic die, removal of the carrier substrate, and formation of source-side structures according to an embodiment of the present disclosure.

FIGS. 30, 31 and 32 are schematic vertical cross-sectional views of steps of forming an alternative exemplary structure according to an alternative embodiment of the present disclosure.

### DETAILED DESCRIPTION

As discussed above, an embodiments of the present disclosure are directed to a three-dimensional memory device including through-stack contact via structures and methods for forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

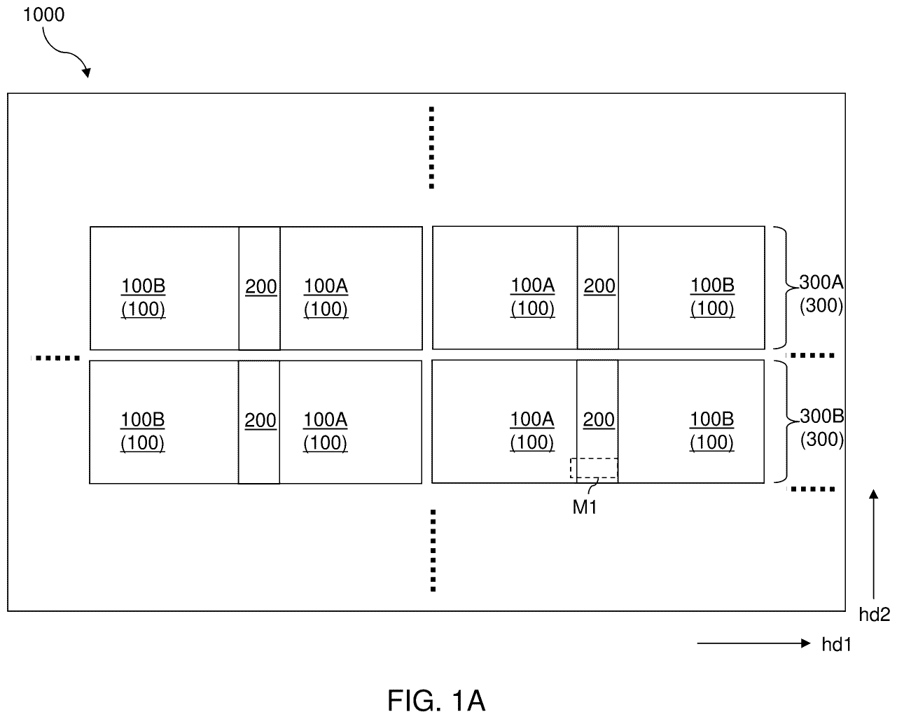

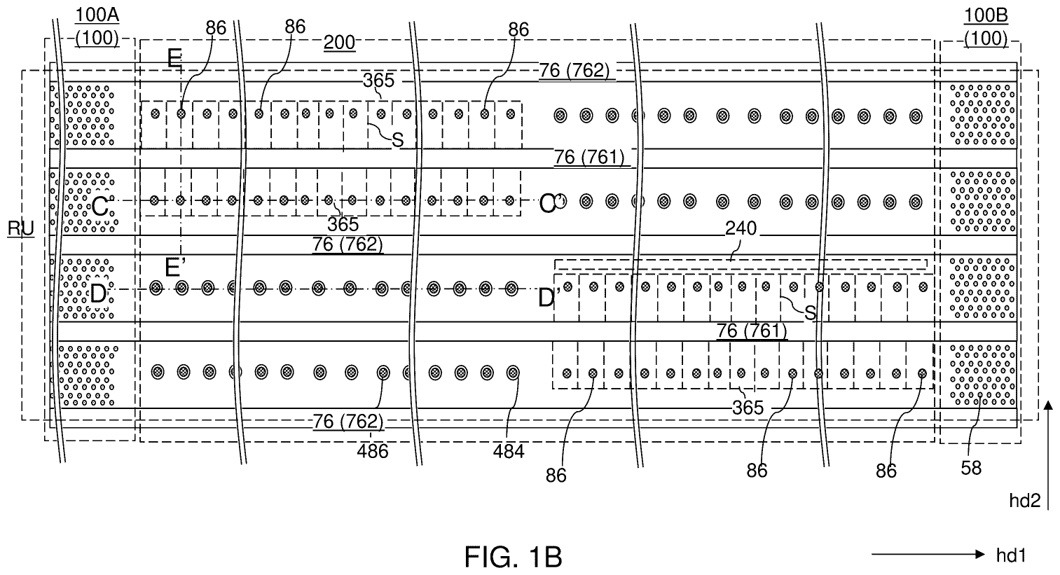

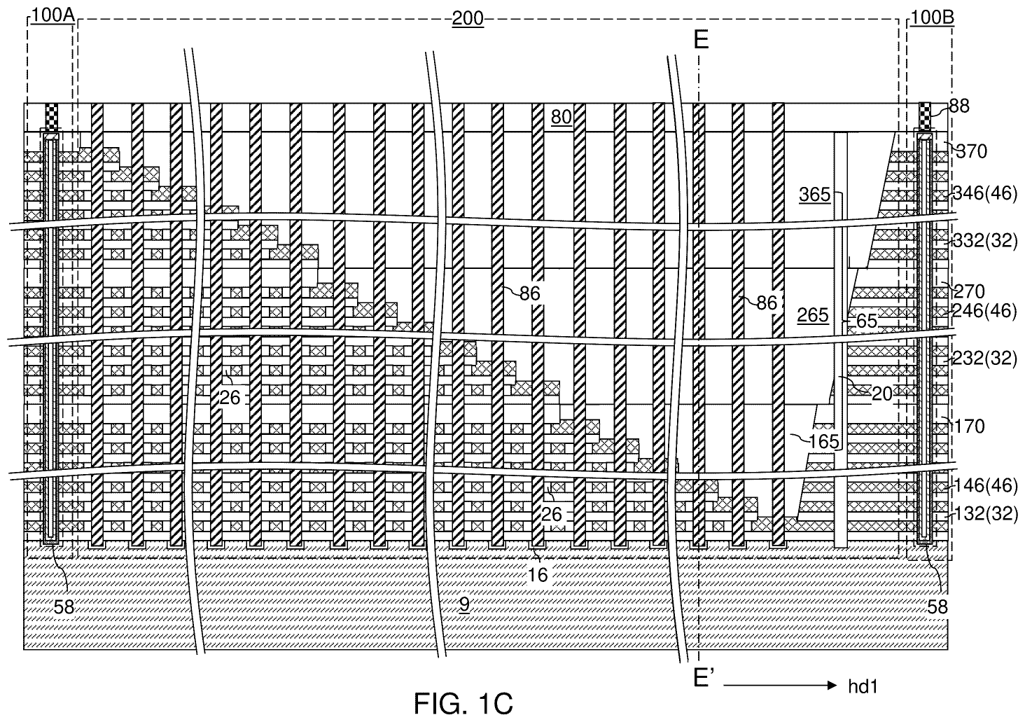

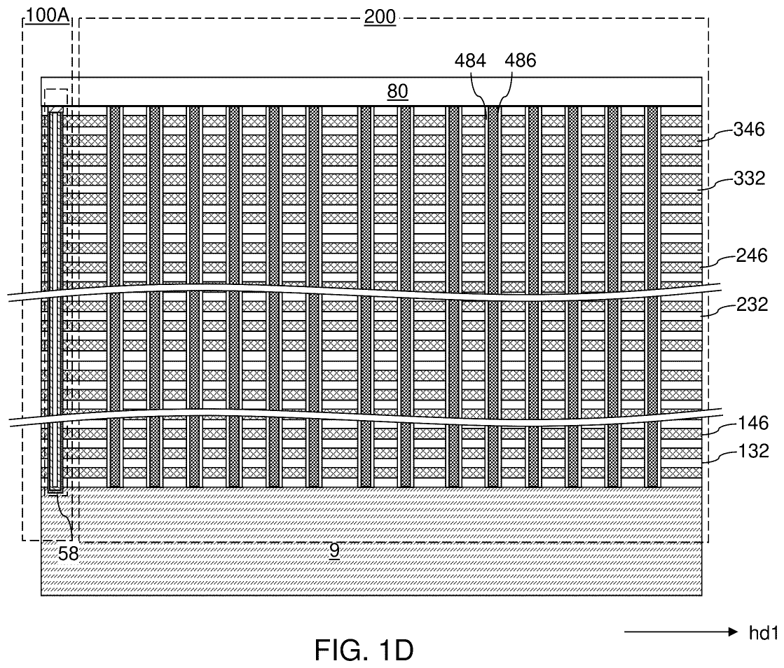

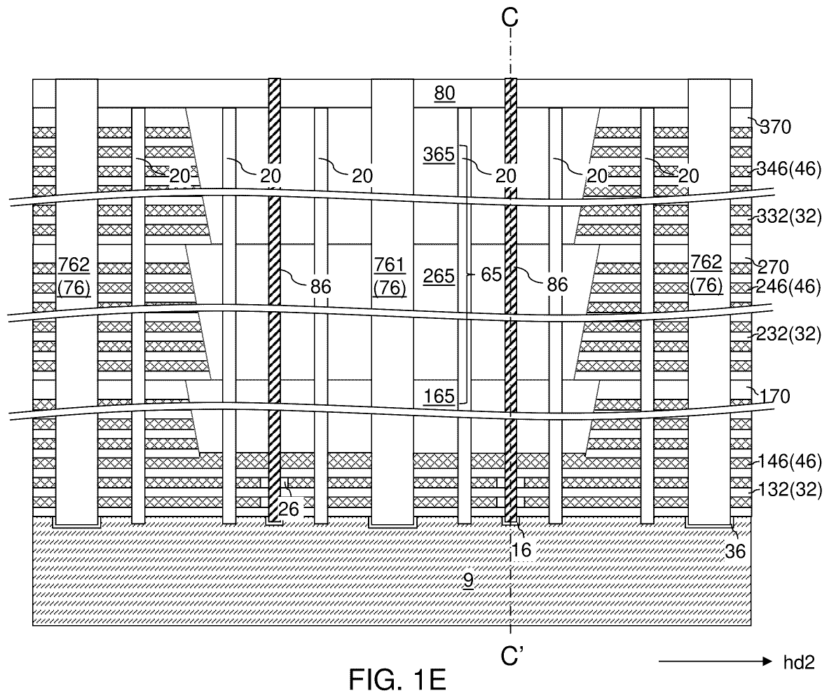

Referring to FIGS. 1A-1E, an exemplary semiconductor die 1000 according to an embodiment of the present disclosure is illustrated. The exemplary semiconductor die 1000 comprises a substrate 9, which may be a semiconductor substrate and/or a carrier substrate. For example, the substrate 9 may comprise a commercially available silicon wafer. If the substrate 9 comprises a carrier substrate, the substrate 9 may comprise any material that may be removed selective the materials of overlying materials which are subsequently formed. The exemplary semiconductor die 1000 is illustrated after a set of processing steps that forms various contact via structures (86, 88), which include layer contact via structures 86 and drain contact via structures 88. The exemplary semiconductor die 1000 illustrates an exemplary layout and configuration of the various device structures of the present disclosure that are subsequently described. However, the layout and the configuration of the exemplary semiconductor die 1000 in FIGS. 1A-1E are only illustrative, and do not limit the general layout and/or configurations of embodiments of the present disclosure.

The exemplary semiconductor die 1000 includes multiple three-dimensional memory array regions and multiple inter-array regions. The exemplary semiconductor die 1000 can include multiple planes 300 (e.g., 300A, 300B), each of which includes two memory array regions 100, such as a first memory array region 100A and a second memory array region 100B that are laterally spaced apart by a respective inter-array region 200. Generally, a semiconductor die 1000 may include a single plane 300 or multiple planes. The total number of planes in the semiconductor die 1000 may be selected based on performance requirements on the semiconductor die 1000. A pair of memory array regions 100 in a plane 300 may be laterally spaced apart along a first horizontal direction hd1 (which may be the word line direction). A second horizontal direction hd2 (which may be the bit line direction) can be perpendicular to the first horizontal direction hd1.

The size of the first memory array region 100A may be the same as, or may differ from, the size of the second memory array region 100B within a given plane. In one embodiment, each of the first memory array region 100A and the second memory array region 100B may have a respective rectangular area having a same width along the second horizontal direction hd2. In one embodiment, the inter-array region 200 within each plane 300 can be located off-center of the respective plane 300 along the first horizontal direction hd1 (i.e., the inter-array region 200 is located closer to one end than to another end of the respective plane 300). For example, the inter-array region 200 in the left plane 300A may be shifted toward the left edge of the die 1000, while the inter-array region 200 in the right plane 300B may be shifted toward the right edge of the die 1000. Alternatively, the inter-array region 200 within each plane 300 can be centered in the respective plane 300 along the first horizontal direction hd1 (i.e., the inter-array region 200 is located the same distance from both ends of the respective plane 300). Each memory array region 100 includes first-tier alternating stacks of first-tier insulating layers 132 and first-tier electrically conductive layers 146 (which function as first word lines), optional second-tier alternating stacks of second-tier insulating layers 232 and second-tier electrically conductive layers 246 (which function as second word lines), and optional third-tier alternating stacks of third-tier insulating layers 332 and third-tier electrically conductive layers 346 (which function as third word lines). Each second-tier alternating stack (232, 246) overlies a respective first-tier alternating stack (132, 146), and each third-tier alternating stack (332, 346), if present, overlies a respective second-tier alternating stack (232, 246). Each combination of a first-tier alternating stack (132, 146), an overlying second-tier alternating stack (232, 246), and an optional overlying third-tier alternating stack (332, 346) may be laterally spaced apart from neighboring combinations of a respective first-tier alternating stack (132, 146), an overlying respective second-tier alternating stack (232, 246), and an overlying optional third-tier alternating stack (332, 346) by lateral isolation trench fill structures 76 that laterally extend along the first horizontal direction hd1 (which may be a word line direction). The first-tier insulating layers 132, the second-tier insulating layers 232, and the third-tier insulating layers 332 are collectively referred to as insulating layers 32. The first-tier electrically conductive layers 146, the second-tier electrically conductive layers 246, and the third-tier electrically conductive layers 346 are collectively referred to as electrically conductive layers 46.

As used herein, a “first-tier level” refers to the tier level that is most proximal to a substrate, a “second-tier level” refers to the tier level that is most proximal to the substrate among tier levels that overlie the first-tier level, and a “third-tier level” refers to the tier level that is most proximal to the substrate among tier levels that overlie the second-tier level, etc. A “first-tier” element refers to an element that is located within the first-tier level; a “second-tier” element refers to an element that is located within the second-tier level; a “third-tier” element refers to an element that is located within the second-tier level; etc. Individual tier levels within a structure including multiple tier levels may be labeled as a first tier level, a second tier level, a third tier level, etc. In this case, the first tier level may be any of the multiple tier levels, the second tier level may be a tier level that is different from the first tier level, etc.

A first-tier alternating stack of first-tier insulating layers 132 and first-tier electrically conductive layers 146 is located over the substrate 9 between each neighboring pair of lateral isolation trench fill structures 76. A first-tier retro-stepped dielectric material portion 165 overlies, and contacts, first stepped surfaces of the first-tier alternating stack (132, 146). A second-tier alternating stack of second-tier insulating layers 232 and second-tier electrically conductive layers 246 overlies the first-tier alternating stack (132, 146), and overlies a horizontal plane including a planar top surface of the first-tier retro-stepped dielectric material portion 165 between each neighboring pair of lateral isolation trench fill structures 76. A second-tier retro-stepped dielectric material portion 265 overlies, and contacts, second stepped surfaces of the second-tier alternating stack (232, 246). A third-tier alternating stack of third-tier insulating layers 332 and third-tier electrically conductive layers 346, if present, overlies the second-tier alternating stack (232, 246), and overlies a horizontal plane including a planar top surface of the second-tier retro-stepped dielectric material portion 265 between each neighboring pair of lateral isolation trench fill structures 76. A third-tier retro-stepped dielectric material portion 365 overlies, and contacts, third stepped surfaces of the third-tier alternating stack (332, 346), if present. Vertical steps S of the first stepped surfaces and the second stepped surfaces laterally extend along the second horizontal direction hd2 (which may be a bit line direction). The first-tier retro-stepped dielectric material portion 165, the second-tier retro-stepped dielectric material portion 265, and the third-tier retro-stepped dielectric material portion 365 are collectively referred to as retro-stepped dielectric material portions 65.

Memory opening fill structures 58 can be located within each memory array region 100 (which includes a first memory array region 100A and a second memory array region 100B) between each neighboring pair of lateral isolation trench fill structures 76. The memory opening fill structures 58 can be located within memory openings that vertically extend through each layer within the first-tier alternating stack (132, 146), the second-tier alternating stack (232, 246), and the optional third-tier alternating stack (332, 346), if present, which are located between a respective neighboring pair of lateral isolation trench fill structures 76.

In one embodiment, each of the memory opening fill structures 58 comprises a vertical stack of memory elements (e.g., portions of a memory film or vertically separated, discrete memory elements) located at levels of the electrically conductive layers 46 and a vertical semiconductor channel 60 that is electrically connected to a respective overlying metal interconnect structure (such as a bit line). In one embodiment, the inter-array region 200 is free of any memory stack structure that is electrically contacted by any metal interconnect structure (such as a bit line).

Each memory opening fill structure 58 includes a respective memory stack structure, which includes a respective memory film and a respective vertical semiconductor channel. The memory openings and the memory opening fill structures 58 are formed in region in which each layer of a first-tier alternating stack and each layer of the second-tier alternating stack are present. For each area within which a continuous combination of a first-tier alternating stack (132, 146), a second-tier alternating stack (232, 246), and an optional third-tier alternating stack (332, 346) continuously laterally extends, first memory stack structures can be located within a respective first memory array region 100A and second memory stack structures can be located within a respective second memory array region 100B. The second memory array region 100B can be connected to the first memory array region 100A through a respective inter-array region 200, in which a first-tier retro-stepped dielectric material portion 165, a second-tier retro-stepped dielectric material portion 265, and an optional third-tier retro-stepped dielectric material portion 365 are located.

A first-tier retro-stepped dielectric material portion 165 can be located between each neighboring pair of lateral isolation trench fill structures 76. Each first-tier retro-stepped dielectric material portion 165 overlies first stepped surfaces of a respective first-tier alternating stack (132, 146). Each first-tier retro-stepped dielectric material portion 165 can have a sidewall that laterally extends along the first horizontal direction hd1 and contacts a respective lateral isolation trench fill structure 76. The first stepped surfaces comprise vertical steps of the first-tier alternating stack (132, 146) that are laterally spaced apart along the first horizontal direction hd1 and vertically offset from each other.

A second-tier retro-stepped dielectric material portion 265 can be located between each neighboring pair of lateral isolation trench fill structures 76. Each second-tier retro-stepped dielectric material portion 265 overlies second stepped surfaces of a respective second-tier alternating stack (232, 246). Each second-tier retro-stepped dielectric material portion 265 can have a sidewall that laterally extends along the second horizontal direction hd1 and contacts a respective lateral isolation trench fill structure 76. The second stepped surfaces comprise vertical steps of the second-tier alternating stack (232, 246) that are laterally spaced apart along the first horizontal direction hd1 and vertically offset from each other. In one embodiment, each second-tier retro-stepped dielectric material portion 265 overlies, and contacts, a respective one of the first-tier retro-stepped dielectric material portions 165.

A third-tier retro-stepped dielectric material portion 365 can be located between each neighboring pair of lateral isolation trench fill structures 76. Each third-tier retro-stepped dielectric material portion 365 overlies third stepped surfaces of a respective third-tier alternating stack (332, 346). Each third-tier retro-stepped dielectric material portion 365 can have a sidewall that laterally extends along the second horizontal direction hd2 and contacts a respective lateral isolation trench fill structure 76. The third stepped surfaces comprise vertical steps of the third-tier alternating stack (332, 346) that are laterally spaced apart along the second horizontal direction hd2 and vertically offset from each other. In one embodiment, each third-tier retro-stepped dielectric material portion 365 overlies, and contacts, a respective one of the second-tier retro-stepped dielectric material portions 265.

Lateral isolation trenches can laterally extend along the first horizontal direction hd1. Each lateral isolation trench can be filled with a lateral isolation trench fill structure 76, which may include a combination of a backside contact via structure and an insulating spacer that laterally surround the backside contact via structure. Alternatively, each lateral isolation trench fill structure 76 may consist of an insulating fill structure. Each vertical stack of a first-tier alternating stack (132, 146), a second-tier alternating stack (232, 246), and an optional third-tier alternating stack (332, 346) can be located between a neighboring pair of lateral isolation trench fill structure 76.

Generally, at least the first-tier alternating stack (132, 146) can be formed, and the second-tier alternating stack (232, 246) and/or the third-tier alternating stack (332, 346) may be formed above the first-tier alternating stack (132, 146). The set of all alternating stack(s) in the exemplary structure may be referred to as at least one alternating stack (32, 46). In one embodiment, each of the electrically conductive layers 46 except the topmost electrically conductive layer 46 may have a first thickness in each area that underlies any other electrically conductive layer 46, and may optionally be locally thickened in each area that does not underlie any other electrically conductive layer 46 to provide a respective locally thickened region having a second thickness. The topmost electrically conductive layer 46 may have the second thickness only within the areas of the stepped surfaces in a top-down view.

A contact-level dielectric layer 80 can be formed over the at least one alternating stack (32, 46). In one embodiment, layer contact via structures 86 vertically extend through a respective subset of the at least one retro-stepped dielectric material portion 65 (which may be a plurality of retro-stepped dielectric material portions 65), through a thickened portion of a respective electrically conductive layer 46, and through underlying electrically conductive layers 46. Each such layer contact via structure 86 can contact a cylindrical sidewall of the optionally thickened portion of the respective electrically conductive layer 46, and can be electrically isolated from at least one of the underlying electrically conductive layers by at least one annular dielectric spacer 26. The optional thickened portions of the electrically conductive layers 46 can be formed by locally thickening sacrificial material layers, and by replacing the sacrificial material layers, during which the electrically conductive layers are formed with local thickening at locations at which the sacrificial material layers are previously thickened. Formation of the annular dielectric spacers 26 and formation of the layer contact via structures 86 in a manner that provides direct contact with cylindrical sidewalls of openings through the electrically conductive layers 46 are described in detail in subsequent sections of the present disclosure.

The inter-array region 200 includes strips of the first-tier insulating layers 132, the first-tier electrically conductive layers 146, the second-tier insulating layers 232, the second-tier electrically conductive layers 246, the third-tier insulating layers 332, and the third-tier electrically conductive layers 346 located between each laterally neighboring pair of lateral isolation trench fill structures 76. Such strips are located in a respective strip-shaped connection regions 240 (i.e., bridge regions) of the inter-array regions 200, which are located adjacent to a respective first-tier retro-stepped dielectric material portion 165, a respective second-tier retro-stepped dielectric material portion 265, or a respective third-tier retro-stepped dielectric material portions 365. The strips have a narrower width along the second horizontal direction hd2 than portions of the alternating stacks (132, 146, 232, 246, 332, 346) located in the memory array regions 100, and portions of the strips located in the remaining portions of the inter-array regions 200 outside of the respective strip-shaped connection regions 240.

For each vertical stack of a first-tier alternating stack (132, 146), a second-tier alternating stack (232, 246), and an optional third-tier alternating stack (332, 346), first memory opening fill structures 58 can be located within a first memory array region 100A in which each layer of the first-tier alternating stack (132, 1446), the second-tier alternating stack (232, 246), and the optional third-tier alternating stack (332, 346) is present. Further, second memory opening fill structures 58 can be located within a second memory array region 100B that is laterally offset along the first horizontal direction hd1 from the first memory array region 100A by the first-tier retro-stepped dielectric material portion 165, the second-tier retro-stepped dielectric material portion 265, and the optional third-tier retro-stepped dielectric material portion 365. Each layer of the first-tier alternating stack (132, 146), the second-tier alternating stack (232, 246), and the optional third-tier alternating stack (332, 346) is present within the second memory array region 100B. Each of the electrically conductive layers 46 within the vertical stack may continuously extend from the first memory array region 100A to the second memory array region 100B through a strip-shaped connection region 240 (which is also referred to as a bridge region). Each strip-shaped connection region 240 is located within an inter-array region 200, and may be located between the lateral isolation trench fill structure 76 and the first-tier retro-stepped dielectric material portion 165 at the level of the first-tier alternating stack (132, 146), or between a lateral isolation trench fill structures 76 and the second-tier retro-stepped dielectric material portion 265 at the level of the second-tier alternating stack (232, 246), or between a lateral isolation trench fill structures 76 and the third-tier retro-stepped dielectric material portion 365 at the level of the third-tier alternating stack (332, 346).

Staircases including first stepped surfaces of a first-tier alternating stack (132, 146), optionally second stepped surfaces of a second-tier alternating stack (232, 246), and optionally third stepped surfaces of a third-tier alternating stack (332, 346) can ascend (i.e., rise) from the substrate along the first horizontal direction hd1, or along the opposite direction of the first horizontal direction hd1. Each region including the staircases is herein referred to as a staircase region. In one embodiment, the direction of rise of the staircases can change for every other pair of vertical stacks of a respective first-tier alternating stack (132, 146), a respective second-tier alternating stack (232, 246), and a respective third-tier alternating stack (332, 346). In other words, the direction of rise is staggered in adjacent alternating stacks that are separated along the second horizontal direction

Optional laterally-isolated vertical interconnection structures (484, 486) can be formed through the inter-array region 200. Each laterally-isolated vertical interconnection structure (484, 486) can include a through-memory-level conductive via structure 486 and a tubular insulating spacer 484 that laterally surrounds the conductive via structure 486. The laterally-isolated vertical interconnection structures (484, 486) vertically extend through the strip portions of the first-tier alternating stack (132, 146), the second-tier alternating stack (232, 246), and the third-tier alternating stack (332, 346), and can contact the substrate 9. Alternatively, the laterally-isolated vertical interconnection structures (484 and/or 486) are omitted.

Drain contact via structures 88 can contact an upper portion of a respective memory opening fill structure 58 (such as a drain region within the respective memory opening fill structure 58). Bit lines (not illustrated) can laterally extend along the second horizontal direction hd2, and can contact top surfaces of a respective subset of the drain contact via structures. Additional metal interconnect structures embedded in overlying dielectric material layers (not shown) may be employed to provide electrical connection among the various nodes of the three-dimensional memory device located in the semiconductor die 1000.

Each lateral isolation trench fill structure 76 includes an insulating material portion. In one embodiment, each insulating material portion may comprise an insulating spacer that laterally surrounds a layer contact via structure such as a backside contact via structure (not expressly shown). In another embodiment, each insulating material portion may comprise a dielectric wall structure which takes up the entire volume of the respective lateral isolation trench fill structure 76. In one embodiment, each sidewall of the first alternating stacks (132, 146) can be contacted by a sidewall of an insulating material portion of a respective one of the lateral isolation trench fill structures 76.

In one embodiment, each plane 300 within the exemplary semiconductor die 1000 includes a three-dimensional memory device, which includes alternating stacks of insulating layers 32 and electrically conductive layers 46. Each of the alternating stacks {(132, 146), (232, 246), (332, 346)} laterally extends along a first horizontal direction hd1 through a first memory array region 100A and a second memory array region 100B that are laterally spaced apart by an inter-array region 200. Each of the alternating stacks {(132, 146), (232, 246), (332, 346)} includes a set of stepped surfaces (i.e., a staircase) in the inter-array region 200. Each plane 300 within the exemplary semiconductor die 1000 includes retro-stepped dielectric material portions (165, 265, 365) overlying a respective set of stepped surfaces of the alternating stacks {(132, 146), (232, 246), (332, 346)}. Each plane 300 within the exemplary semiconductor die 1000 includes clusters of memory stack structures located within memory opening fill structures 58. Each of the memory stack structures vertically extends through a respective one of the alternating stacks {(132, 146), (232, 246), (332, 346)} and is located within the first memory array region 100A or the second memory array region 100B. Each memory stack structure can include a respective vertical semiconductor channel and a vertical stack of memory elements (e.g., a memory film) located at levels of the electrically conductive layers 46.

Each of the retro-stepped dielectric material portions 65 comprises a respective stepped bottom surface. Each region of the alternating stacks (32, 46) that underlies a respective retro-stepped dielectric material portion 65 constitutes a staircase region. A strip-shaped connection region 240 including each layer within an alternating stack (32, 46) is provided adjacent to each staircase region, and is herein referred to as a bridge region. Each strip-shaped connection region 240 laterally extends along the first horizontal direction hd1, and provides electrically conductive paths between a respective portion located in the first memory array region 100A and a respective portion located in the second memory array region 100B for each electrically conductive layer 46. The strip region has a lesser width (i.e., narrower width along the second horizontal direction hd2) than the portions of the electrically conductive layer 46 located in the first memory array region 100A or in the second memory array region 100B. The portions of the electrically conductive layer 46 located in the first memory array region 100A or in the second memory array region 100B have a width along the second horizontal direction hd2 that is the same as a lateral distance between a neighboring pair of lateral isolation trench fill structures 76.

In contrast, each strip portion of the electrically conductive layer 46 in the strip-shaped connection region 240 has a width along the second horizontal direction hd2 that is the same as the difference between the lateral distance between a neighboring pair of lateral isolation trench fill structures 76 and the width of an adjoining retro-stepped dielectric material portion (165 or 265) along the second horizontal direction hd2. Each electrical connection between a layer contact via structure 86 and a most proximal portion of the second memory array region 100B includes a narrow strip portion of an electrically conductive layer 46 in the strip-shaped connection region 240, while electrical connection between the layer contact via structure 86 and a most proximal portion of the first memory array region 100A does not include any narrow strip portion of the electrically conductive layer 46 because the first memory array region 100A is not separated from the layer contact via structures 86 by the strip-shaped connection region 240.

In one embodiment, the alternating stacks {(132, 146), (232, 246), (332, 346)} are laterally spaced apart along the second horizontal direction hd2 by line trenches (such as lateral isolation trenches) that laterally extend along the first horizontal direction hd1. The line trenches are filled with lateral isolation trench fill structures 76 having dielectric surfaces (such as surfaces of insulating spacers or dielectric wall structures) that contact sidewalls of the alternating stacks {(132, 146), (232, 246), (332, 346)}. In one embodiment, upon sequentially numbering the lateral isolation trench fill structures 76 with positive integers along the second horizontal direction hd2, odd-numbered lateral isolation trench fill structures 76 (e.g., 761) may contact a respective pair of retro-stepped dielectric material portions (165, 265, 365) (which are located on either side of a respective odd-numbered lateral isolation trench fill structure 76), and even-numbered lateral isolation trench fill structures 76 (e.g., 762) do not contact any retro-stepped dielectric material portion (165, 265, 365), or alternatively, even-numbered lateral isolation trench fill structures 76 (e.g., 762) may contact a respective pair of retro-stepped dielectric material portions (165, 265, 365) and odd-numbered lateral isolation trench fill structures 76 (e.g., 761) do not contact any retro-stepped dielectric material portion (165, 265, 365).

In one embodiment, strip widths of the first-tier electrically conductive layers 146 decrease with a respective vertical distance from the substrate 9. Strip widths of the second-tier electrically conductive layers 246 decrease with a respective vertical distance from the substrate 9. Strip widths of the third-tier electrically conductive layers 346 decrease with a respective vertical distance from the substrate 9. A bottommost second electrically conductive layer 246 within the second-tier alternating stack (232, 246) has a greater strip width than a topmost first electrically conductive layer 146 within the first-tier alternating stack (132, 146). A bottommost third electrically conductive layer 346 within the third-tier alternating stack (332, 346) has a greater strip width than a topmost second electrically conductive layer 246 within the second-tier alternating stack (232, 246).

According to an aspect of the present disclosure shown in FIG. 1E, a set of a first-tier retro-stepped dielectric material portion 165, a second-tier retro-stepped dielectric material portion 265, and a third-tier retro-stepped dielectric material portion 365 can be formed between a neighboring pair of lateral isolation trench fill structures 76, which are herein referred to as a first lateral isolation trench fill structure 761 and a second lateral isolation trench fill structure 762. The width of each strip of an electrically conductive layer 46 along the second horizontal direction in the strip-shaped connection region 240 is herein referred to as a strip width or a bridge width. Generally, embedding of the retro-stepped dielectric material portions (165, 265, 365) in alternating stacks of insulating layers 32 and electrically conductive layers 46 may induce cracking due to voids formed in the retro-stepped dielectric material portions (165, 265, 365) and/or due to incline of the alternating stacks into the lateral isolation trenches due to unbalanced electrically conductive layer material filling. While the illustrated configuration of the exemplary structure illustrated in FIGS. 1A-1E includes three tier levels, embodiments are expressly contemplated herein in which one tier level, two tier levels, or four or more tier levels are used in an alternative configuration.

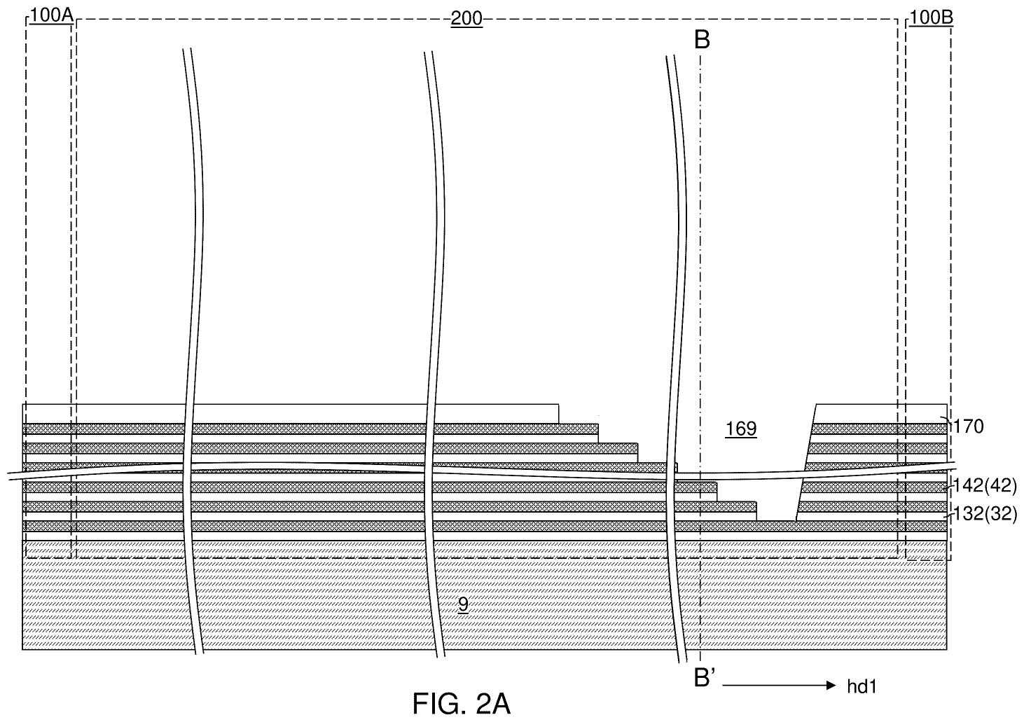

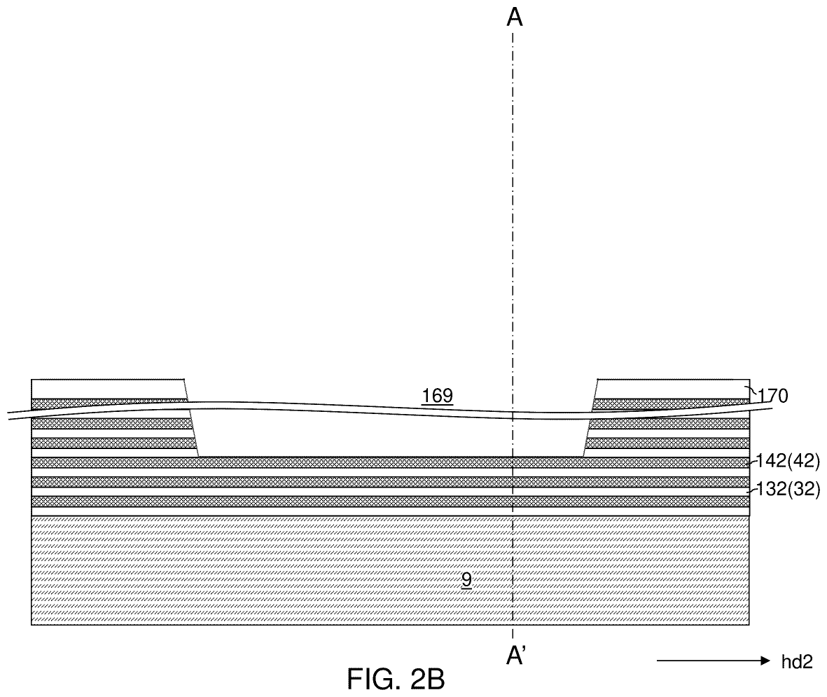

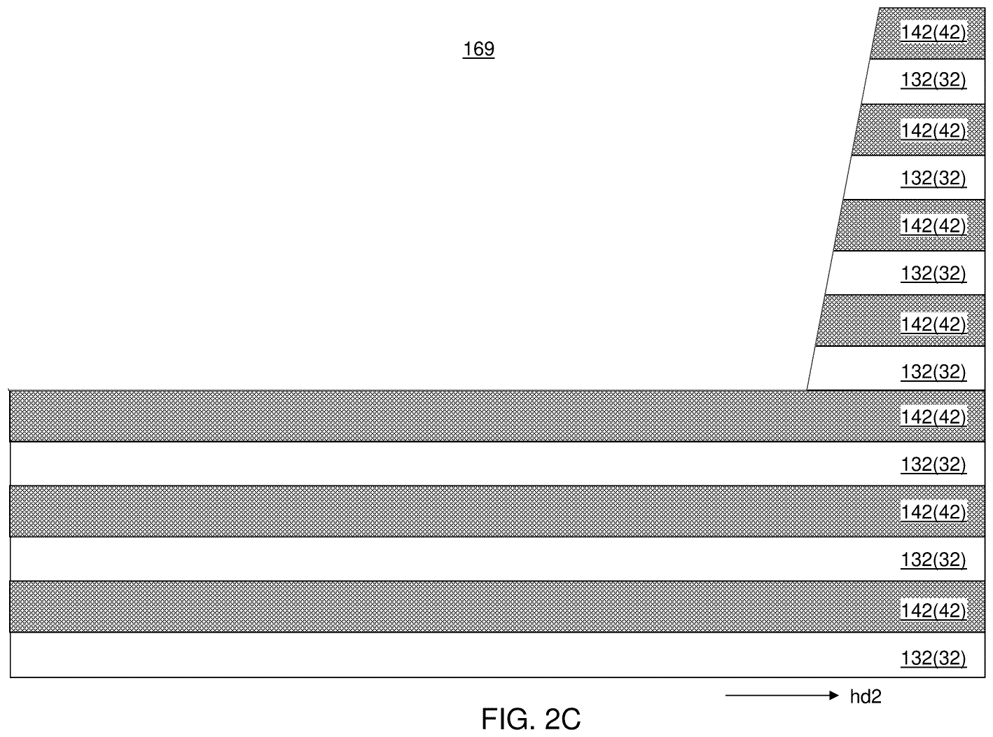

Referring to FIGS. 2A-2C, an exemplary structure according to an embodiment of the present disclosure is illustrated, which can be employed to form a semiconductor die such as the semiconductor die 1000 illustrated in FIGS. 1A-1E.

A first vertically alternating sequence of first-tier insulating layers 132 and first-tier sacrificial material layers 142 can be formed over a substrate 9. As used herein, a vertically alternating sequence refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element.

The first-tier insulating layers 132 can be composed of the first material, and the first-tier sacrificial material layers 142 can be composed of the second material, which is different from the first material. Each of the first-tier insulating layers 132 is an insulating layer that continuously extends over the entire area of the substrate 8, and may have a uniform thickness throughout. Each of the first-tier sacrificial material layers 142 includes is a sacrificial material layer that includes a dielectric material and continuously extends over the entire area of the substrate 8, and may have a uniform thickness throughout. Insulating materials that may be used for the first-tier insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first-tier insulating layers 132 may be silicon oxide.

The second material of the first-tier sacrificial material layers 142 is a dielectric material, which is a sacrificial material that may be removed selective to the first material of the first-tier insulating layers 132. As used herein, removal of a first material is “selective to” a second material if the removal process removes the first material at a removal rate that is at least twice the removal rate for the second material. The ratio of the rate of removal of the first material to the rate of removal of the second material is herein referred to as a “selectivity” of the removal process for the first material with respect to the second material.

The thickness of each first-tier insulating layer 132 may be in a range from 12 nm to 50 nm, such as from 15 nm to 30 nm, although lesser and greater thicknesses may also be employed. The thickness of each first-tier sacrificial material layer 142 may be in a range from 15 nm to 50 nm, such as from 20 nm to 30 nm, although lesser and greater thicknesses may also be employed. The second material of the first-tier sacrificial material layers 142 may be subsequently replaced with electrically conductive electrodes which may function, for example, as control gate electrodes of a vertical NAND device. In one embodiment, the first-tier sacrificial material layers 142 may comprise silicon nitride.

Generally, a vertically alternating sequence of unit layer stacks over a substrate. Each of the unit layer stacks comprises a first insulating layer (such as a first insulating layer 132) and a first spacer material layer (such as a first-tier sacrificial material layer 142). Generally, the first spacer material layers are formed as, or are subsequently replaced with, first-tier electrically conductive layers. While the present disclosure is described employing an embodiment in which the first spacer material layers are formed as first-tier sacrificial material layers 142 that are subsequently replaced with first-tier electrically conductive layers, embodiments are expressly contemplated herein in which the first spacer material layers are formed as first-tier electrically conductive layers. In such embodiments, steps for replacing the material of the first spacer material layers with an electrically conductive material can be omitted.

A first-tier insulating cap layer 170 can be formed over the first vertically alternating sequence (132, 142). The first-tier insulating cap layer 170 comprises an insulating material, which may be the same material as the material of the first-tier insulating layers 132. First stepped surfaces can be formed within the staircase regions of the inter-array region 200 by patterning the first-tier insulating cap layer 170 and the first vertically alternating sequence (132, 142). For example, a combination of a sacrificial hard mask layer and a trimming mask layer may be employed to form the first stepped surfaces. In one embodiment, a row of multiple first staircase regions can be formed within each area that corresponds to a combination of the area of a laterally-neighboring pair of first-tier retro-stepped dielectric material portions 165 and an intervening area. In this case, the multiple first staircase regions can be vertically offset by different depths by subsequently performing area recess etch processes.

In an illustrative example, 2^{M} sets of first stepped surfaces can be formed within a combination of the area of a laterally-neighboring pair of first-tier retro-stepped dielectric material portions 165 and an intervening area. M can be an integer in a range from 1 to 8. Each set of first stepped staircases may include P steps such that sidewalls of P first continuous spacer material layers are physically exposed with lateral offsets. P may be an integer from 2 to 64. M area recess etch processes can be performed such that each area recess etch process vertically recesses P times 2ⁱ sets of a first insulating layer 132 and a first-tier sacrificial material layer 142, in which i is a different integer from 0 to (M−1). A total of up to 2^{M}×P stepped surfaces can be formed for the first vertically alternating sequence of the first-tier insulating layers 132 and the first-tier sacrificial material layers 142. The total number of the stepped surfaces within each continuous cavity overlying the first stepped surfaces can be the same as the total number of the first-tier sacrificial material layers 142 in the first vertically alternating sequence (132, 142).

A first-tier stepped cavity 169 can be formed over each contiguous set of stepped surfaces of the first vertically alternating sequence (132, 142). The lateral extents of the first-tier sacrificial material layers 142 vary with a vertical distance from the substrate 9. Generally, an alternating stack (32, 42) of insulating layers 32 and sacrificial material layers 42 may be formed over a substrate 9, and stepped surfaces can be formed by patterning the alternating stack (32, 42) such that lateral extents of the sacrificial material layers 42 vary with a vertical distance from the substrate 9 in a staircase region.

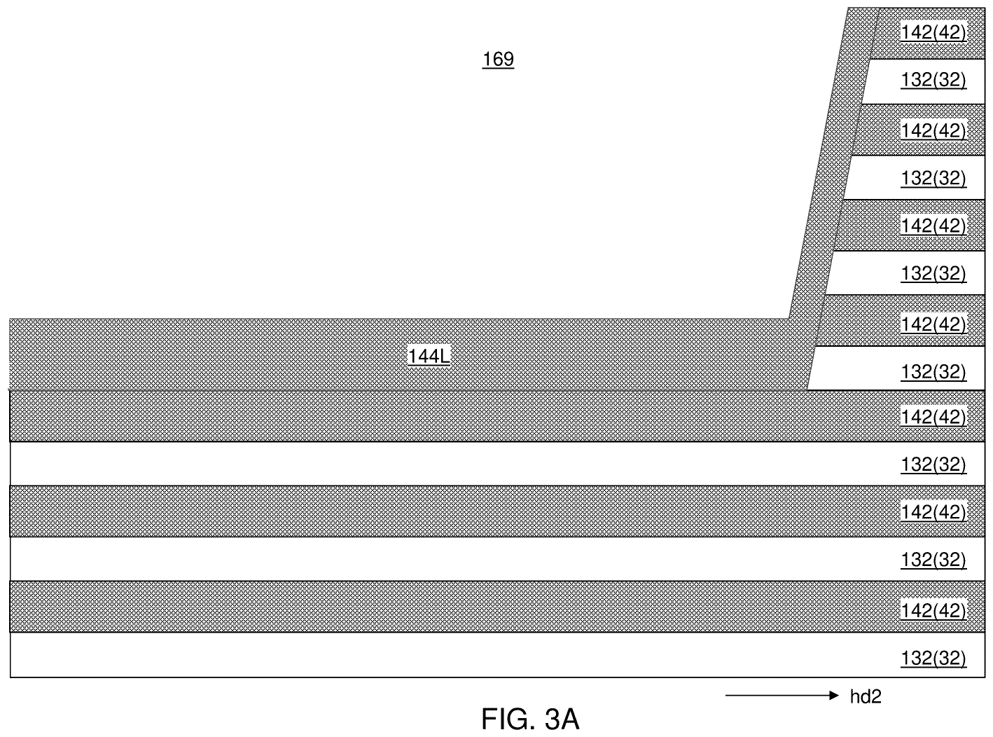

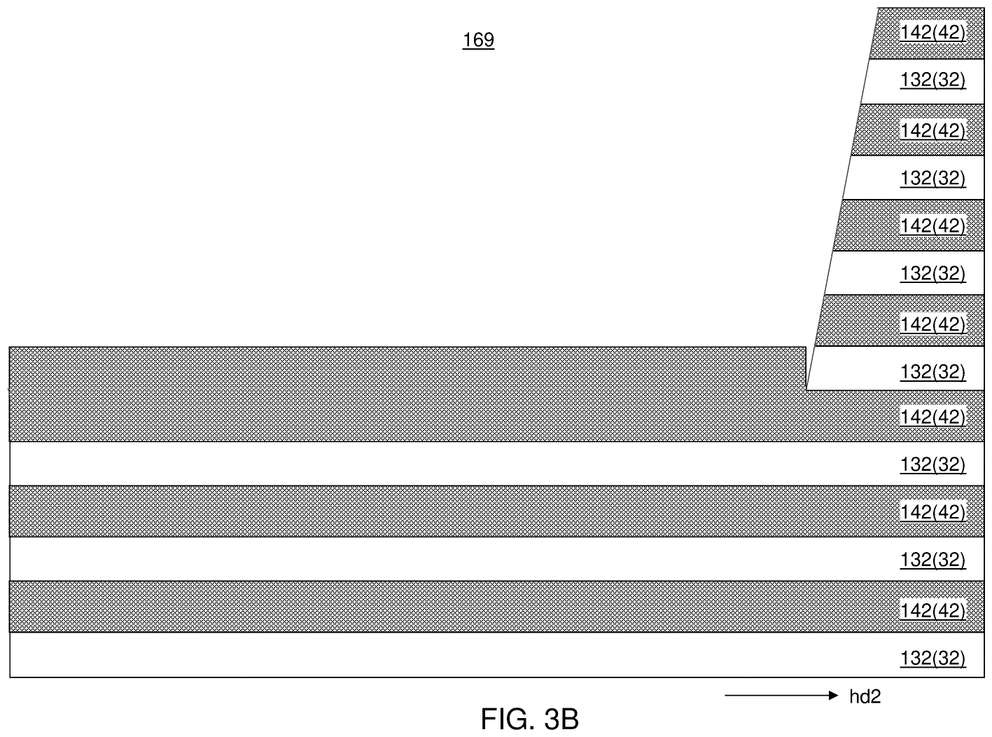

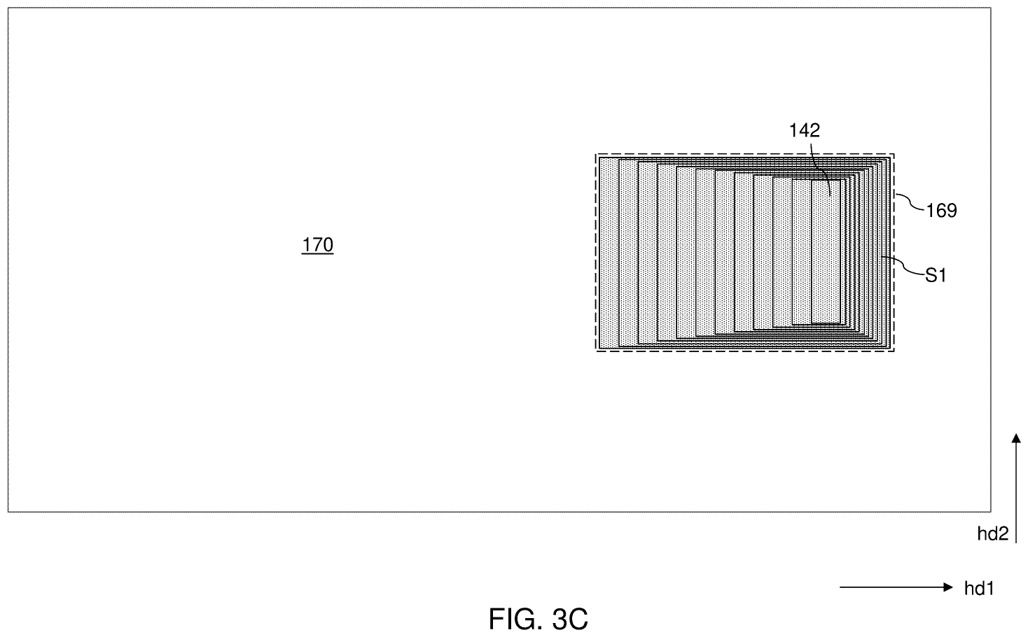

Referring to FIG. 3A, an anisotropic material deposition process can be performed to anisotropically deposit a same material as the material of the first-tier sacrificial material layers 142 to form a non-conformal sacrificial material layer 144L. In one embodiment, the first-tier sacrificial material layers 142 comprise silicon nitride, and the anisotropic material deposition process may deposit a silicon nitride material anisotropically. The non-conformal sacrificial material layer 144L is deposited by a non-conformal deposition process such as a plasma-enhanced chemical vapor deposition (PECVD) process. Preferably, the deposition of the sacrificial material of the non-conformal sacrificial material layer 144L is highly anisotropic such that the thickness of each horizontally-extending portion of the non-conformal sacrificial material layer 144L is greater than (e.g., at least twice) the thickness of non-horizontally-extending portions of the non-conformal sacrificial material layer 144L. In one embodiment the thickness of the horizontally-extending portions of the non-conformal sacrificial material layer 144L may be in a range from 50% to 300% of the thickness of each first-tier sacrificial material layer 142.

Referring to FIG. 3B, an isotropic etch process can be performed to isotropically recess the non-conformal sacrificial material layer 144L. The duration of the isotropic etch process can be selected such that the non-horizontally-extending portions of the non-conformal sacrificial material layer 144L are removed by the isotropic etch process. Remaining horizontally-extending portions of the non-conformal sacrificial material layer 144L overlying a top surface segment of a respective one of the first-tier sacrificial material layers 142 can be incorporated into the respective one of the first-tier sacrificial material layers 142.

Thus, physically-exposed portions of the sacrificial material layers 42 (such as the first-tier sacrificial material layers 142) in the staircase region can be thickened such that the thickened portions of the sacrificial material layers 142 has a thickness in a range form 125% to 250%, such as from 150% to 200%, of the unthickened portion of the first-tier sacrificial material layers 142 (which is the same as the original thickness of each first-tier sacrificial material layers 142). While an embodiment is described in which physically exposed portions of the first-tier sacrificial material layers 142 are locally thickened by anisotropic deposition and isotropic etch-back of a sacrificial material, the physically exposed portions of the first-tier sacrificial material layers 142 may be locally thickened by alternative methods that can selectively increase the thickness of physically exposed portions of the first-tier sacrificial material layers 142.

Referring to FIG. 3C, portions of the non-conformal sacrificial material layer 144L that are deposited outside the areas of the first-tier stepped cavities 169 can be removed, for example, by covering the areas of the first-tier stepped cavities 169 with patterned photoresist materials, and by performing an etch process that etches unmasked portions of the material of the non-conformal sacrificial material layer 144L. First vertical steps S1 of the first stepped surfaces that are perpendicular to the first horizontal direction hd1 are illustrated.

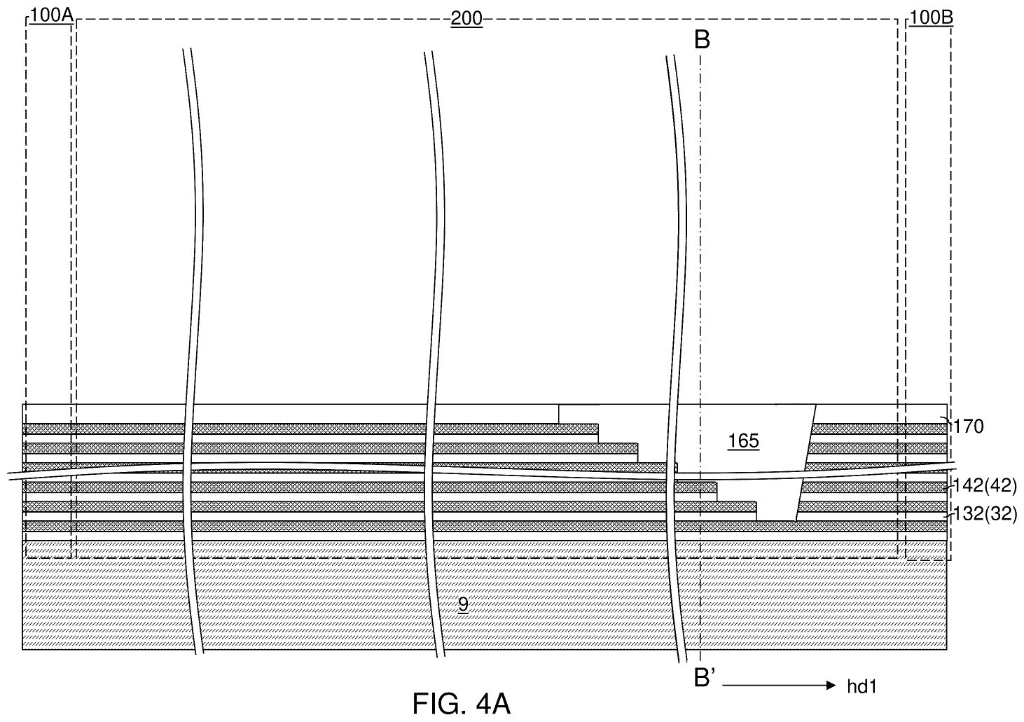

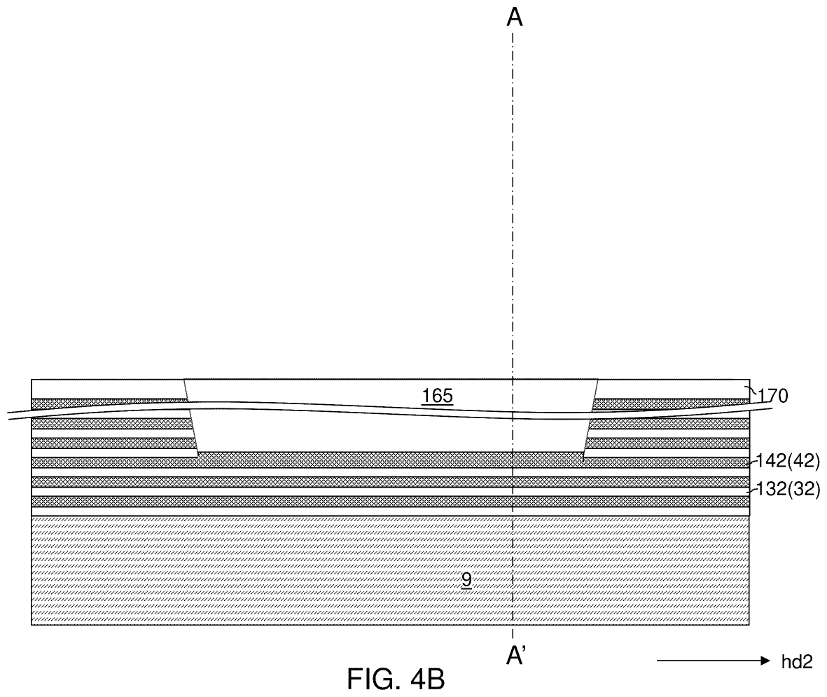

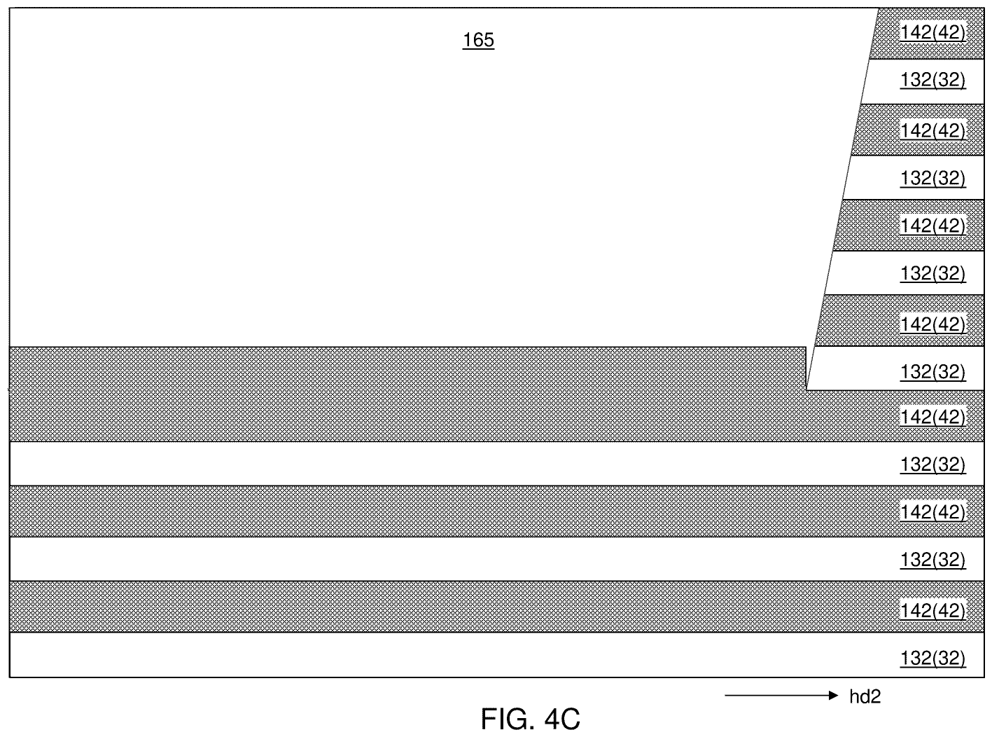

Referring to FIGS. 4A-4C, a first dielectric fill material (such as undoped silicate glass (i.e., silicon oxide) or a doped silicate glass) can be deposited in each first-tier stepped cavity 169. The first dielectric fill material can be planarized to remove excess portions of the first dielectric fill material from above the horizontal plane including the topmost surface of the first vertically alternating sequence (132, 142). Each remaining portion of the first dielectric fill material that fills a respective first-tier stepped cavity 169 constitutes a first-tier retro-stepped dielectric material portion 165. Generally, the first-tier retro-stepped dielectric material portions 165 can be formed in inter-array regions 200 located between a respective first memory array region 100A and a respective second memory array region 100B that are laterally spaced apart along the first horizontal direction hd1. The planar top surface of each first-tier retro-stepped dielectric material portion 165 can be located within a horizontal plane including the top surface of the first-tier insulating cap layer 170.

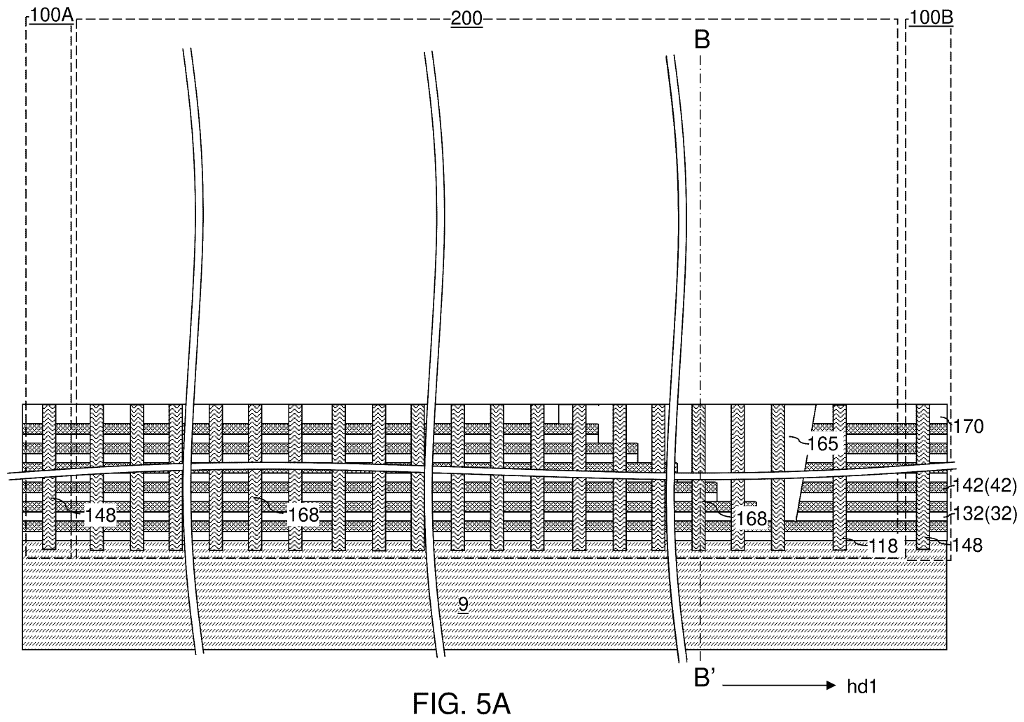

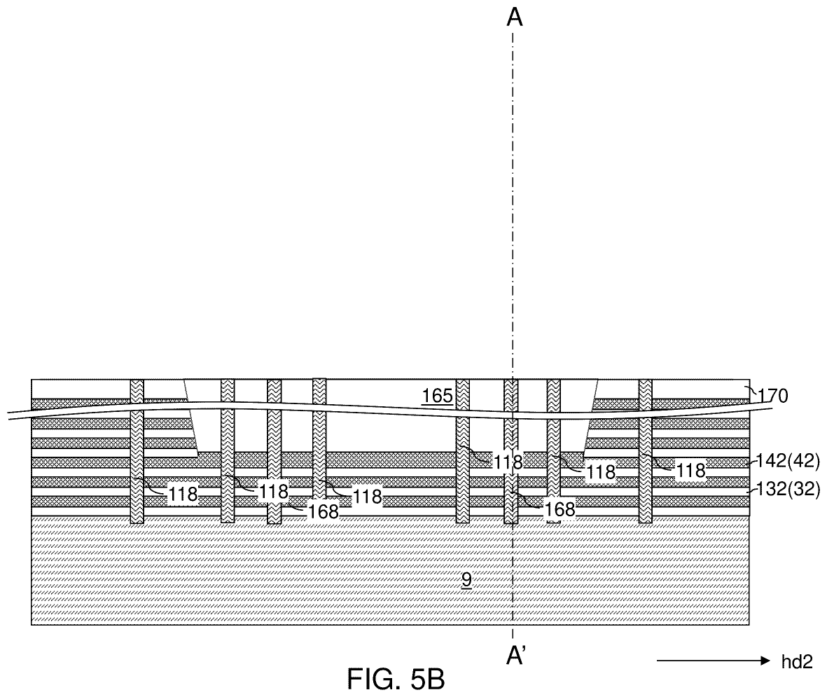

Referring to FIGS. 5A and 5B, various first-tier openings may be formed through the first vertically alternating sequence (132, 142) and into the substrate 9. A photoresist layer (not shown) may be applied over the first vertically alternating sequence (132, 142), and may be lithographically patterned to form various openings therethrough. The pattern of openings in the photoresist layer may be transferred through the first vertically alternating sequence (132, 142) and into the substrate 9 by a first anisotropic etch process to form the various first-tier openings concurrently, i.e., during the first isotropic etch process. The various first-tier openings may include first-tier memory openings formed in the memory array regions 100 and first-tier support openings formed in the inter-array regions 200, and first-tier contact openings formed in the staircase regions (which are located within the inter-array regions 200). Each cluster of first-tier memory openings may be formed as a two-dimensional array of first-tier memory openings. The first-tier support openings are openings that are formed in the inter-array region 200, and are subsequently employed to form support pillar structures. Each first-tier contact opening is formed in a respective area in which a respective layer contact via structure 86 is to be subsequently formed. A subset of the first-tier support openings may be formed through a respective horizontally-extending surface segment of the first stepped surfaces. A subset of the first-tier contact openings is formed through a respective horizontally-extending surface segment of the first stepped surfaces.

According to an embodiment of the present disclosure, each first-tier sacrificial material layer 142 comprises a respective locally thickened portion underneath each first-tier retro-stepped dielectric material portion 165. Each of the first-tier contact openings can be formed through a locally thickened portion of a respective first-tier sacrificial material layer 142.

Sacrificial first-tier opening fill structures (148, 118, 168) may be formed in the various first-tier openings. For example, a sacrificial first-tier fill material is concurrently deposited in each of the first-tier openings. The sacrificial first-tier fill material includes a material that may be subsequently removed selective to the materials of the first-tier insulating layers 132 and the first-tier sacrificial material layers 142. In one embodiment, the sacrificial first-tier fill material may include a semiconductor material such as silicon (e.g., a-Si or polysilicon), a silicon-germanium alloy, germanium, a III-V compound semiconductor material, or a combination thereof. Optionally, a thin etch stop liner (such as a silicon oxide layer or a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In another embodiment, the sacrificial first-tier fill material may include a silicon oxide material having a higher etch rate than the material of the first-tier insulating layers 132. For example, the sacrificial first-tier fill material may include borosilicate glass or porous or non-porous organosilicate glass having an etch rate that is at least 100 times higher than the etch rate of densified TEOS oxide (i.e., a silicon oxide material formed by decomposition of tetraethylorthosilicate glass in a chemical vapor deposition process and subsequently densified in an anneal process) in a 100:1 dilute hydrofluoric acid. In this case, a thin etch stop liner (such as a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In yet another embodiment, the sacrificial first-tier fill material may include carbon-containing material (such as amorphous carbon or diamond-like carbon) that may be subsequently removed by ashing, or a silicon-based polymer that may be subsequently removed selective to the materials of the first vertically alternating sequence (132, 142).

Portions of the deposited sacrificial first-tier fill material may be removed from above the topmost layer of the first vertically alternating sequence (132, 142), such as from above the first-tier insulating cap layer 170. For example, the sacrificial first-tier fill material may be recessed to a top surface of the first-tier insulating cap layer 170 using a planarization process. The planarization process may include a recess etch, chemical mechanical planarization (CMP), or a combination thereof. The top surface of the first-tier insulating cap layer 170 may be used as an etch stop layer or a planarization stop layer.

Remaining portions of the sacrificial first-tier fill material comprise sacrificial first-tier opening fill structures (148, 118, 168). Specifically, each remaining portion of the sacrificial first-tier fill material in a first-tier memory opening constitutes a sacrificial first-tier memory opening fill structure 148. Each remaining portion of the sacrificial first-tier fill material in a first-tier support opening constitutes a sacrificial first-tier support opening fill structure 118. Each remaining portion of the sacrificial first-tier fill material in a first-tier contact opening constitutes a sacrificial first-tier contact opening fill structure 168. The various sacrificial first-tier opening fill structures (148, 118, 168) are concurrently formed, i.e., during a same set of processes including the deposition process that deposits the sacrificial first-tier fill material and the planarization process that removes the first-tier deposition process from above the first vertically alternating sequence (132, 142) (such as from above the top surface of the first-tier insulating cap layer 170). The top surfaces of the sacrificial first-tier opening fill structures (148, 118, 168) may be coplanar with the top surface of the first-tier insulating cap layer 170. Each of the sacrificial first-tier opening fill structures (148, 118, 168) may, or may not, include cavities therein. The set of all structures located between the bottommost surface of the first vertically alternating sequence (132, 142) and the topmost surface of the first vertically alternating sequence (132, 142) or embedded within the first vertically alternating sequence (132, 142) constitutes a first-tier structure.

According to an aspect of the present disclosure, each first-tier sacrificial material layer 142 comprises a respective locally thickened portion underneath each first-tier retro-stepped dielectric material portion 165. Each of the first-tier contact openings can be formed through a locally thickened portion of a respective first-tier sacrificial material layer 142. Accordingly, each of the sacrificial first-tier contact opening fill structures 168 can be formed through a locally thickened portion of a respective first-tier sacrificial material layer 142. The sacrificial first-tier contact opening fill structures 168 may vertically extend from a horizontal plane including a top surface of the first-tier alternating stack (132, 142) at least to a horizontal plane including a bottom surface of the first-tier alternating stack (132, 142).

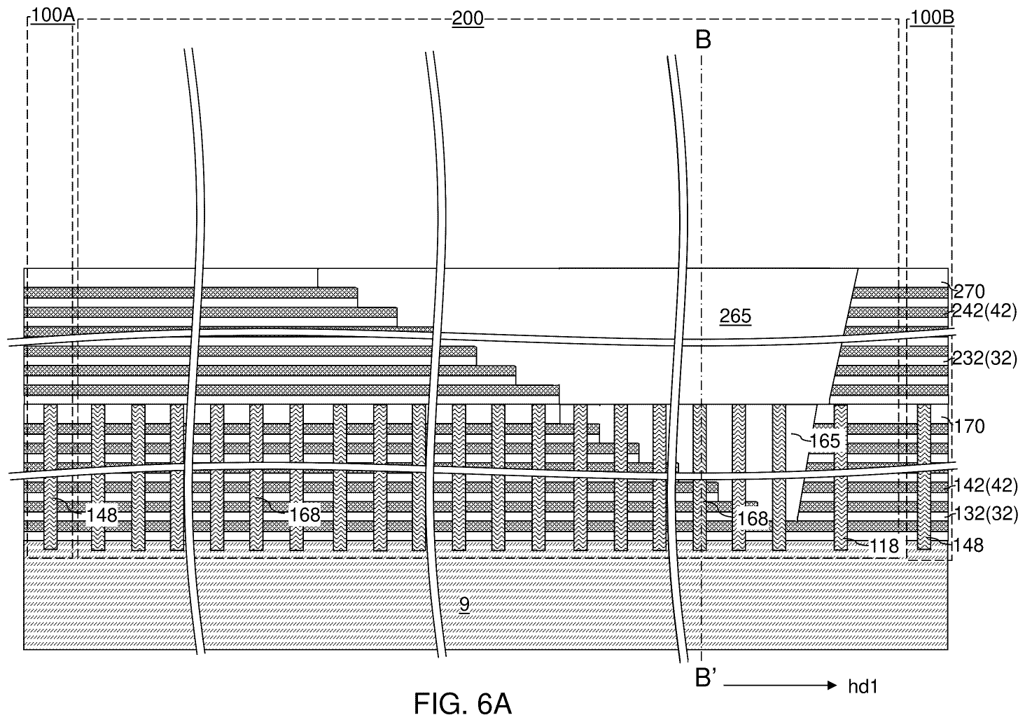

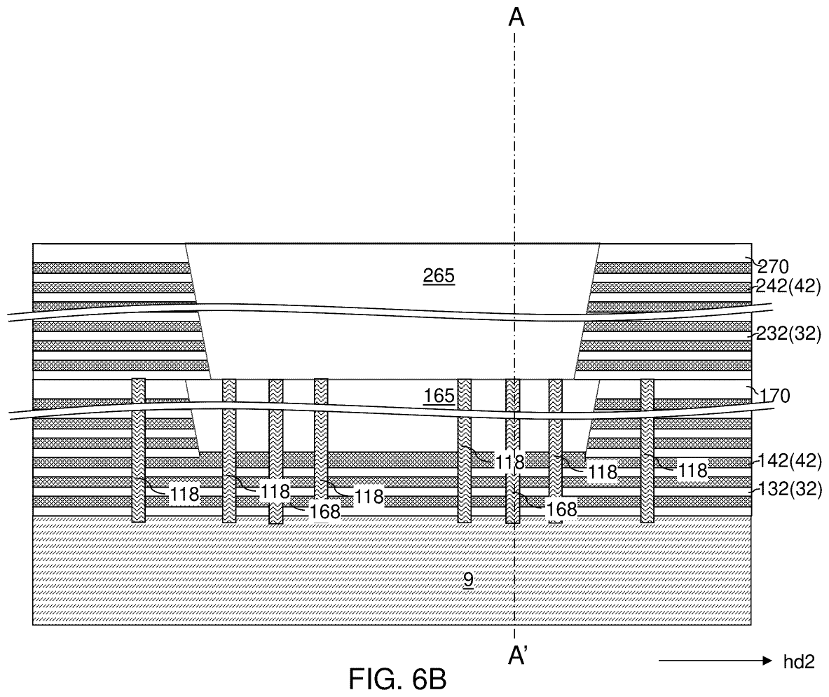

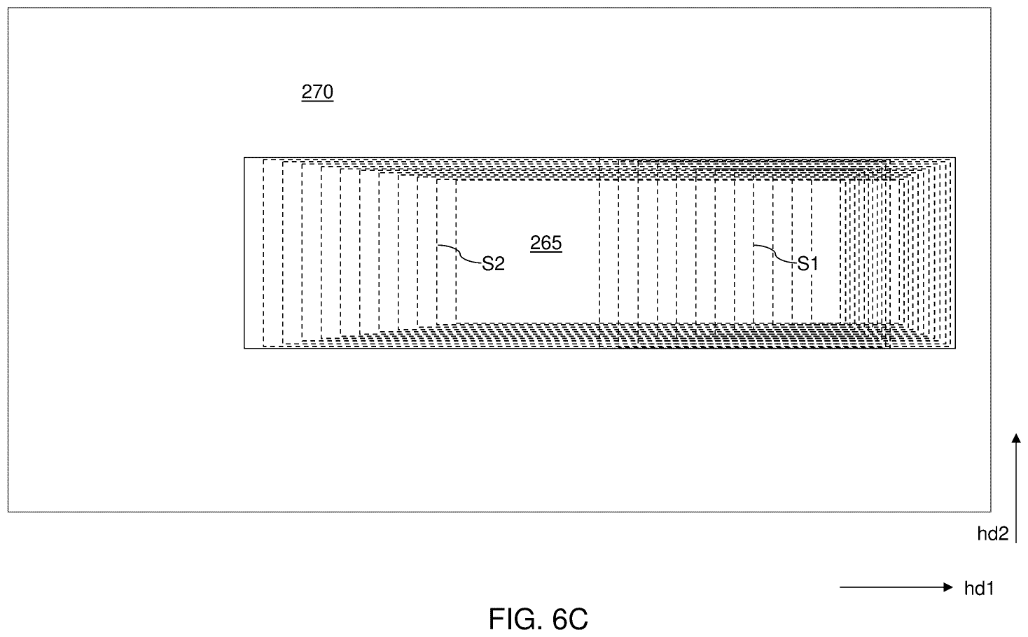

Referring to FIGS. 6A-6C, a second vertically alternating sequence of second-tier insulating layers 232 and second-tier sacrificial material layers 242 can be formed. Each of the second-tier insulating layers 232 is an insulating layer 32 that continuously extends over the entire area of the substrate 8, and may have a uniform thickness throughout. Each of the second-tier sacrificial material layers 242 is a sacrificial material layer 42 that includes a dielectric material and continuously extends over the entire area of the substrate 8, and may have a uniform thickness throughout. The second-tier insulating layers 232 can have the same material composition and the same thickness as the first-tier insulating layers 132. The second-tier sacrificial material layers 242 can have the same material composition and the same thickness as the first-tier sacrificial material layers 142. A second-tier insulating cap layer 270 can be formed over the second vertically alternating sequence (232, 242).

Second stepped surfaces can be formed within the staircase regions of the inter-array region 200 which will be filled with the second-tier retro-stepped dielectric material portions 265. For example, a combination of a sacrificial hard mask layer and a trimming mask layer may be employed to form the second stepped surfaces. Generally, the processing steps described with reference to FIGS. 2A-2C can be performed to form second-tier stepped cavities, under which a respective set of second stepped surfaces of the second vertically alternating sequence (232, 242) are exposed. Each set of second stepped surfaces may be laterally offset relative to an adjacent and underling set of first stepped surfaces of the first vertically alternating sequence (132, 142) along the first horizontal direction hd1.

In an illustrative example, 2^{N} sets of second stepped surfaces can be formed within a combination of the area of a laterally-neighboring pair of second-tier retro-stepped dielectric material portions 265 and an intervening area. N can be an integer in a range from 2 to 8. Each set of second stepped staircases may include P steps such that sidewalls of Q second continuous spacer material layers are physically exposed with lateral offsets. Q may be an integer from 2 to 64. M area recess etch processes can be performed such that each area recess etch process vertically recesses Q times 2 sets of a second insulating layer 232 and a second-tier sacrificial material layer 242, in which j is a different integer from 0 to (N−1). A total of up to 2^{N}×Q stepped surfaces can be formed for the second vertically alternating sequence of the second-tier insulating layers 232 and the second-tier sacrificial material layers 242. The total number of the stepped surfaces within each continuous cavity overlying the second stepped surfaces can be the same as the total number of the second-tier sacrificial material layers 242 in the second vertically alternating sequence (132, 242).

The processing steps described with reference to FIGS. 3A-3C can be performed with suitable modifications in the masking pattern to optionally locally thicken physically exposed portions of the second-tier sacrificial material layers 242 in each second-tier stepped cavity. A second dielectric fill material (such as undoped silicate glass (i.e., silicon oxide) or a doped silicate glass) can be deposited in each second-tier stepped cavity. The second dielectric fill material can be planarized to remove excess portions of the second dielectric fill material from above the horizontal plane including the topmost surface of the second vertically alternating sequence (232, 242). Each remaining portion of the second dielectric fill material that fills a respective second continuous retro-stepped cavity constitutes a second-tier retro-stepped dielectric material portion 265. First vertical steps S1 of the first stepped surfaces that underlie the first-tier retro-stepped dielectric material portion 165 and second vertical steps S2 of the second stepped surfaces that underlie the second-tier retro-stepped dielectric material portion 265 are illustrated. The second vertical steps S2 are perpendicular to the first horizontal direction hd1. Generally, a second-tier structure is formed, which comprises a second vertically alternating sequence of second-tier insulating layers 232 and second-tier sacrificial material layers 242 and second-tier retro-stepped dielectric material portions 265 overlying second stepped surfaces of the second vertically alternating sequence that are located in the inter-array regions 200.

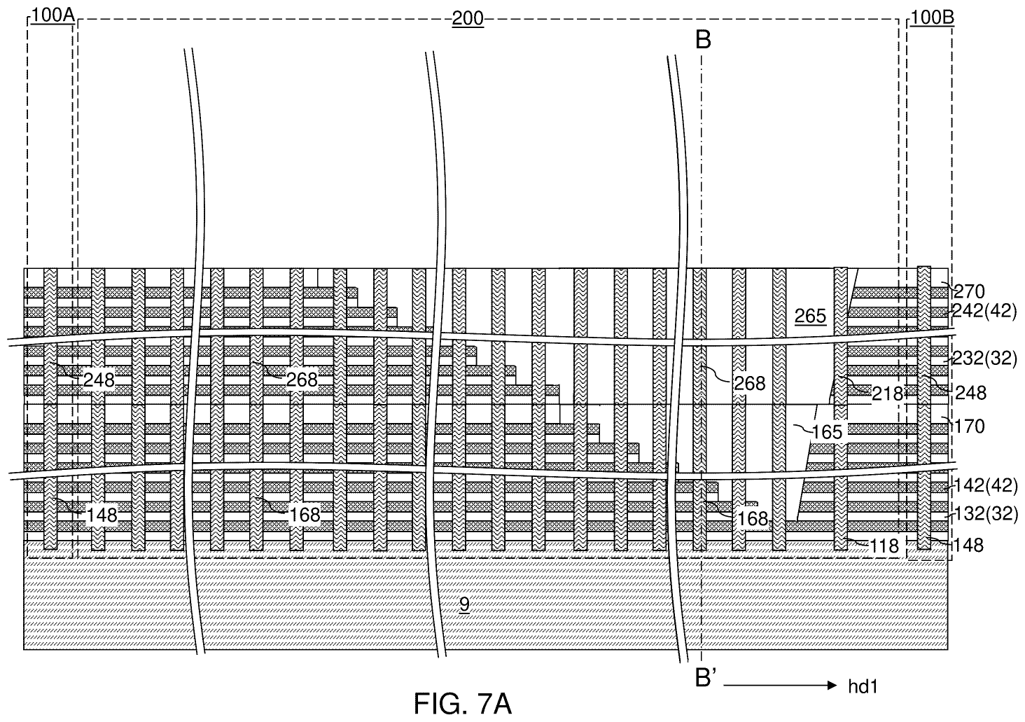

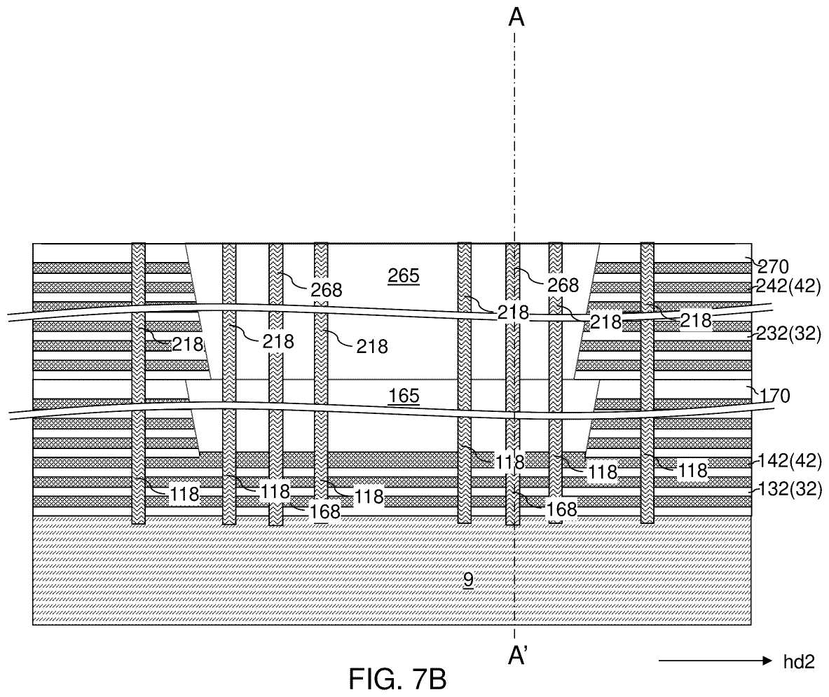

Referring to FIGS. 7A and 7B, various second-tier openings may be formed through the second vertically alternating sequence (232, 242) and over the sacrificial first-tier opening fill structures (148, 118, 168). A photoresist layer (not shown) may be applied over the second vertically alternating sequence (232, 242), and may be lithographically patterned to form various openings therethrough. The pattern of openings in the photoresist layer may be transferred through the second vertically alternating sequence (232, 242) to form the various second-tier openings concurrently, i.e., during the second isotropic recess etch process.

The various second-tier openings may include second-tier memory openings formed in the memory array regions 100, second-tier support openings formed in the inter-array region 200, and second-tier contact openings formed in the staircase region which is located within the inter-array region 200. Each second-tier opening may be formed within the area of a respective one of the sacrificial first-tier opening fill structures (148, 118, 168). Thus, a top surface of a sacrificial first-tier opening fill structure can be physically exposed at the bottom of each second-tier opening. Specifically, each second-tier memory openings can be formed directly over a respective sacrificial first-tier memory opening fill structure 148, each second-tier support opening can be formed directly over a respective sacrificial first-tier support opening fill structure 118, and each second-tier contact opening can be formed directly over a respective sacrificial first-tier contact opening fill structure 168.

Each cluster of second-tier memory openings may be formed as a two-dimensional array of second-tier memory openings. The second-tier support openings are openings that are formed in the inter-array region 200, and are subsequently employed to form support pillar structures. A subset of the second-tier support openings may be formed through a respective horizontally-extending surface segment of the second stepped surfaces. A subset of the second-tier contact openings may be formed through a respective horizontally-extending surface segment of the second stepped surfaces.

Sacrificial second-tier opening fill structures may be formed in the various second-tier openings. For example, a sacrificial first-tier fill material is concurrently deposited in each of the second-tier openings. The sacrificial second-tier fill material can include any material that may be employed for the sacrificial first-tier fill material. Portions of the deposited sacrificial second-tier fill material may be removed from above the topmost layer of the second vertically alternating sequence (232, 242). Remaining portions of the sacrificial second-tier fill material comprise sacrificial second-tier opening fill structures (248, 218, 268).

Specifically, each remaining portion of the sacrificial second-tier fill material in a second-tier memory opening constitutes a sacrificial second-tier memory opening fill structure 248. Each remaining portion of the sacrificial second-tier fill material in a second-tier support opening constitutes a sacrificial second-tier support opening fill structure 218. Each remaining portion of the sacrificial second-tier fill material in a second-tier contact opening constitutes a sacrificial second-tier contact opening fill structure 268. The top surfaces of the sacrificial second-tier opening fill structures (248, 218, 268) may be coplanar with the top surface of the second-tier insulating cap layer 270. Each of the sacrificial second-tier opening fill structures may, or may not, include cavities therein. The set of all structures located between the bottommost surface of the second vertically alternating sequence (232, 242) and the topmost surface of the second vertically alternating sequence (232, 242) or embedded within the second vertically alternating sequence (232, 242) constitutes a second-tier structure.

According to an aspect of the present disclosure, each second-tier sacrificial material layer 242 comprises a respective locally thickened portion underneath each second-tier retro-stepped dielectric material portion 265. Each of the second-tier contact openings can be formed through a locally thickened portion of a respective second-tier sacrificial material layer 242. Accordingly, each of the sacrificial second-tier contact opening fill structures 268 can be formed through a locally thickened portion of a respective second-tier sacrificial material layer 242. The sacrificial second-tier contact opening fill structures 268 may vertically extend from a horizontal plane including a top surface of the second-tier alternating stack (232, 242) at least to a horizontal plane including a bottom surface of the second-tier alternating stack (232, 242).

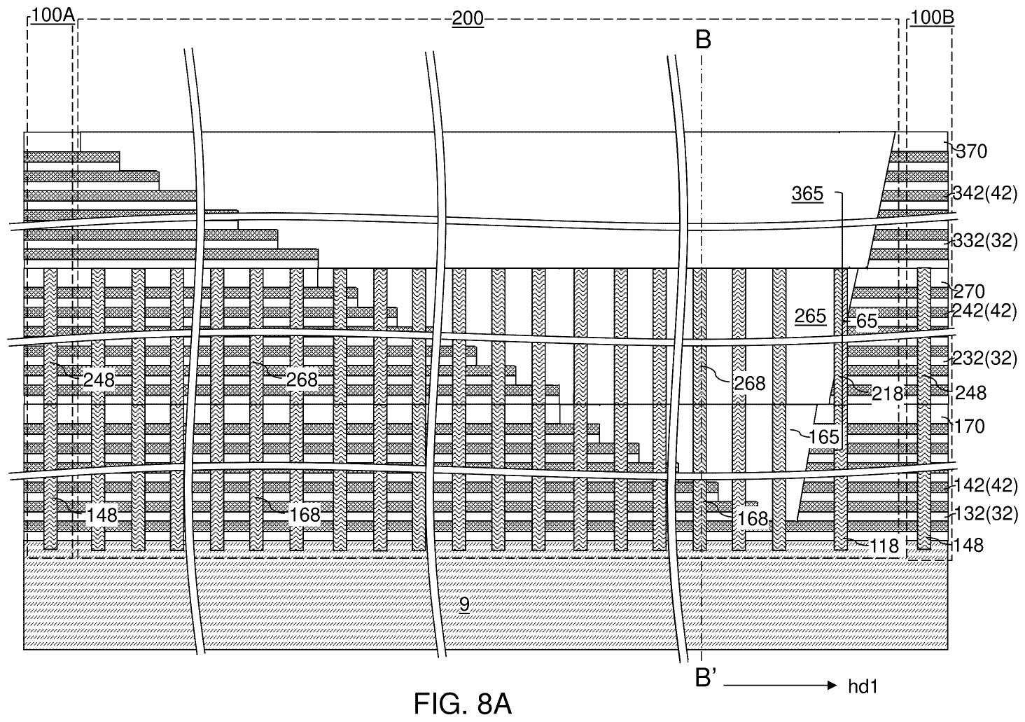

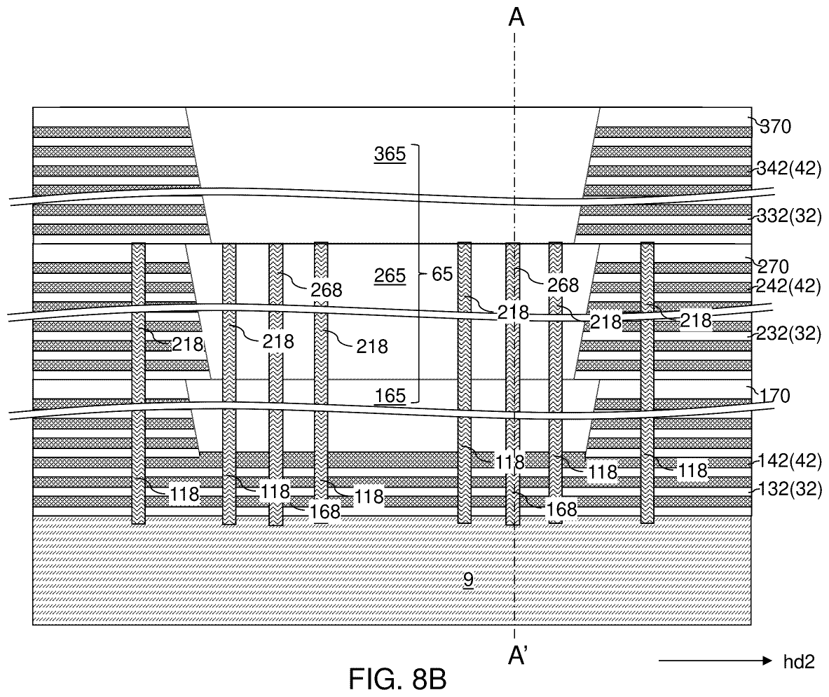

Referring to FIGS. 8A and 8B, a third vertically alternating sequence of third-tier insulating layers 332 and third-tier sacrificial material layers 342 can be formed. Each of the third-tier insulating layers 332 is an insulating layer 32 that continuously extends over the entire area of the substrate 8, and may have a uniform thickness throughout. Each of the third-tier sacrificial material layers 342 is a sacrificial material layer 42 that includes a dielectric material and continuously extends over the entire area of the substrate 8, and may have a uniform thickness throughout. The third-tier insulating layers 332 can have the same material composition and the same thickness as the first-tier insulating layers 132. The third-tier sacrificial material layers 342 can have the same material composition and the same thickness as the first-tier sacrificial material layers 142. A third-tier insulating cap layer 370 can be formed over the third vertically alternating sequence (332, 342).

Third stepped surfaces can be formed within the staircase regions of the inter-array region 200 which will be filled with the third-tier retro-stepped dielectric material portions 365. For example, a combination of a sacrificial hard mask layer and a trimming mask layer may be employed to form the third stepped surfaces. Generally, the processing steps described with reference to FIGS. 2A-2C can be performed to form third-tier stepped cavities, under which a respective set of third stepped surfaces of the third vertically alternating sequence (332, 342) are exposed. Each set of third stepped surfaces may be laterally offset relative to an adjacent and underling set of second stepped surfaces of the second vertically alternating sequence (232, 242) and relative to an adjacent and underlying set of first stepped surfaces of the first vertically alternating sequence (132, 142) along the first horizontal direction hd1.

The processing steps described with reference to FIGS. 3A-3C can be performed with suitable modifications in the masking pattern to locally thicken physically exposed portions of the third-tier sacrificial material layers 342 in each third-tier stepped cavity. A third dielectric fill material (such as undoped silicate glass (i.e., silicon oxide) or a doped silicate glass) can be deposited in each third-tier stepped cavity. The third dielectric fill material can be planarized to remove excess portions of the second dielectric fill material from above the horizontal plane including the topmost surface of the third-tier insulating cap layer 370. Each remaining portion of the third dielectric fill material that fills a respective third continuous retro-stepped cavity constitutes a third-tier retro-stepped dielectric material portion 365.

A third dielectric fill material (such as undoped silicate glass (i.e., silicon oxide) or a doped silicate glass) can be deposited in each third continuous retro-stepped cavity. The third dielectric fill material can be planarized to remove excess portions of the third dielectric fill material from above the horizontal plane including the topmost surface of the third vertically alternating sequence (332, 342). Each remaining portion of the third dielectric fill material that fills a respective third continuous retro-stepped cavity constitutes a third-tier retro-stepped dielectric material portion 365.

Generally, a third-tier structure is formed, which comprises a third vertically alternating sequence of third-tier insulating layers 332 and third-tier sacrificial material layers 342 and third-tier retro-stepped dielectric material portions 365 overlying third stepped surfaces of the third vertically alternating sequence that are located in the inter-array regions 200.

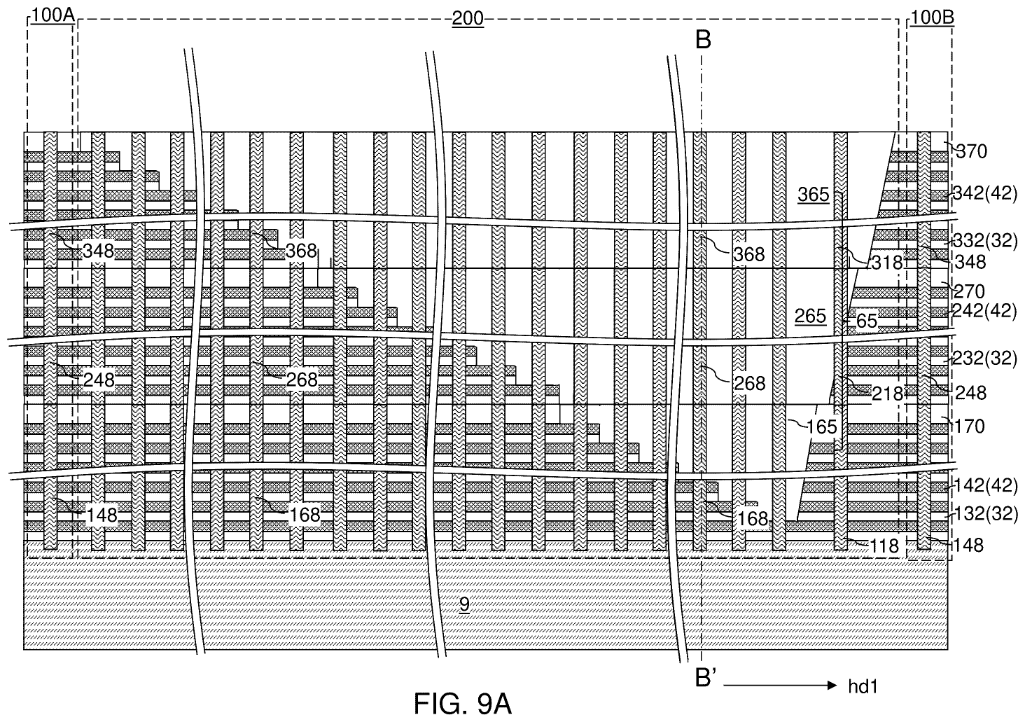

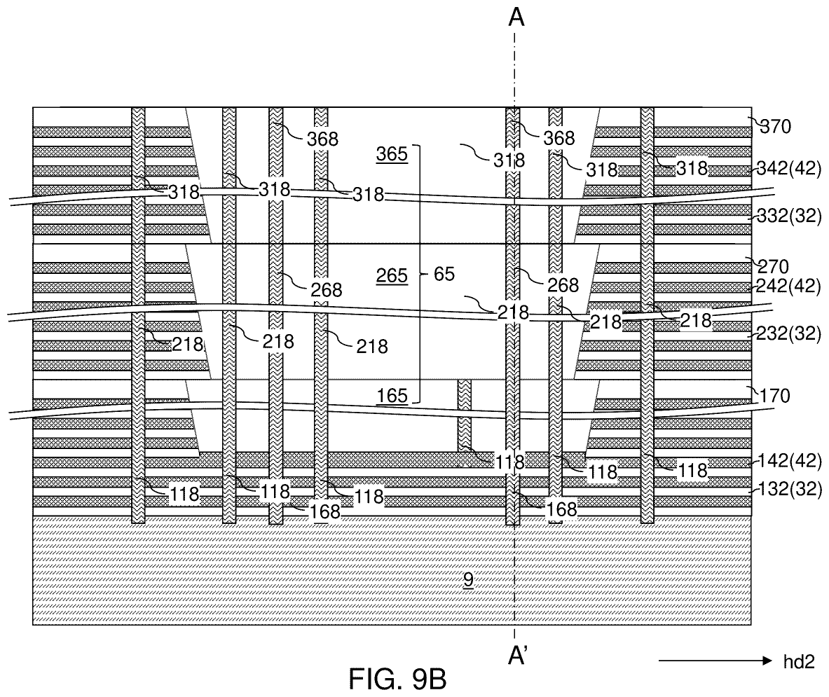

Referring to FIGS. 9A and 9B, various third-tier openings may be formed through the third vertically alternating sequence (332, 342) and over the sacrificial second-tier opening fill structures (248, 218, 268). A photoresist layer (not shown) may be applied over the third vertically alternating sequence (332, 342), and may be lithographically patterned to form various openings therethrough. The pattern of openings in the photoresist layer may be transferred through the third vertically alternating sequence (332, 342) to form the various third-tier openings concurrently, i.e., during the third isotropic etch process.

The various third-tier openings may include third-tier memory openings formed in the memory array regions 100, third-tier support openings formed in the inter-array region 200, and third-tier contact openings formed in the staircase region which is located within the inter-array region 200. Each third-tier opening may be formed within the area of a respective one of the sacrificial second-tier opening fill structures (248, 218, 268). Thus, a top surface of a sacrificial second-tier opening fill structure can be physically exposed at the bottom of each third-tier opening. Specifically, each third-tier memory openings can be formed directly over a respective sacrificial second-tier memory opening fill structure 248, each third-tier support opening can be formed directly over a respective sacrificial second-tier support opening fill structure 218, and each third-tier contact opening can be formed directly over a respective sacrificial second-tier contact opening fill structure 268. Each cluster of third-tier memory openings may be formed as a two-dimensional array of third-tier memory openings. The third-tier support openings are openings that are formed in the inter-array region 200, and are subsequently employed to form support pillar structures. A subset of the third-tier support openings may be formed through a respective horizontally-extending surface segment of the third stepped surfaces. A subset of the third-tier contact openings may be formed through a respective horizontally-extending surface segment of the third stepped surfaces.

Sacrificial third-tier opening fill structures may be formed in the various third-tier openings. For example, a sacrificial second-tier fill material is concurrently deposited in each of the third-tier openings. The sacrificial third-tier fill material can include any material that may be employed for the sacrificial second-tier fill material. Portions of the deposited sacrificial third-tier fill material may be removed from above the topmost layer of the third vertically alternating sequence (332, 342). Remaining portions of the sacrificial third-tier fill material comprise sacrificial third-tier opening fill structures (348, 318, 368). Specifically, each remaining portion of the sacrificial third-tier fill material in a third-tier memory opening constitutes a sacrificial third-tier memory opening fill structure 348. Each remaining portion of the sacrificial third-tier fill material in a third-tier support opening constitutes a sacrificial third-tier support opening fill structure 318. Each remaining portion of the sacrificial third-tier fill material in a third-tier contact opening constitutes a sacrificial third-tier contact opening fill structure 368. The top surfaces of the sacrificial third-tier opening fill structures (348, 318, 368) may be coplanar with the top surface of the third-tier insulating cap layer 370. Each of the sacrificial third-tier opening fill structures may, or may not, include cavities therein. The set of all structures located between the bottommost surface of the third vertically alternating sequence (332, 342) and the topmost surface of the third vertically alternating sequence (332, 342) or embedded within the third vertically alternating sequence (332, 342) constitutes a third-tier structure.

According to an aspect of the present disclosure, each third-tier sacrificial material layer 342 optionally comprises a respective locally thickened portion underneath each third-tier retro-stepped dielectric material portion 365. Each of the third-tier contact openings can be formed through a locally thickened portion of a respective third-tier sacrificial material layer 342. Accordingly, each of the sacrificial third-tier contact opening fill structures 368 can be formed through a locally thickened portion of a respective third-tier sacrificial material layer 342. The sacrificial third-tier contact opening fill structures 368 may vertically extend from a horizontal plane including a top surface of the third-tier alternating stack (332, 342) at least to a horizontal plane including a bottom surface of the third-tier alternating stack (332, 342).

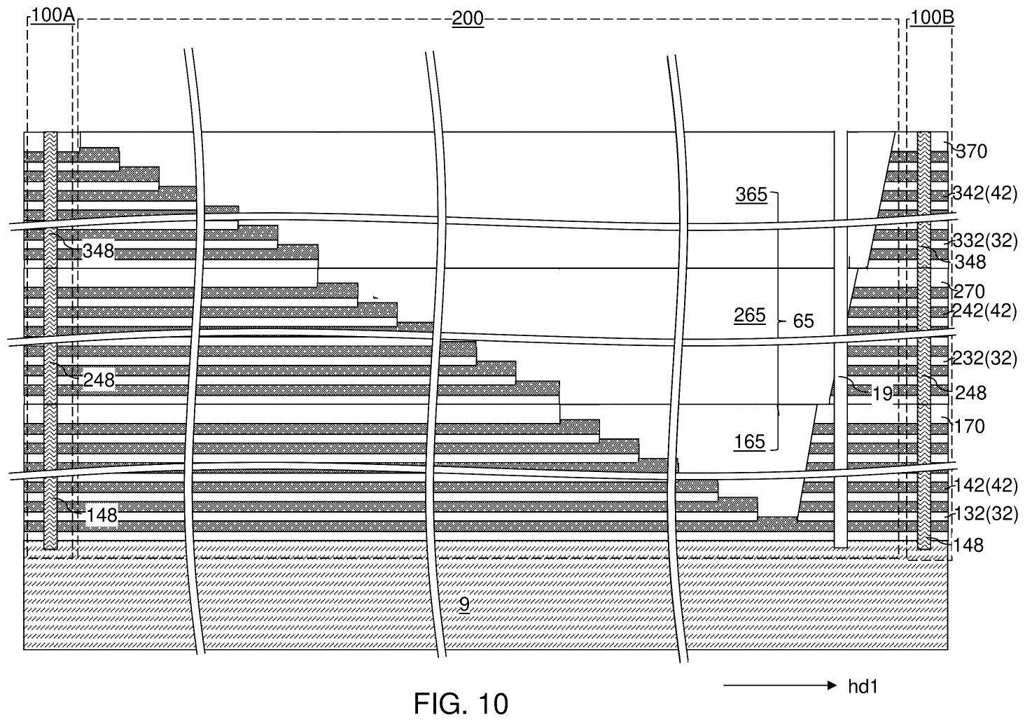

Referring to FIG. 10, a photoresist layer (not shown) can be applied over the third-tier structure, and can be lithographically patterned to form openings over the areas of the sacrificial third-tier support opening fill structures 318. The sacrificial fill materials of the sacrificial third-tier support opening fill structures 318, the sacrificial second-tier support opening fill structures 218, and the sacrificial first-tier support opening fill structures 118 can be removed selective to the materials of the retro-stepped dielectric material portions 65, the insulating layers 32, and the sacrificial material layers 42. Support pillar cavities can be formed in the volumes from which the materials of the sacrificial third-tier support opening fill structures 318, the sacrificial second-tier support opening fill structures 218, and the sacrificial first-tier support opening fill structures 118 are removed. The photoresist layer can be subsequently removed, for example, by ashing.

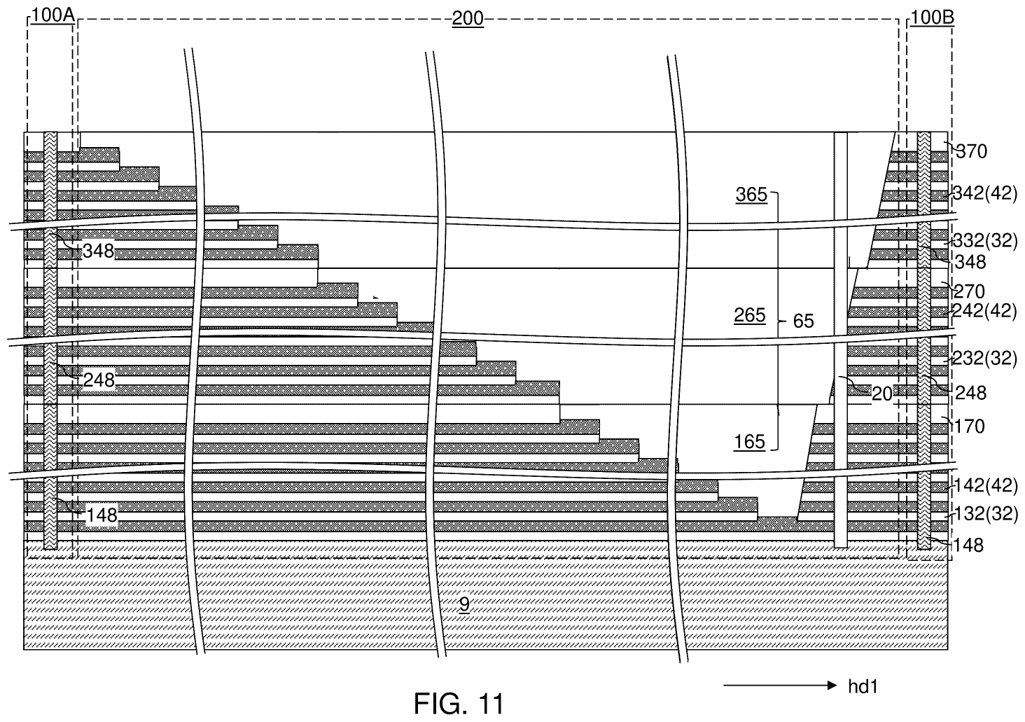

Referring to FIG. 11, a dielectric fill material can be deposited in the support pillar cavities by performing a conformal deposition process. The dielectric fill material comprises a dielectric material that is different from the material of the sacrificial material layers 42. For example, the dielectric fill material may comprise undoped silicate glass or a doped silicate glass. Excess portions of the dielectric fill material can be removed from above the horizontal plane including the top surface of the topmost retro-stepped dielectric material portions 65 (such as the third-tier retro-stepped dielectric material portion 365). Each remaining portion of the dielectric fill material that fills a respective support pillar cavity constitutes a support pillar structure 20. The support pillar structures 20 can be formed in the inter-array region 200, and may vertically extend from the substrate 9 to a horizontal plane including the topmost surfaces of the retro-stepped dielectric material portions 65 and the third-tier insulating cap layer 370.

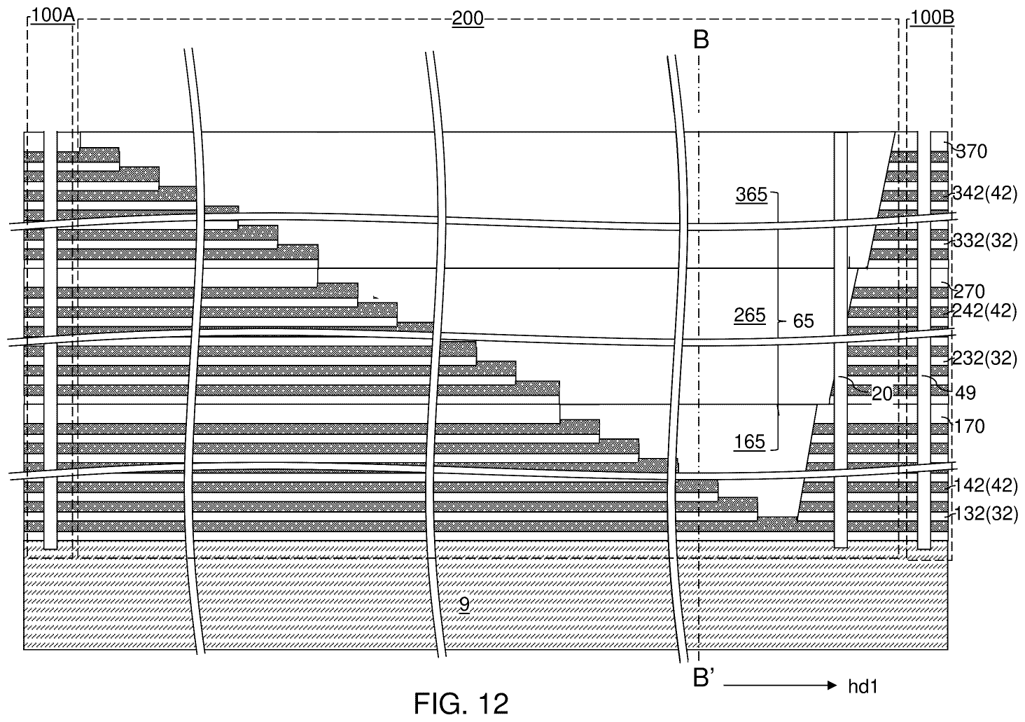

Referring to FIG. 12, a photoresist layer (not shown) can be applied over the third-tier structure, and can be lithographically patterned to cover the inter-array regions 200 without covering the memory array regions 100. The sacrificial fill materials of the sacrificial memory opening fill structures (148, 248, 348) can be removed selective to the materials of the insulating layers 32, the sacrificial material layers 42, and the substrate 9. Memory openings 49 are formed in the voids from which the sacrificial fill materials of the sacrificial memory opening fill structures (148, 248, 348) are removed.

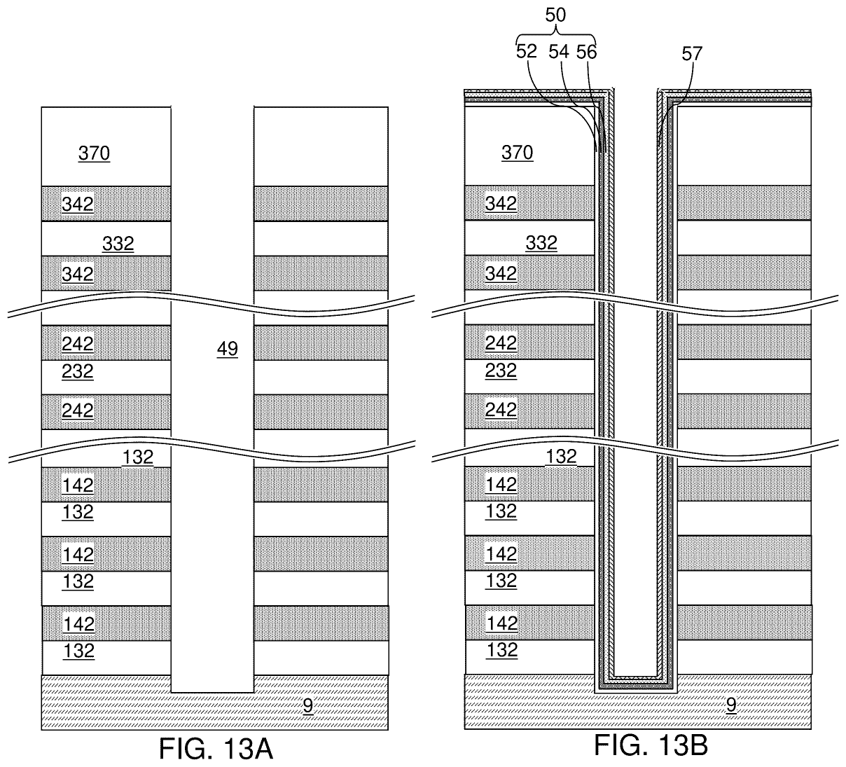

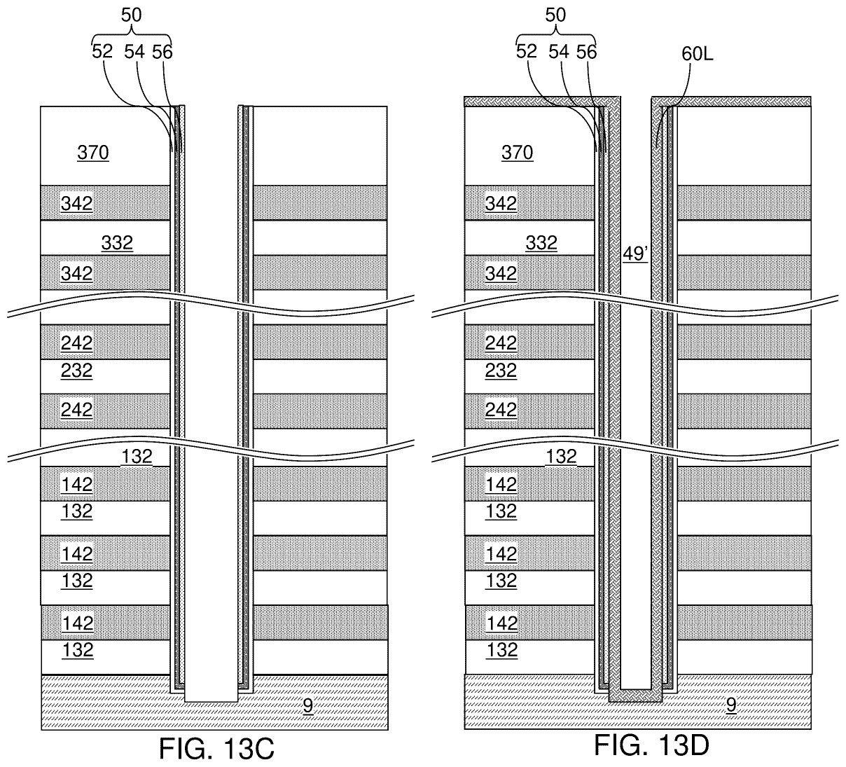

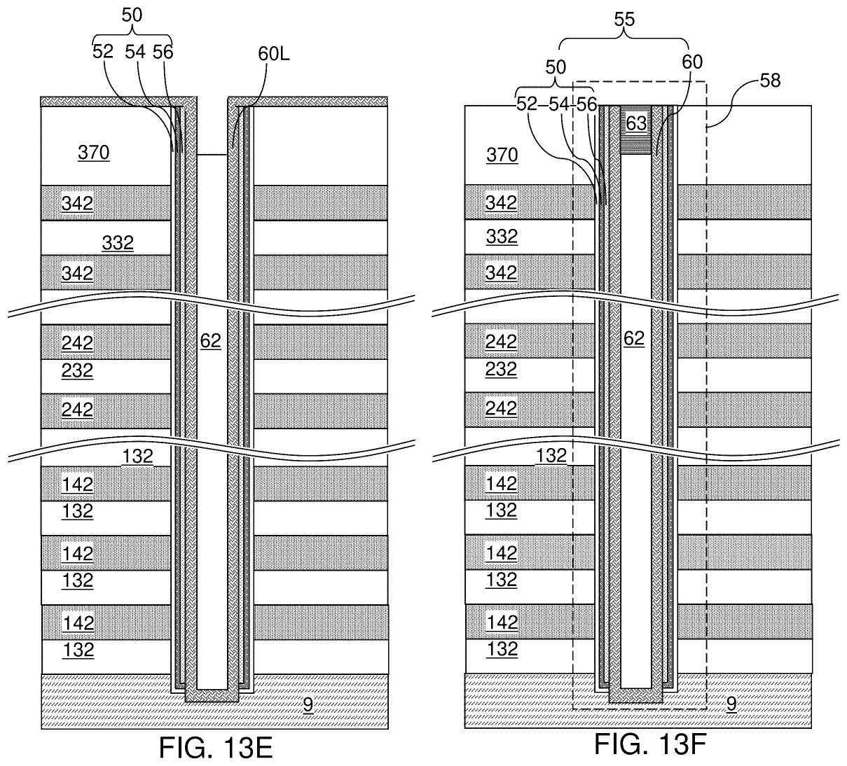

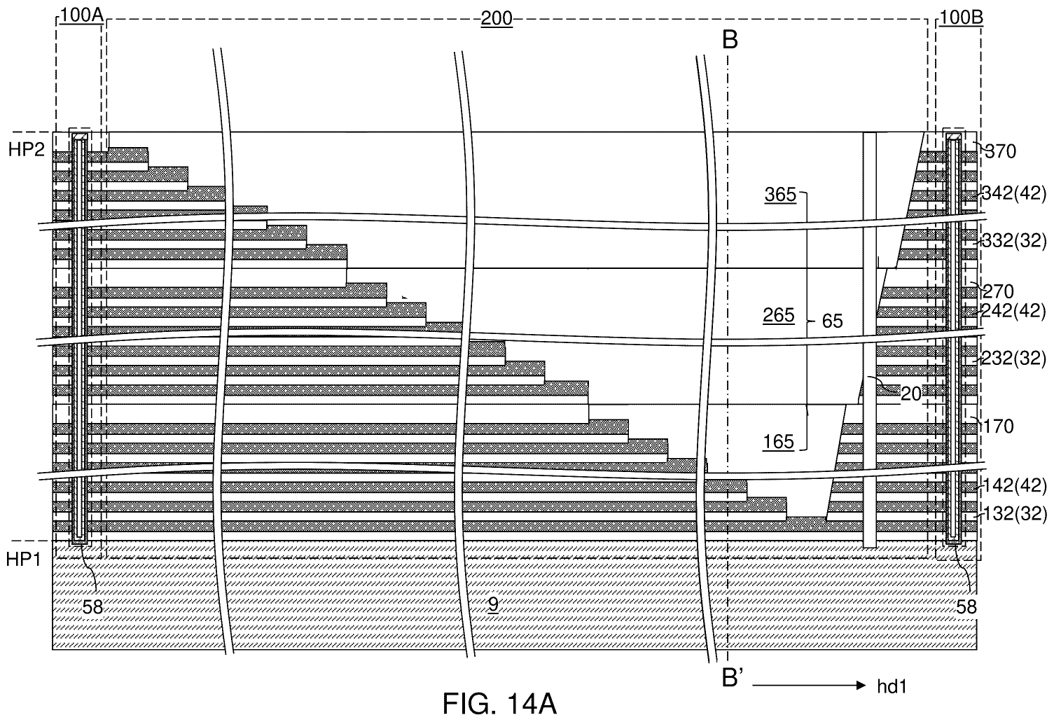

FIGS. 13A-13F illustrate sequential vertical cross-sectional views of a memory opening during formation of a memory opening fill structure according to an embodiment of the present disclosure.

Referring to FIG. 13A, a memory opening 49 in the exemplary structure of FIG. 12 is illustrated.

Referring to FIG. 13B, a stack of layers including a blocking dielectric layer 52, a memory material layer 54, a dielectric liner 56, and an optional sacrificial cover layer 57 may be sequentially deposited in the inter-tier memory openings 49. The blocking dielectric layer 52 may include a single dielectric material layer or a stack of a plurality of dielectric material layers. In one embodiment, the blocking dielectric layer 52 may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 may be formed. Generally, the memory material layer 54 may comprise any memory material known in the art. In one embodiment, the memory material layer 54 may be a continuous layer or patterned discrete portions of a charge trapping material including a dielectric charge trapping material, which may be, for example, silicon nitride. Alternatively, the memory material layer 54 may include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 may have vertically coincident sidewalls, and the memory material layer 54 may be formed as a single continuous layer. Alternatively, the sacrificial material layers 42 may be laterally recessed with respect to the sidewalls of the insulating layers 32, and a combination of a deposition process and an anisotropic etch process may be used to form the memory material layer 54 as a plurality of memory material portions that are vertically spaced apart. The thickness of the memory material layer 54 may be in a range from 2 nm to 20 nm, although lesser and greater thicknesses may also be used.

The dielectric liner 56 includes a dielectric material. In one embodiment, the dielectric liner 56 may comprise a tunneling dielectric layer through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 may include a stack of a first silicon oxide layer, a silicon oxynitride layer, and a second silicon oxide layer, which is commonly known as an ONO stack. In one embodiment, the dielectric liner 56 may include a silicon oxide layer that is substantially free of carbon or a silicon oxynitride layer that is substantially free of carbon. The thickness of the dielectric liner 56 may be in a range from 2 nm to 20 nm, although lesser and greater thicknesses may also be used. The stack of the blocking dielectric layer 52, the memory material layer 54, and the dielectric liner 56 constitutes a memory film 50 that stores memory bits.

The sacrificial cover layer 57 may comprise a sacrificial material that may be subsequently removed selective to the material of the dielectric liner 56. For example, the sacrificial cover layer may comprise a semiconductor material (e.g., amorphous silicon), silicon oxide, or a carbon-based material (such as amorphous carbon or diamond-like carbon). The thickness of the sacrificial cover layer may be in a range from 1 nm to 10 nm, although lesser and greater thicknesses may also be employed.

Referring to FIG. 13C, an anisotropic etch process may be performed to remove horizontal portions of the sacrificial cover layer 57, the dielectric liner 56, the memory material layer 54, and the blocking dielectric layer 52. Remaining cylindrical portions of the sacrificial cover layer 57 may be removed selective to the material of the dielectric liner 56 during the anisotropic etch process, or by an isotropic etch process (such as a wet etch process) or by ashing. Alternatively, if the sacrificial cover layer 57 comprises a semiconductor material (e.g., amorphous silicon), then it may be retained.

Referring to FIG. 13D, a semiconductor channel material layer 60L can be deposited by a conformal deposition process. The semiconductor channel material layer 60L includes a p-doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may have a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as a low pressure chemical vapor deposition (LPCVD) process. The thickness of the semiconductor channel material layer 60L may be in a range from 2 nm to 10 nm, although lesser and greater thicknesses may also be used. A cavity 49′ is formed in the volume of each inter-tier memory opening 49 that is not filled with the deposited material layers (52, 54, 56, 60L).

Referring to FIG. 13E, if the cavity 49′ in each memory opening 49 is not completely filled by the semiconductor channel material layer 60L, a dielectric core layer may be deposited in the cavity 49′ to fill any remaining portion of the cavity 49′ within each memory opening 49. The dielectric core layer includes a dielectric material such as silicon oxide or organosilicate glass. The dielectric core layer may be deposited by a conformal deposition method such as a low pressure chemical vapor deposition (LPCVD) process, or by a self-planarizing deposition process such as spin coating. The horizontal portion of the dielectric core layer overlying the third-tier insulating cap layer 370 may be removed, for example, by a recess etch. The recess etch continues until top surfaces of the remaining portions of the dielectric core layer are recessed to a height between the top and bottom surfaces of the third-tier insulating cap layer 370. Each remaining portion of the dielectric core layer constitutes a dielectric core 62.

Referring to FIG. 13F, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the dielectric liner 56, the memory material layer 54, and the blocking dielectric layer 52 that overlie the horizontal plane including the top surface of the third-tier insulating cap layer 370 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of lateral recesses. As used herein, a macroscopic retention time refers to a retention time suitable for operation of a memory device as a permanent memory device such as a retention time in excess of 24 hours.

Each combination of a memory film 50 and a vertical semiconductor channel 60 within an inter-tier memory opening 49 constitutes a memory stack structure 55. The memory stack structure 55 is a combination of a vertical semiconductor channel 60, a dielectric liner 56, a plurality of memory elements comprising portions of the memory material layer 54, and an optional blocking dielectric layer 52. The memory stack structures 55 can be formed through memory array regions 100 of the first and second vertically alternating sequences in which all layers of the first and second vertically alternating sequences are present. Each combination of a memory stack structure 55, a dielectric core 62, and a drain region 63 within an inter-tier memory opening 49 constitutes a memory opening fill structure 58. Generally, memory opening fill structures 58 are formed within the memory openings 49. Each of the memory opening fill structures 58 comprises a respective memory film 50 and a respective vertical semiconductor channel 60.

In one embodiment, each of the memory stack structures 55 comprises vertical NAND string including the respective vertical stack of memory elements (comprising portions of a memory material layer 54 located at levels of the sacrificial material layers 42) and a vertical semiconductor channel 60 that vertically extend through the sacrificial material layers 42 adjacent to the respective vertical stack of memory elements.

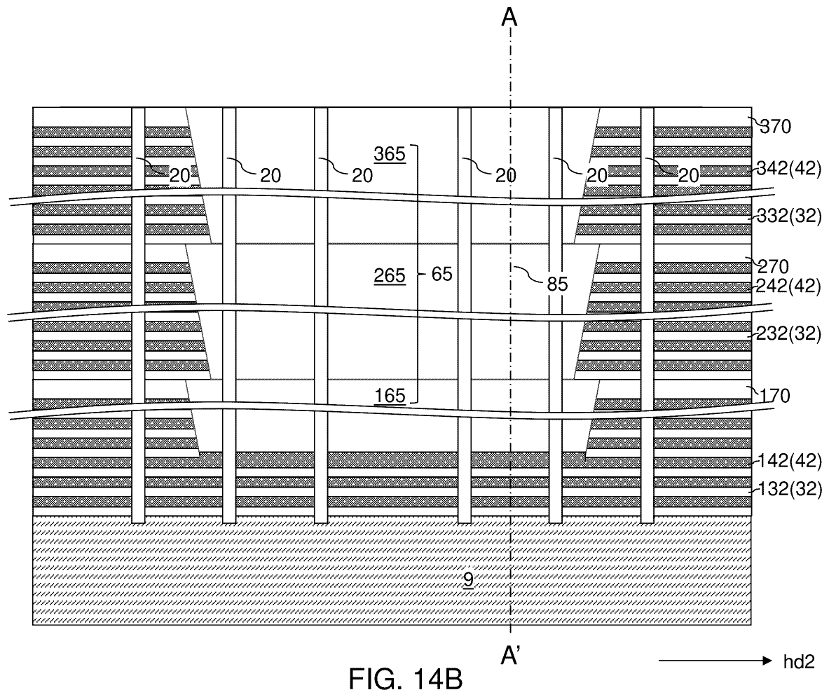

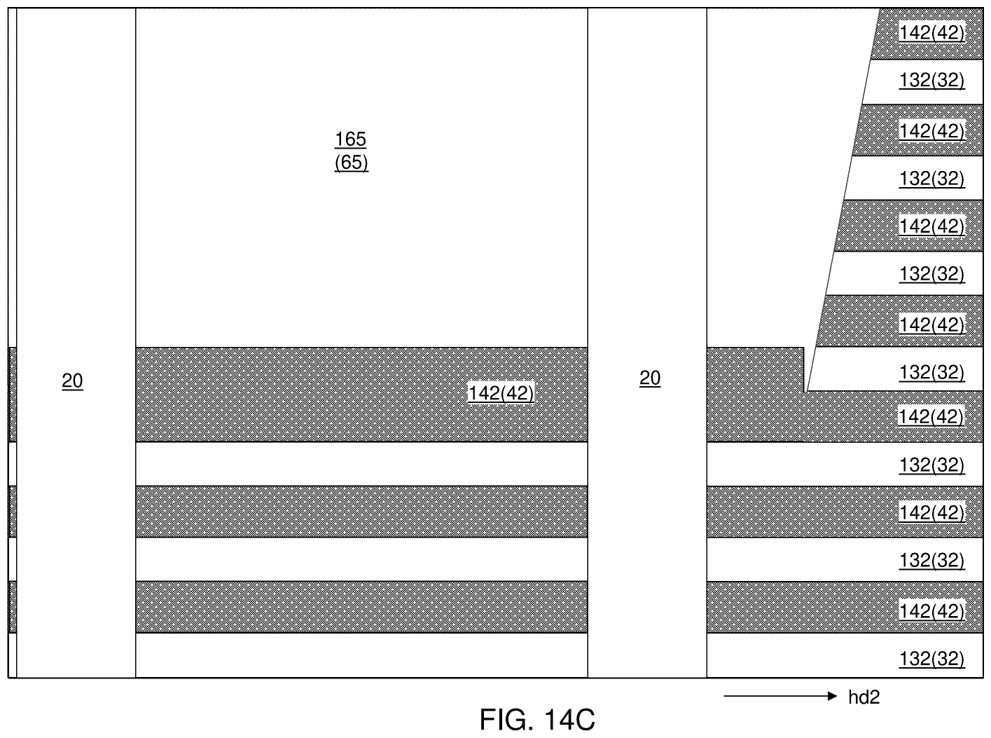

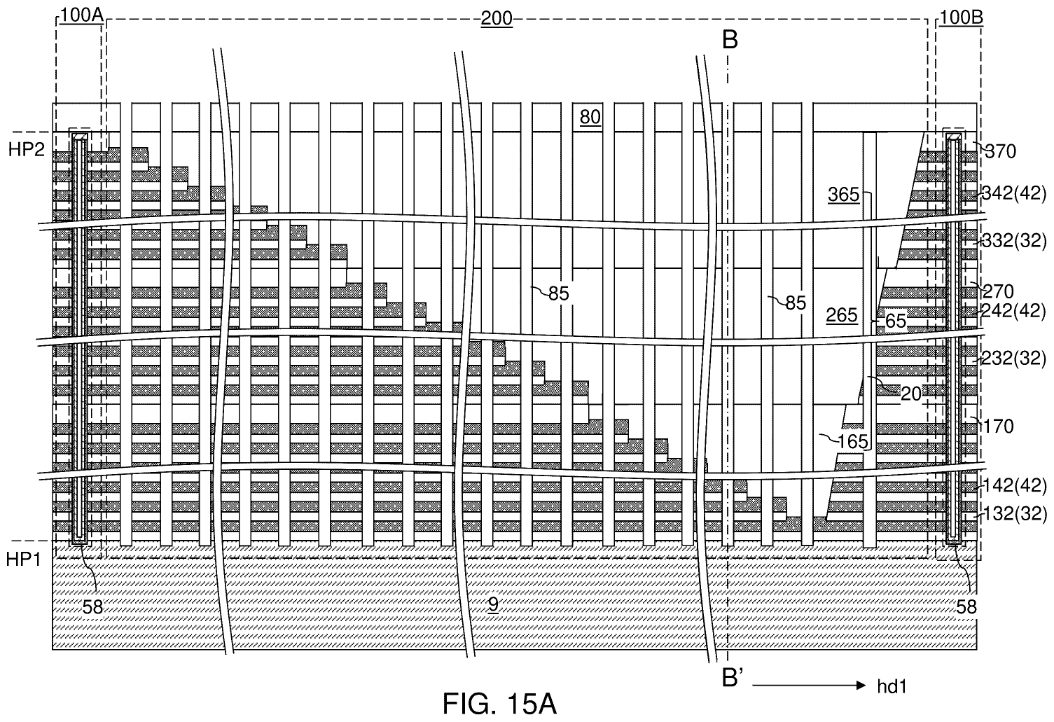

Referring to FIGS. 14A-14C, the exemplary structure is illustrated after the processing steps of FIG. 13F, i.e., after formation of the memory opening fill structures 58 in the memory openings 49. In one embodiment, support pillar structures (not shown) may be formed in the support openings. Generally, each of the memory opening fill structures 58 comprises a respective vertical stack of memory elements located at levels of the electrically conductive layers 46 within the plurality of tier structures, and further comprises a respective vertical semiconductor channel 60 that vertically extends through the plurality of tier structures. Each memory opening fill structure 58 vertically extends from below a first horizontal plane HP1 including a bottommost surface of the at least one alternating stack (32, 42) to a second horizontal plane HP2 including the top surfaces of the memory opening fill structures 58.

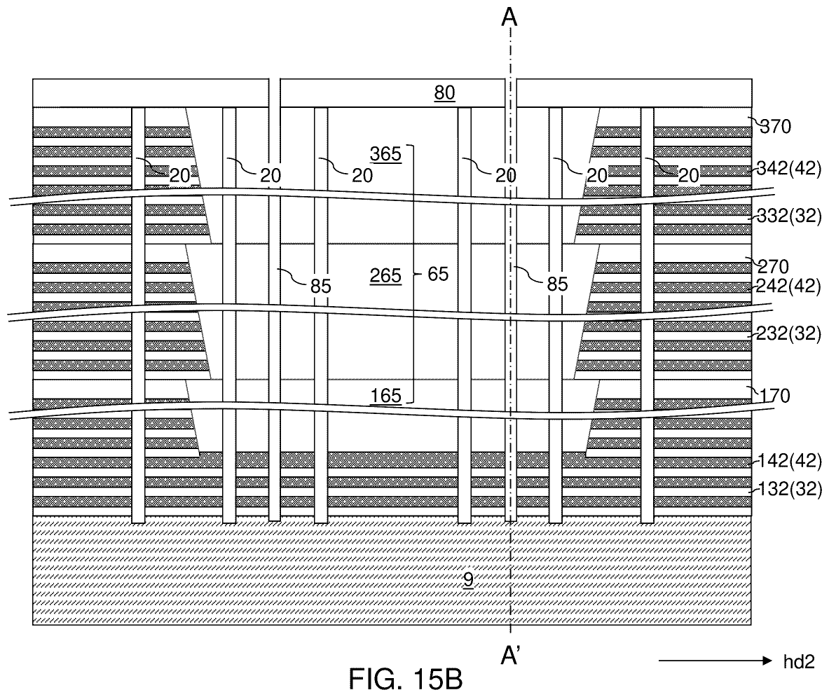

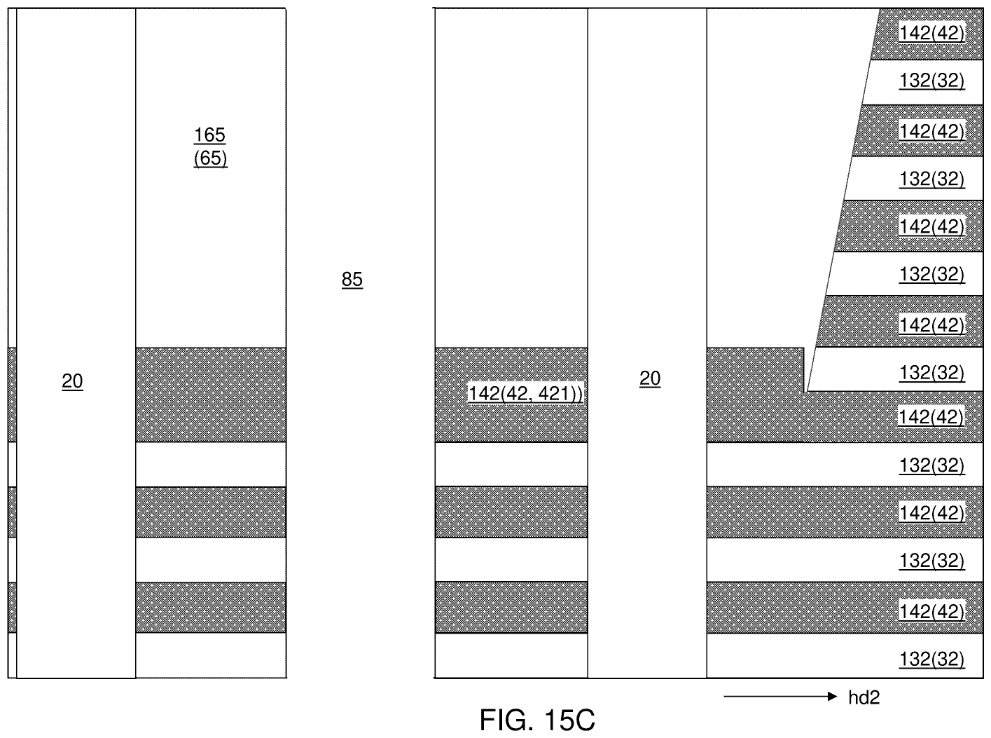

Referring to FIGS. 15A-15C, a contact-level dielectric layer 80 can be deposited over the third-tier insulating cap layer 370 and the third-tier retro-stepped dielectric material portions 365. The contact-level dielectric layer 80 comprises a dielectric material such as silicon oxide, and may have a thickness in a range from 100 nm to 800 nm, although lesser and greater thicknesses may also be employed.

A photoresist layer (not shown) can be applied over the contact-level dielectric layer, and can be lithographically patterned to cover the memory array regions 100 without covering the inter-array regions 200. The sacrificial fill materials of the sacrificial third-tier contact opening fill structures 368, the sacrificial second-tier contact opening fill structures 268, and the sacrificial first-tier contact opening fill structures 168 can be removed selective to the materials of the retro-stepped dielectric material portions 65, the insulating layers 32, the sacrificial material layers 42, and the support pillar structures 20. Contact via cavities 85 are formed in the volumes from which the materials of the sacrificial third-tier contact opening fill structures 368, the sacrificial second-tier contact opening fill structures 268, and the sacrificial first-tier contact opening fill structures 168 are removed. Each contact via cavity 85 vertically extends from the horizontal plane including the planar top surfaces of the third-tier retro-stepped dielectric material portion 365 to the substrate 9. Each contact via cavity 85 may vertically extend through a respective set of at least one insulating layer 32 and a respective set of at least one sacrificial material layer 42 of an alternating stack of insulating layers 32 and sacrificial material layers 42. Each contact via cavity 85 vertically extends through a thickened portion of the topmost sacrificial material layer within the respective set of at least one sacrificial material layer 42.

For each contact via cavity 85 other than contact via cavities 85 that vertically extends through a bottommost first-tier sacrificial material layer 142, the contact via cavity 85 vertically extends through at least one retro-stepped dielectric material portion 65 and a subset of the sacrificial material layers 42 within the alternating stack (32, 42). In this case, the subset of the sacrificial material layers 42 comprises a first sacrificial material layer 421 which is a topmost sacrificial material layer 42 of the subset of the sacrificial material layers 42 and further comprises at least one second sacrificial material layer 42 (which may be a plurality of second sacrificial material layers 42) that underlie the first sacrificial material layer 421, as illustrated in FIG. 15C.

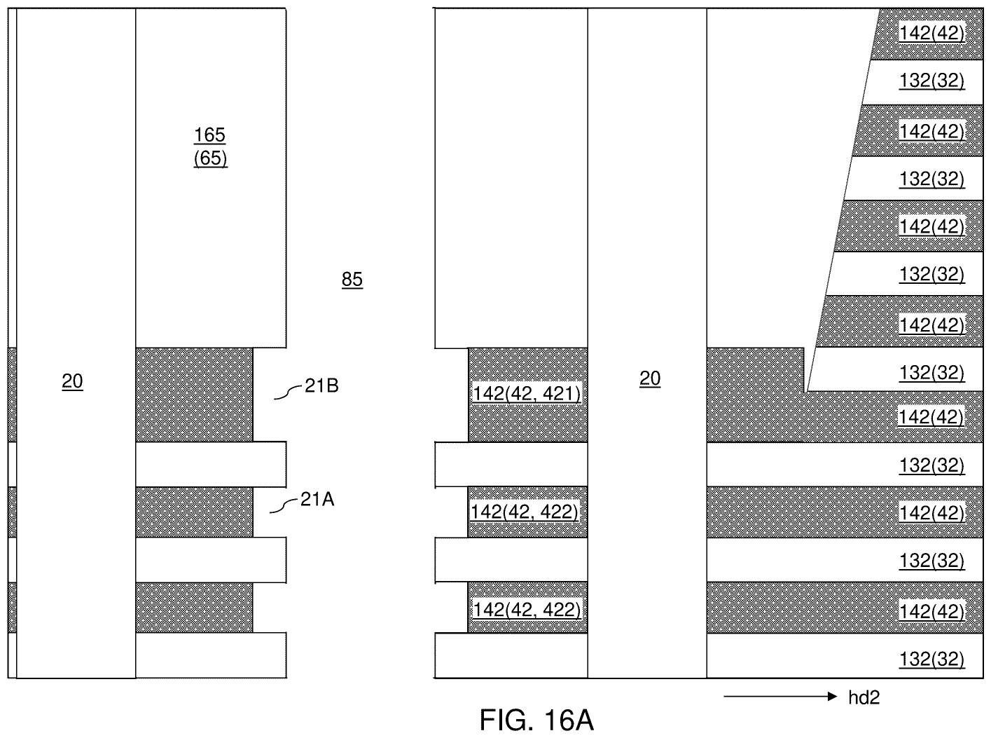

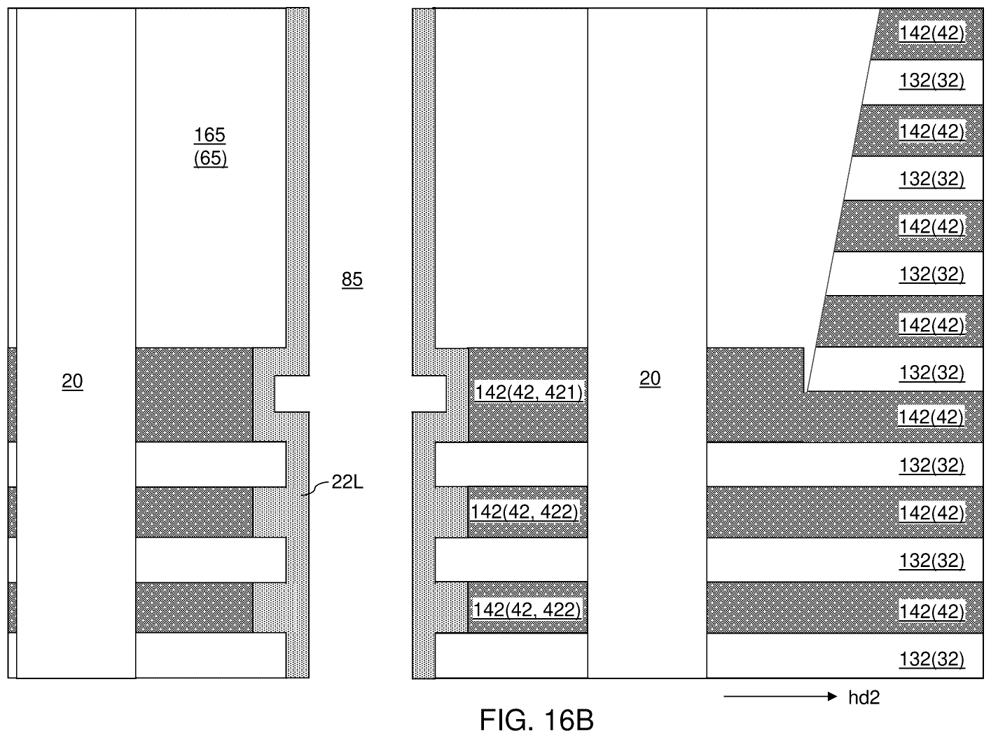

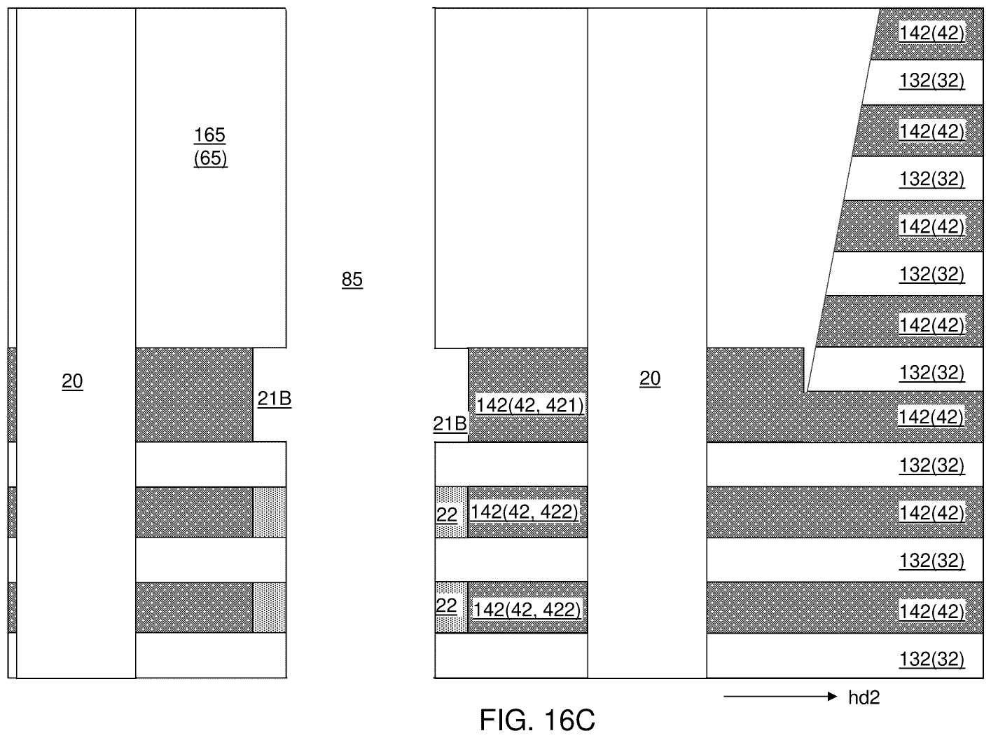

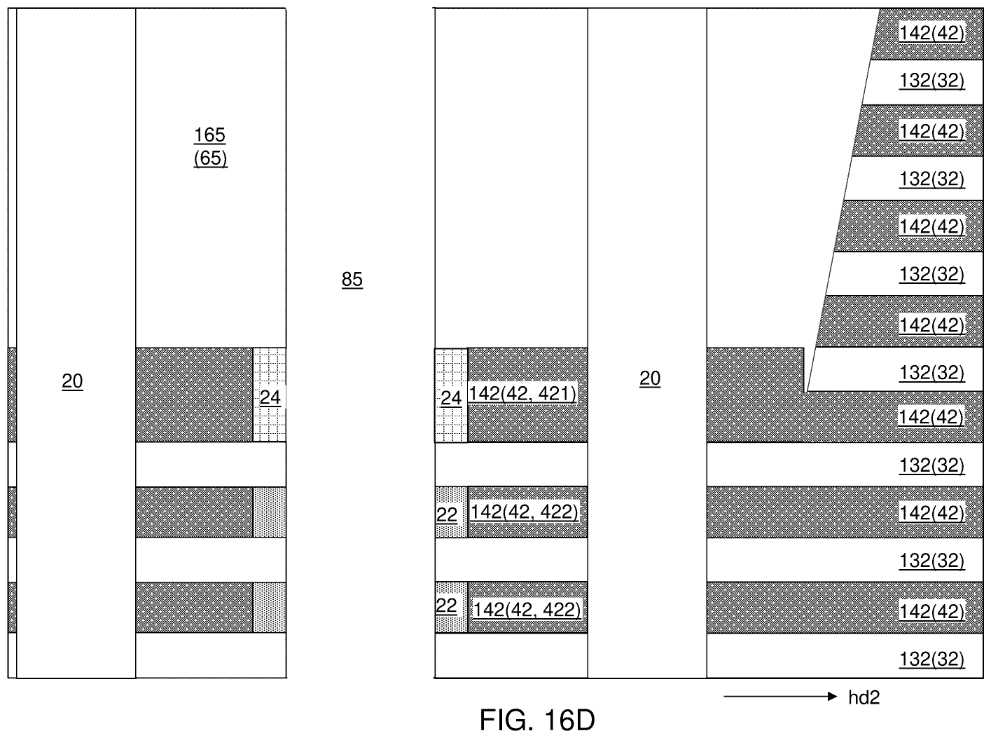

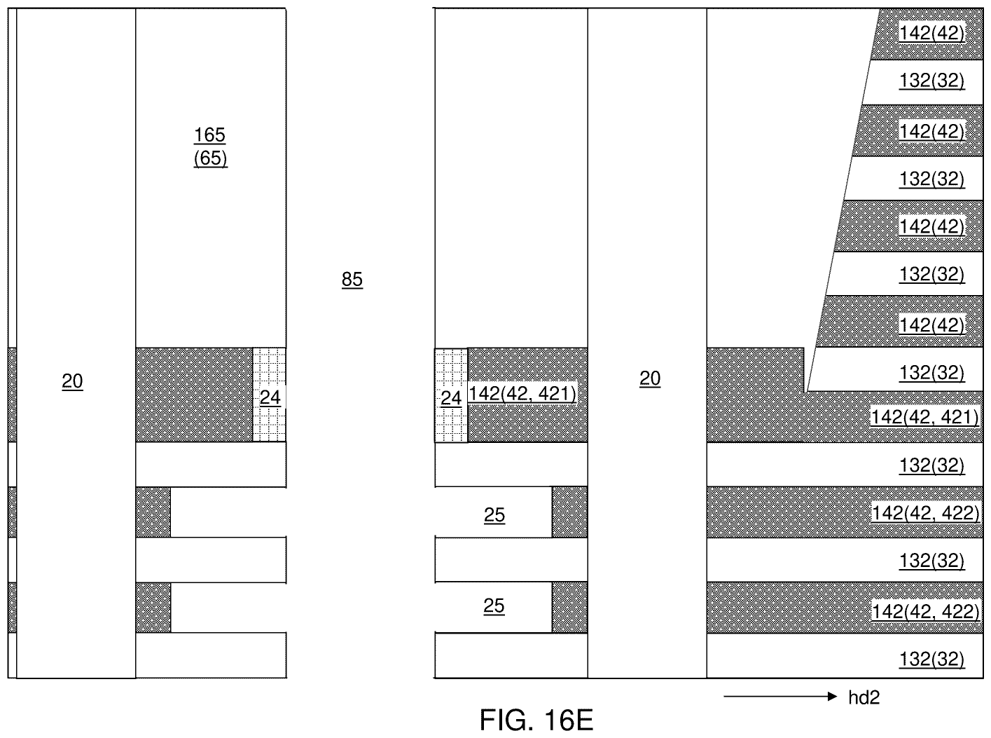

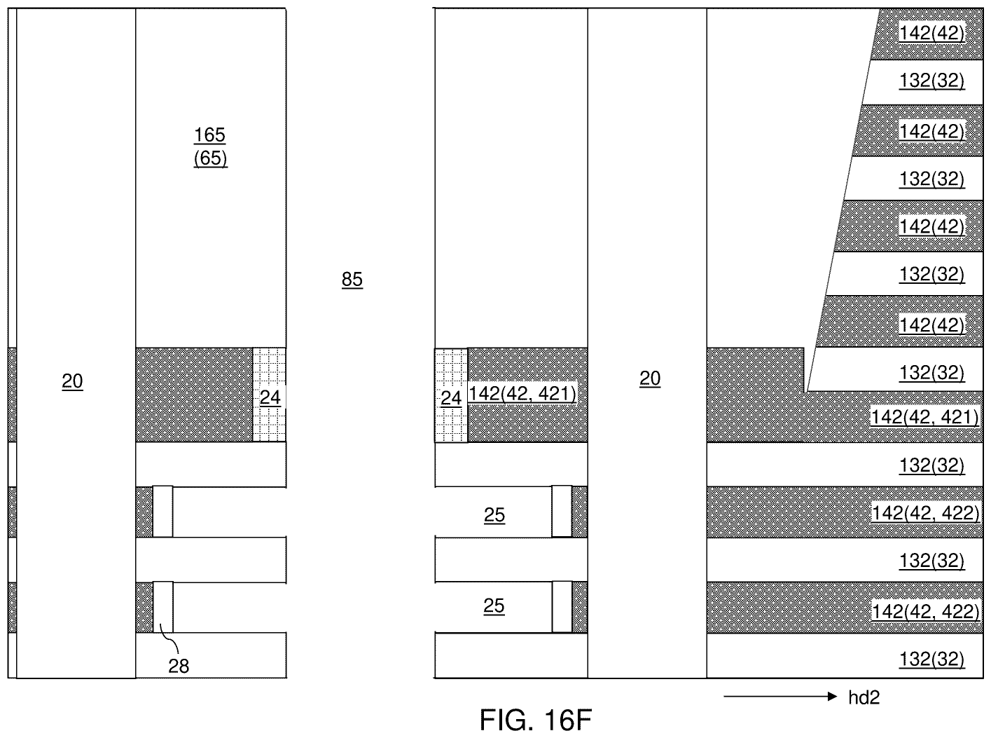

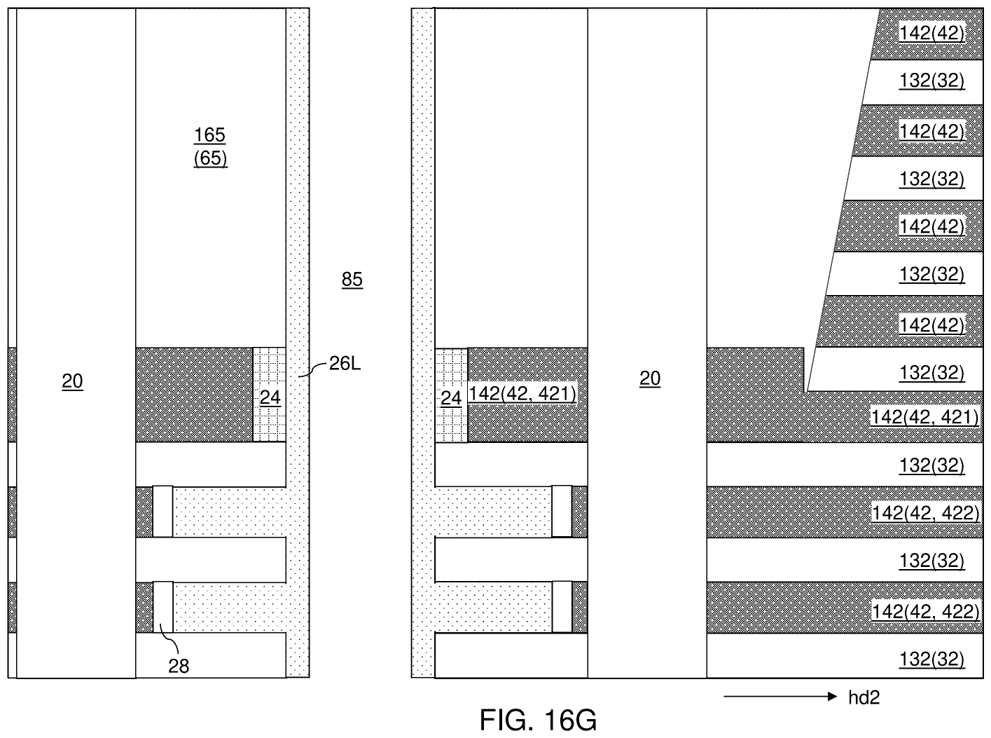

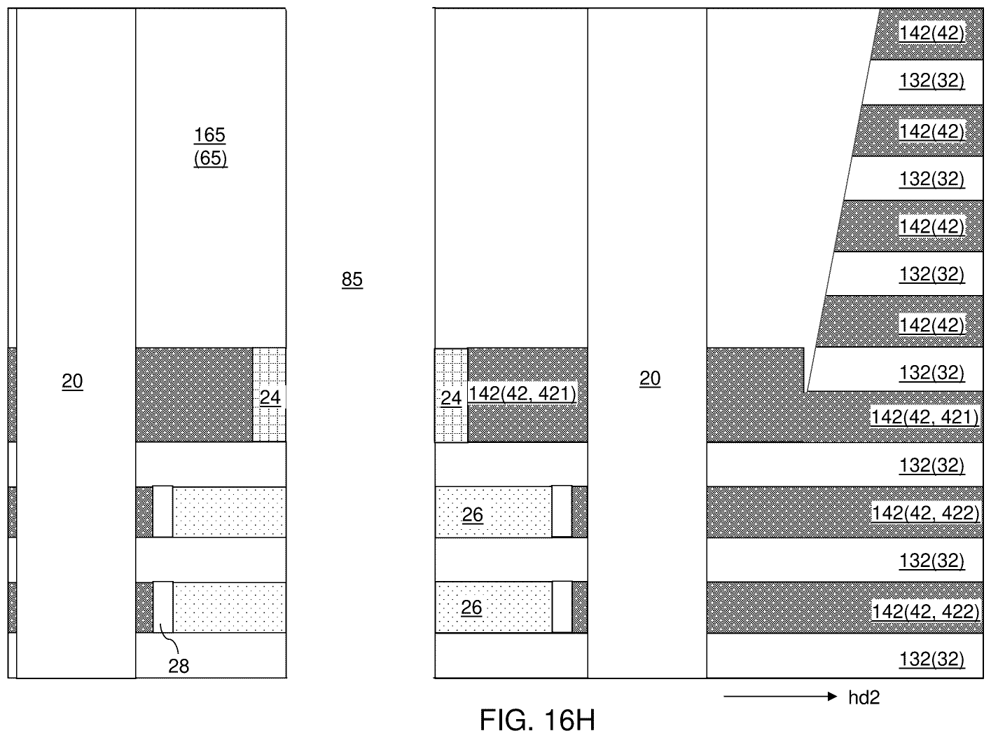

FIGS. 16A-16H are sequential vertical cross-sectional views of a region of the exemplary structure during formation of annular dielectric spacers 26 according to an embodiment of the present disclosure.

Referring to FIG. 16A, a region of a contact via cavity 85 around a thickened portion of a first sacrificial material layer 421 is illustrated after performing a first isotropic recess etch process that isotropically etches the sacrificial material of the sacrificial material layers 42 selective to the materials of the insulating layers 32, the retro-stepped dielectric material portions 65, the insulating cap layers (170, 270, 370), and the contact-level dielectric layer 80. For example, if the sacrificial material layers 42 comprise silicon nitride, the first isotropic recess etch process may comprise a wet etch process employing hot phosphoric acid. The duration of the first isotropic recess etch process can be selected such that lateral recess distance of the first isotropic recess etch process is in a range from 50% to 300%, such as from 100% to 200%, of the thickness of unthickened portions of the sacrificial material layers 42.

Generally, for each contact via cavity 85, a subset of the sacrificial material layers 42 can be physically exposed the contact via cavity 85. The subset of the sacrificial material layers 42 comprises a respective first sacrificial material layer 421 which is the topmost layer within the subset of the sacrificial material layers 42. If present, any sacrificial material layer 42 within the subset of the sacrificial material layers 42 that underlies the first sacrificial material layer 421 is herein referred to as a second sacrificial material layer 422. In case the subset of the sacrificial material layers 42 comprises at least one second sacrificial material layer 422, a first annular recess region 21A is formed in each volume from which an annular portion of a second sacrificial material layer 422 is removed, and a second annular recess region 21B is formed in the volume from which an annular portion of the first sacrificial material layer 422 is removed.

Referring to FIG. 16B, a sacrificial fill material can be conformally deposited to form a sacrificial material liner 22L in a peripheral region of each contact via cavity 85. In one embodiment, the sacrificial fill material may be the same material (e.g., silicon nitride) as the material of the sacrificial material layers 42. The thickness of the sacrificial material liner 22L can be greater than one half of the thickness of the unthickened portions of the sacrificial material layers 42, and can be less than one half of the thickness of the thickened portions of the sacrificial material layers 42. Thus, each first annular recess region 21A can be completely filled with the sacrificial material liner 22L, while the second annular recess region 21B can be only partly filled around each contact via cavity 85.

Referring to FIG. 16C, an isotropic etch process can be performed to isotropically etch back the sacrificial fill material of the sacrificial material liner 22L. The duration of the isotropic etch process can be selected such that the sacrificial material liner 22L is removed from outside the volumes of the first annular recess regions 21A, and remains within the volumes of the first annular recess regions 21A. The sacrificial material liner 22L is removed from inside the volumes of the second annular recess region 21B around each contact via cavity 85. Remaining portions of the sacrificial material liner 22L that fills the first annular recess regions 21A comprise sacrificial annular plates 22. Thus, the sacrificial annular plates 22 may be formed within first annular recess regions 21A at levels of the second sacrificial material layers 422 around each contact via cavity 85.

Referring to FIG. 16D, an etch-stop material can be conformally deposited in the second annular recess region 21B and in peripheral portions of the contact via cavity 85. The etch-stop material comprises a material that is resistant to a second isotropic recess etch process to be subsequently employed to etch the sacrificial annular plates 22 and proximal portions of the sacrificial material layers 42. For example, if the sacrificial material layers 42 comprise silicon nitride and if the second isotropic recess etch process to be subsequently performed comprises a wet etch process employing hot phosphoric acid, the etch-stop material may comprise carbon or a metal nitride (such as titanium nitride, tantalum nitride, etc.) materials. An etch-back process, which may comprise an anisotropic etch process and/or an isotropic etch process, may be performed to remove portions of the etch-stop material located outside the volume of the second annular recess region 21B. A remaining annular portion of the etch-stop material that fills the second annular recess region 21B comprises an etch-stop annular plate 24. Thus, an etch-stop annular plate 24 can be formed within a second annular recess region 21B at a level of the first sacrificial material layer 421 around each contact via cavity 85.

Referring to FIG. 16E, a second isotropic recess etch process can be performed to isotropically recess the materials of the sacrificial annular plates 22 and the sacrificial material layers 42 from around each of the contact via cavities 85. The duration of the second isotropic etch process can be selected such that the sacrificial annular plates 22 are completely removed, and proximal portions of the second sacrificial material layers 422 are laterally recessed. Third annular recess regions 25 are formed in volumes from which the sacrificial annular plates 22 and the proximal portions of the second sacrificial material layers 422 are removed. The etch-stop annular plate 24 functions as an etch-stop structure around each contact via cavity 85, and prevents etching of a respective first sacrificial material layer 421 around each contact via cavity 85.

The second isotropic recess etch process removes the sacrificial annular plates 22 and isotropically recesses proximal portions of the second sacrificial material layers 422 without removing the etch-stop annular plate 24 or the insulating layers 32. In an illustrative example, if the sacrificial material layers 42 comprise silicon nitride, the second isotropic recess etch process may comprise a wet etch process employing hot phosphoric acid. The ratio of the lateral etch distance of the second isotropic recess etch process to the thickness of the unthickened portions of the sacrificial material layers 42 may be in a range from 1.5 to 15, such as from 3 to 10, although lesser and greater ratios may also be employed. In one embodiment, the lateral etch distance of the second isotropic recess etch process may be in a range from 100 nm to 300 nm, although lesser and greater lateral etch distances may also be employed. Each third annular recess region 25 may be laterally bounded solely by a cylindrical sidewall of a respective one of the second sacrificial material layers 422, or may be laterally bounded by a combination of at least one cylindrical surface segment of the respective one of the second sacrificial material layers 422 and a surface segment of at least one support pillar structure 20.

Referring to FIG. 16F, in case the etch-stop annular plates 24 comprise a material that is resistant to oxidation, an oxidation process may be performed to convert physically exposed surface portions of the second sacrificial material layers 422 into tubular oxidation liners 28. In case the sacrificial material layers 42 comprise silicon nitride, the tubular oxidation liners 28 may comprise a silicon oxide material or silicon oxynitride material. The silicon oxynitride material may have a lateral nitrogen concentration gradient such that the atomic concentration of nitrogen atoms increases with a radial distance from a vertical line passing through a geometrical center of the contact via cavity 85. The thickness of each tubular oxidation liner 28 may be in a range from 2 nm to 8 nm, although lesser and greater thicknesses may also be employed.

Referring to FIG. 16G, a dielectric fill material layer, which is herein referred to as a recess-fill dielectric material 26L, can be conformally deposited in the third annular recess regions 25 and in peripheral portions of each contact via cavity 85. The recess-fill dielectric material layer 26L comprises a dielectric material that is resistant to an etch process to be subsequently employed to remove the etch-stop annular plates 24. In one embodiment, the recess-fill dielectric material layer 26L comprises a dielectric fill material such as undoped silicate glass (i.e., silicon oxide), a doped silicate glass, silicon oxynitride, or silicon carbonitride.

Referring to FIG. 16H, an etch process can be performed to recess the material of the recess-fill dielectric material layer 26L. Remaining portions of the recess-fill dielectric material layer 26L that fill the third annular recess regions 25 constitute annular dielectric spacers 26. For each contact via cavity 85 that is laterally surrounded by a plurality of second sacrificial material layers 422, a vertical stack of annular dielectric spacers 26 can be formed around the contact via cavity 85.

In summary, each contact via cavity 85 that is laterally surrounded by a respective first sacrificial material layer 421 and a respective set of second sacrificial material layers 422, a vertical stack of annular dielectric spacers 26 may be formed at each level of the second sacrificial material layers 422.

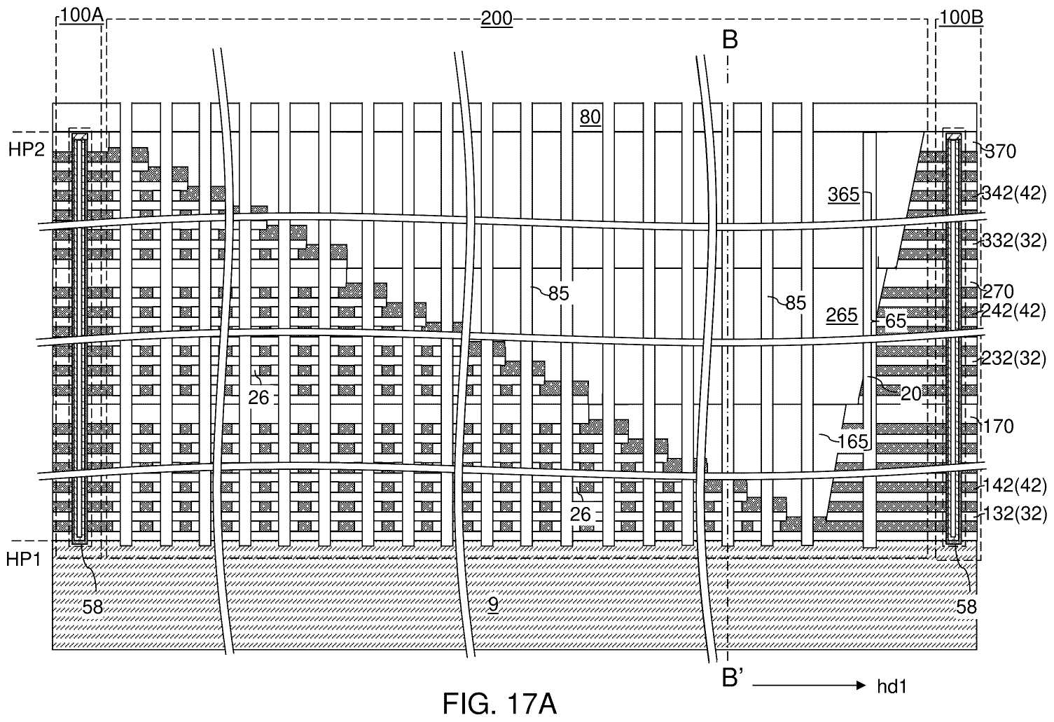

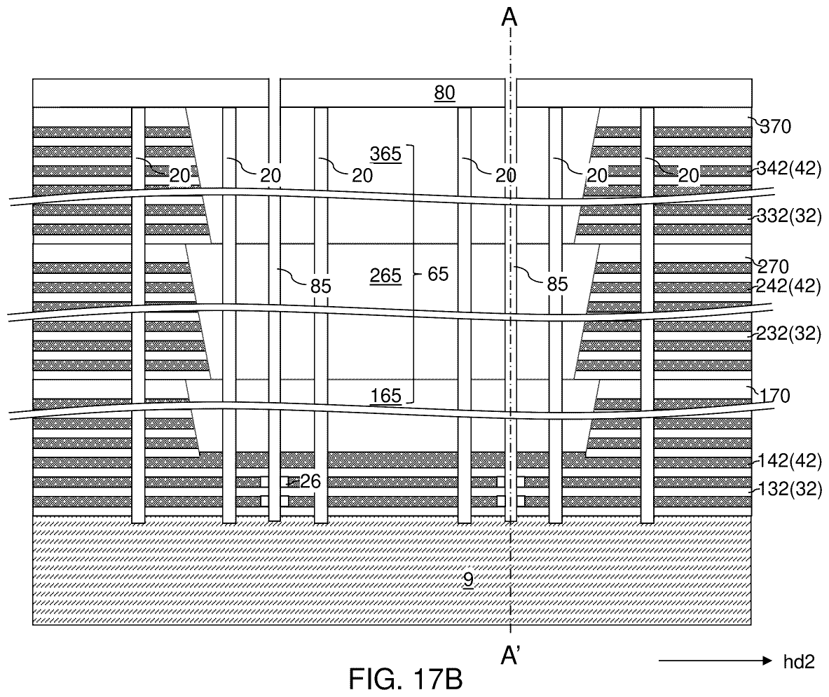

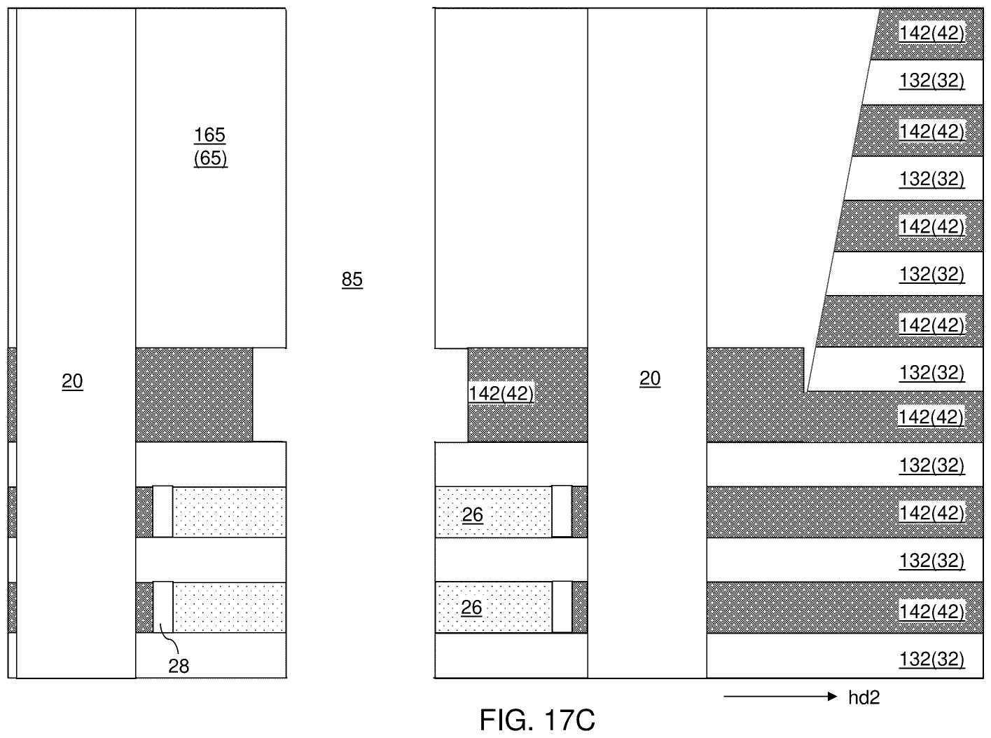

Referring to FIGS. 17A-17C, a selective etch process that etches the material of the etch-stop annular plates 24 selective to materials of the sacrificial material layers 42, the insulating layers 32, the annular dielectric spacers 26, and the retro-stepped dielectric material portions 65 can be performed. For example, a wet etch process that selectively etches the material of the etch-stop annular plates 24 can be performed to remove the etch-stop annular plates 24.

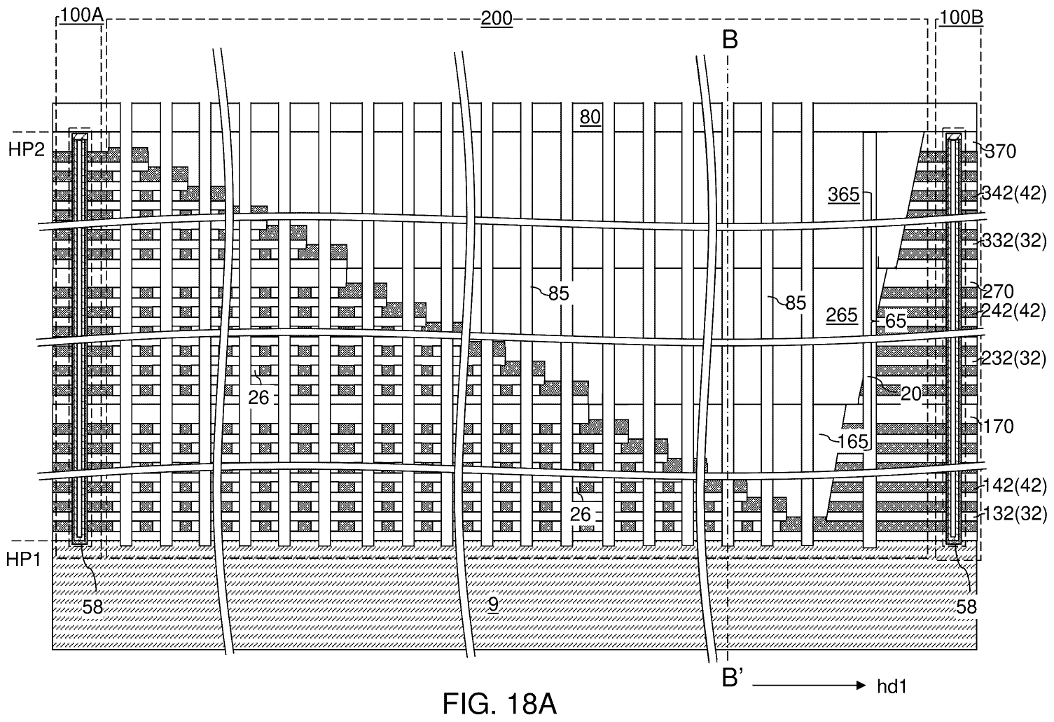

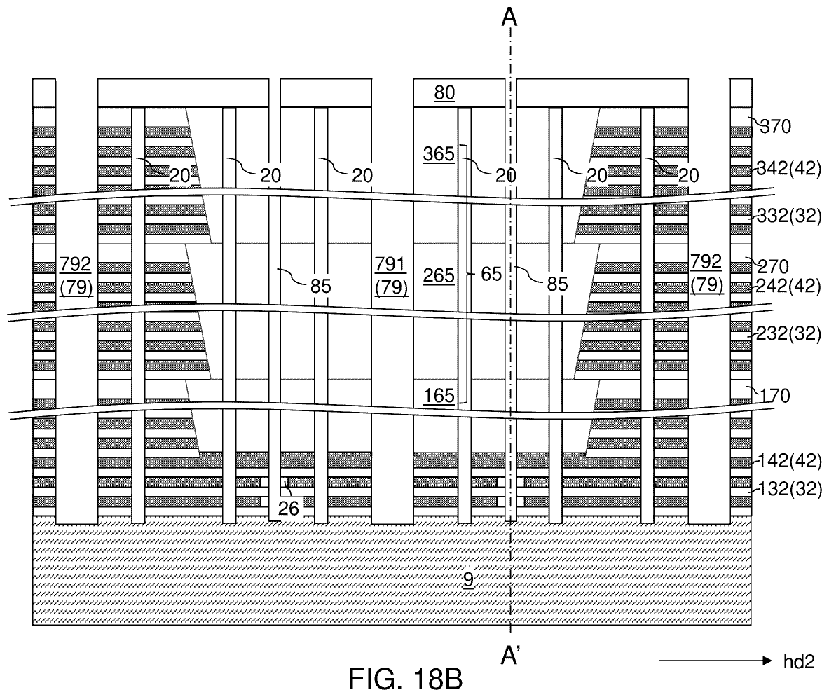

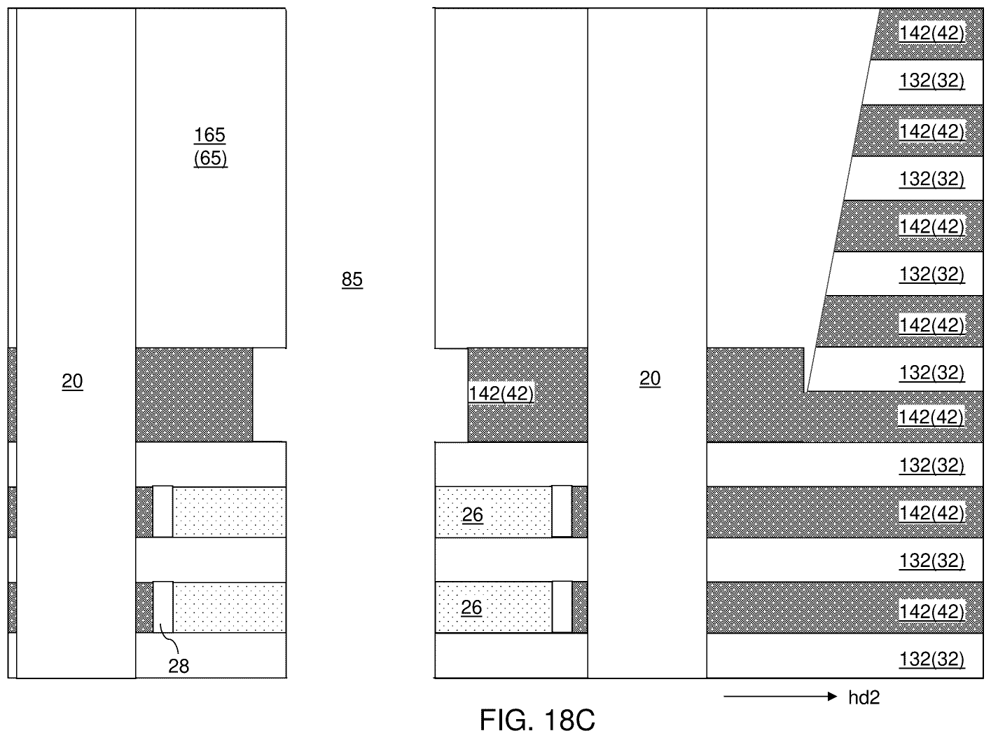

Referring to FIGS. 18A-18C, a masking layer, such as a photoresist layer and/or a carbon patterning film can be applied over the contact-level dielectric layer 80, and can be lithographically patterned to form elongated openings that laterally extend along the first horizontal direction hd1. The elongated openings can be formed in areas in which the memory opening fill structure 58, the support pillar structures 20, and the contact via cavities 85 are not present. An anisotropic etch process can be performed to transfer the pattern of the elongated openings through the contact-level dielectric layer 80 and the vertically alternating sequences (32, 42) of the insulating layers 32 and the sacrificial material layers 42.

Lateral isolation trenches 79 can be formed in the voids formed by removal of the material portions of the contact-level dielectric layer 80 and the vertically alternating sequences. Each of the vertically alternating sequences is divided into a respective set of alternating stacks {(132, 142), (232, 242), (332, 342)} of insulating layers 32 and sacrificial material layers 42 that are laterally spaced apart along a second horizontal direction hd2. For example, the first vertically alternating sequence is divided into first-tier alternating stacks of first-tier insulating layers 132 and first-tier sacrificial material layers 142; the second vertically alternating sequence is divided into second-tier alternating stacks of second-tier insulating layers 232 and second-tier sacrificial material layers 242; and the third vertically alternating sequence is divided into third-tier alternating stacks of third-tier insulating layers 332 and third-tier sacrificial material layers 342. The locations of the lateral isolation trenches 79 may be the same as the locations of the lateral isolation trench fill structures 76 illustrated in FIGS. 1A-1E.

The lateral isolation trenches 79 may comprise first lateral isolation trenches 791 that cut through the retro-stepped dielectric material portion (165, 265, 365) and second lateral isolation trenches 792 that do not cut through the retro-stepped dielectric material portion (165, 265, 365). In one embodiment, each first lateral isolation trench 791 divides each retro-stepped dielectric material portion (165, 265, 365) into a respective pair of retro-stepped dielectric material portions (such as first-tier retro-stepped dielectric material portions 265, second-tier retro-stepped dielectric material portions 265 and/or third-tier retro-stepped dielectric material portions 365). Generally, a plurality of tier structures that are vertically stacked can be formed over a substrate 9. Each tier structure within the plurality of tier structures comprises a respective set of alternating stacks of insulating layers 32 and sacrificial material layers 42. The photoresist layer can be subsequently removed, for example, by ashing.

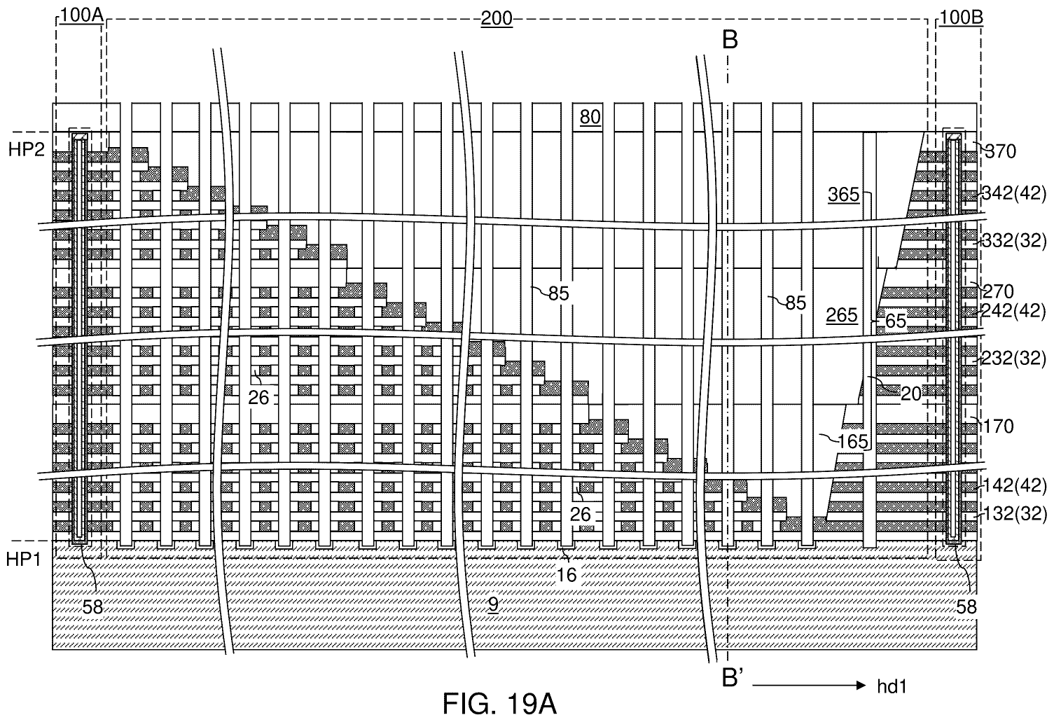

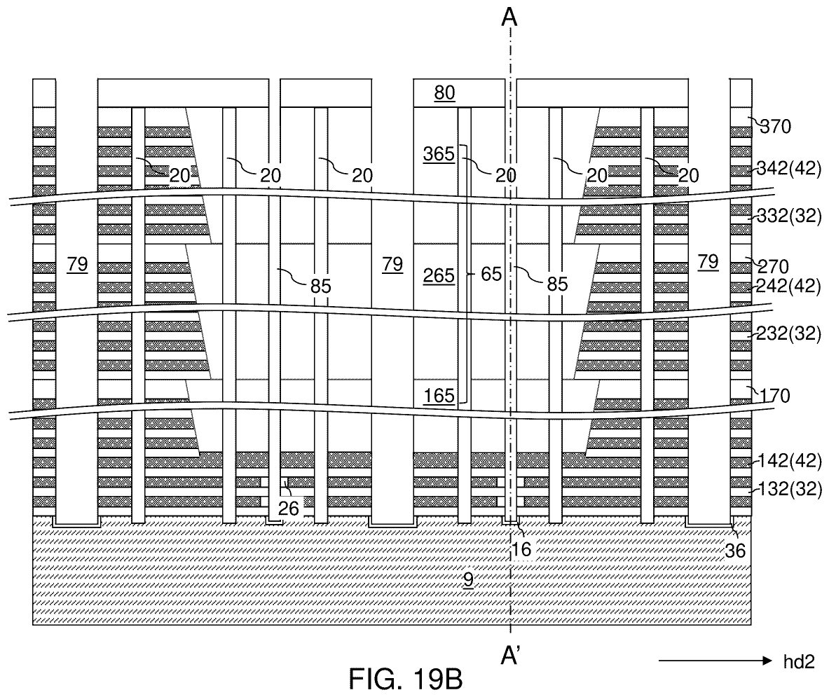

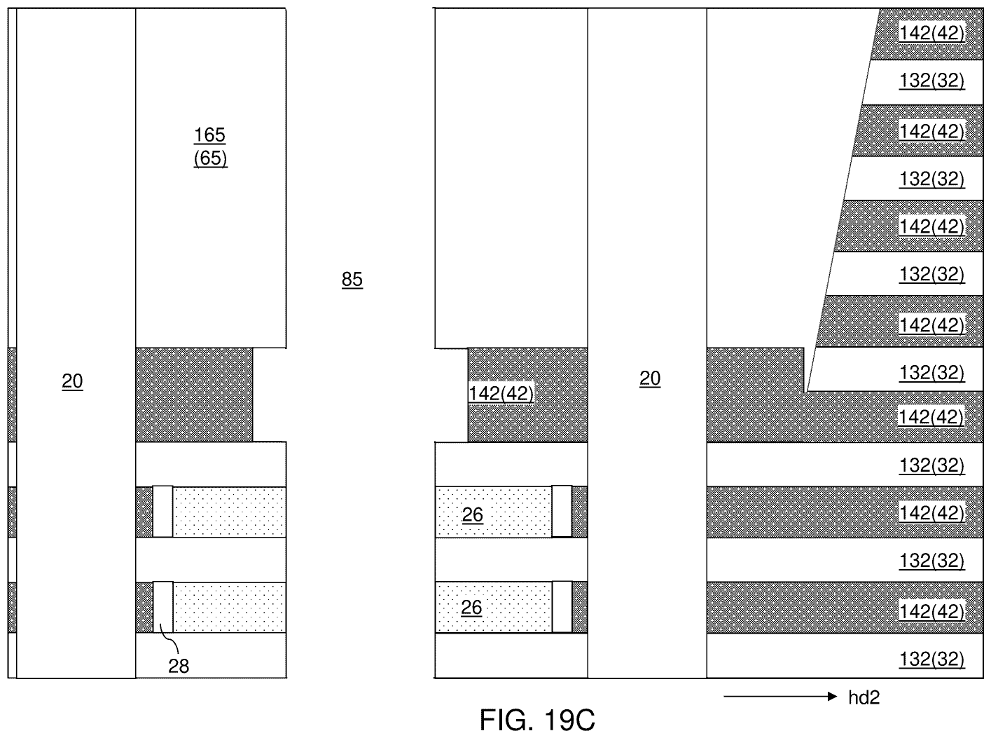

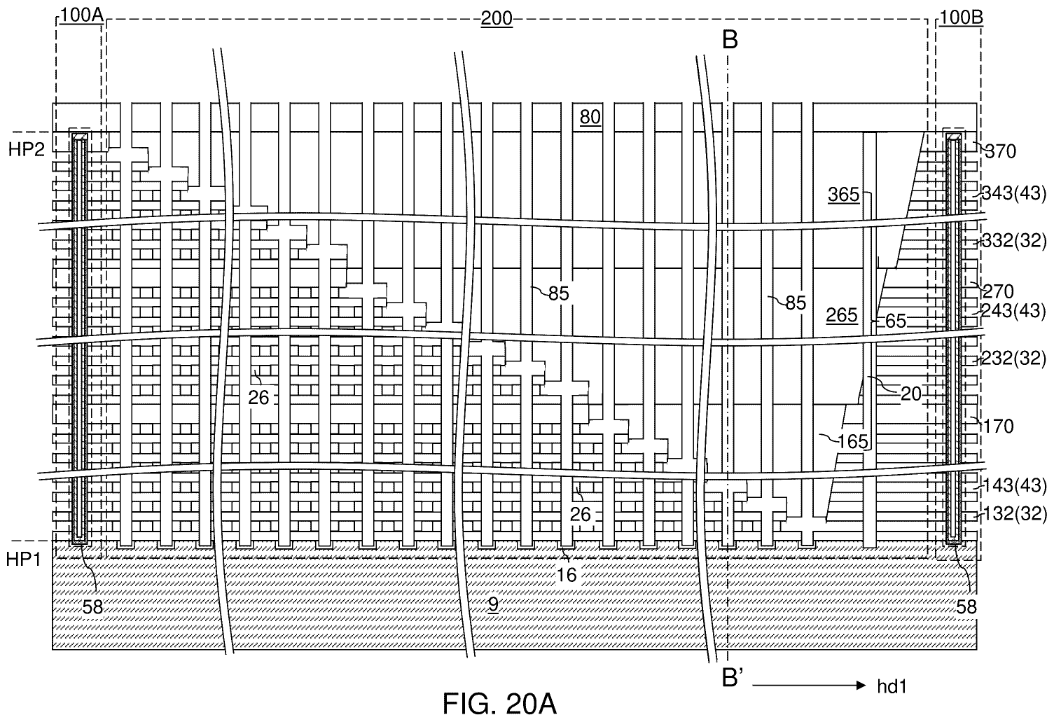

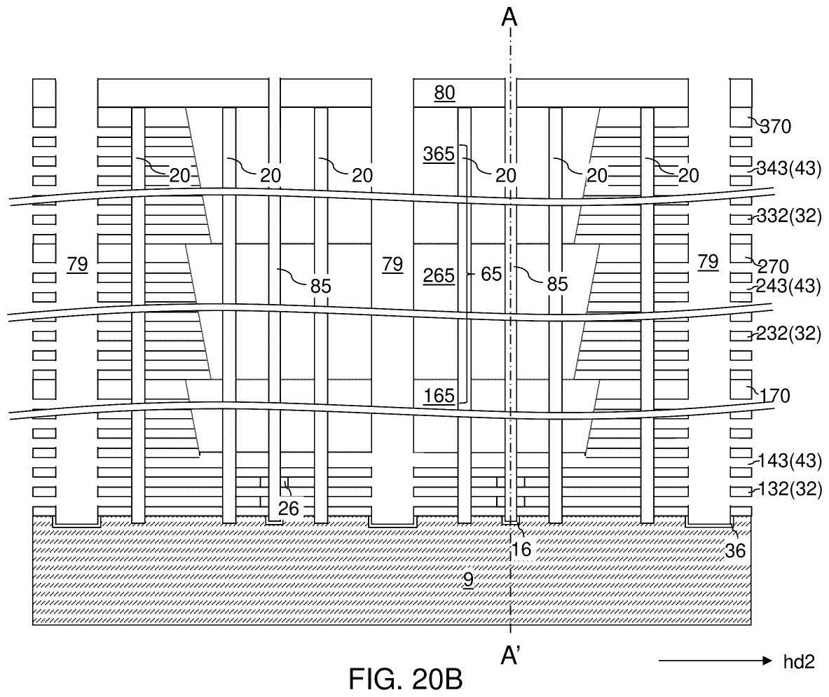

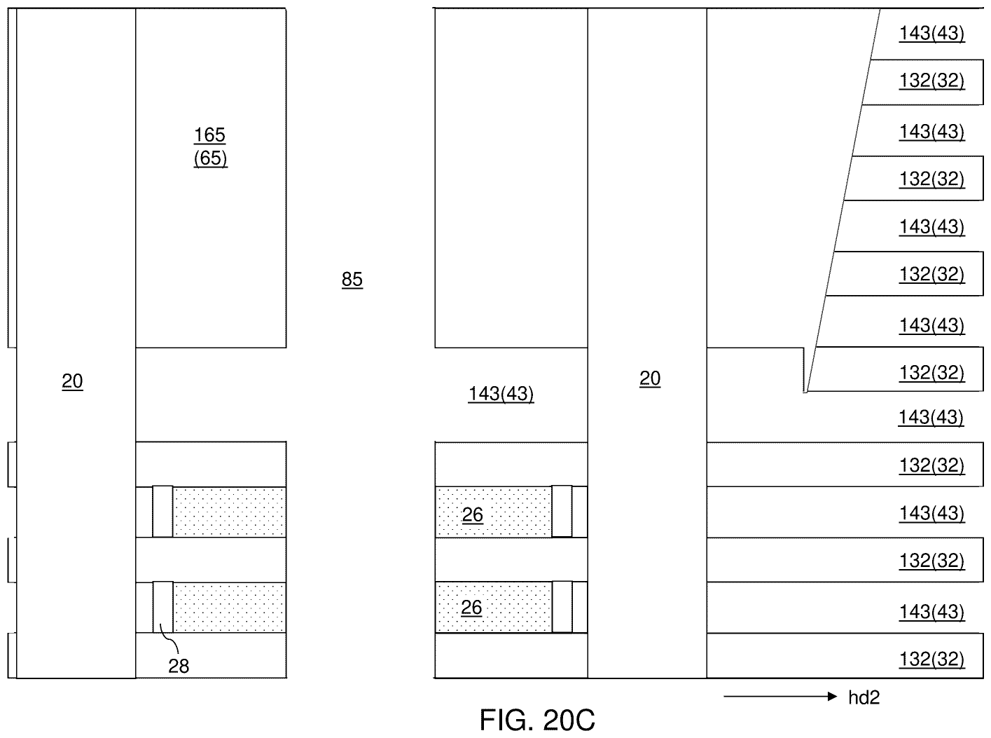

Referring to FIGS. 19A-19C, in case the substrate 9 comprises a semiconductor material, such as silicon, an oxidation process may be performed to convert physically exposed surface portions of the substrate 9 into semiconductor oxide spacer liners (36, 16), such as silicon oxide spacers. The semiconductor oxide spacer liners (36, 16) may comprise semiconductor oxide trench spacer liners 36 that are formed underneath the lateral isolation trenches 79, and semiconductor oxide spacer liners 16 that are formed underneath the contact via cavities 85. The thickness of the semiconductor oxide spacer liners (36, 16) may be in a range from 3 nm to 8 nm, although lesser and greater thicknesses may also be employed. In one embodiment, collateral oxidation of the physically exposed surfaces of the sacrificial material layers 42 may be minimized by reducing the thickness of the semiconductor oxide spacer liners (36, 16).

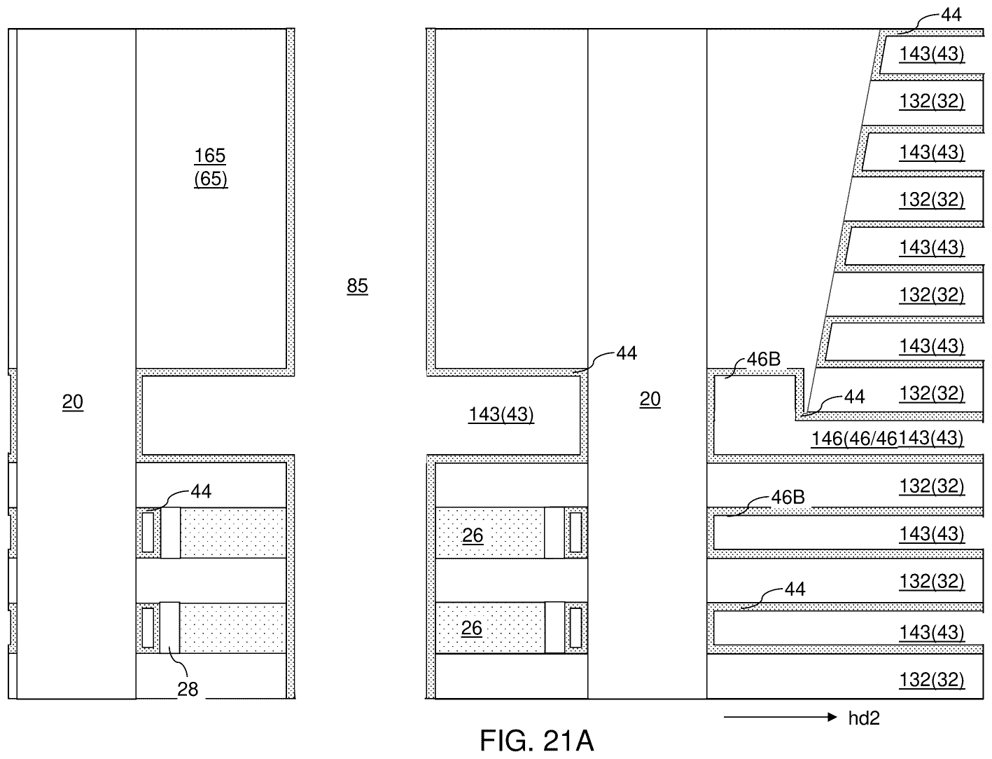

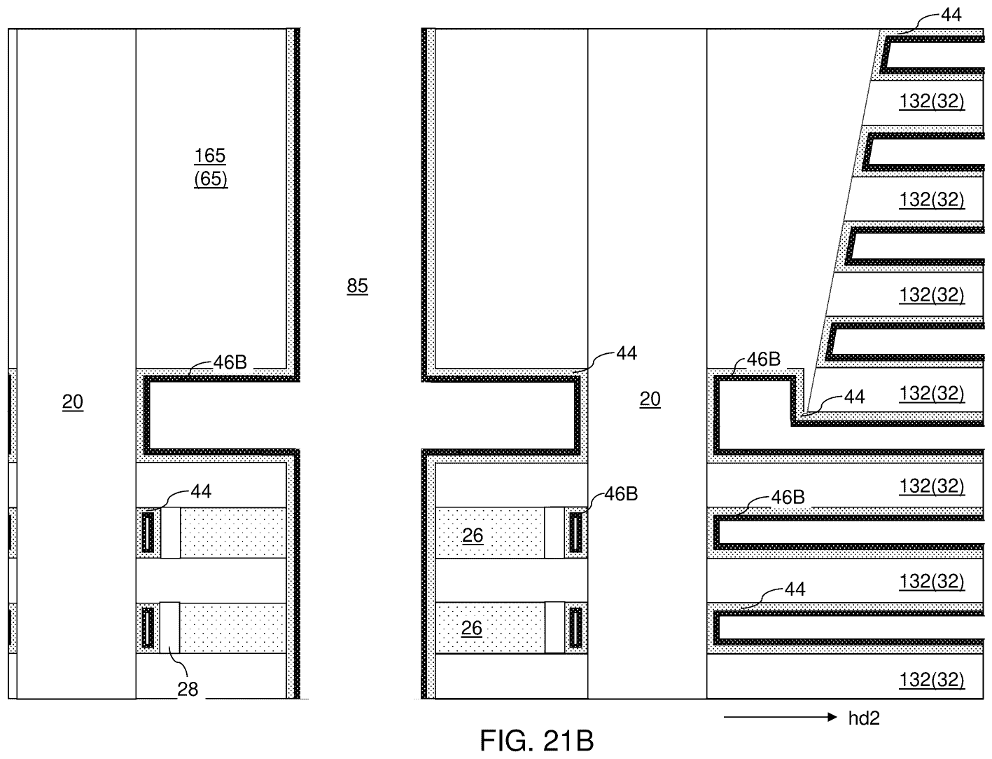

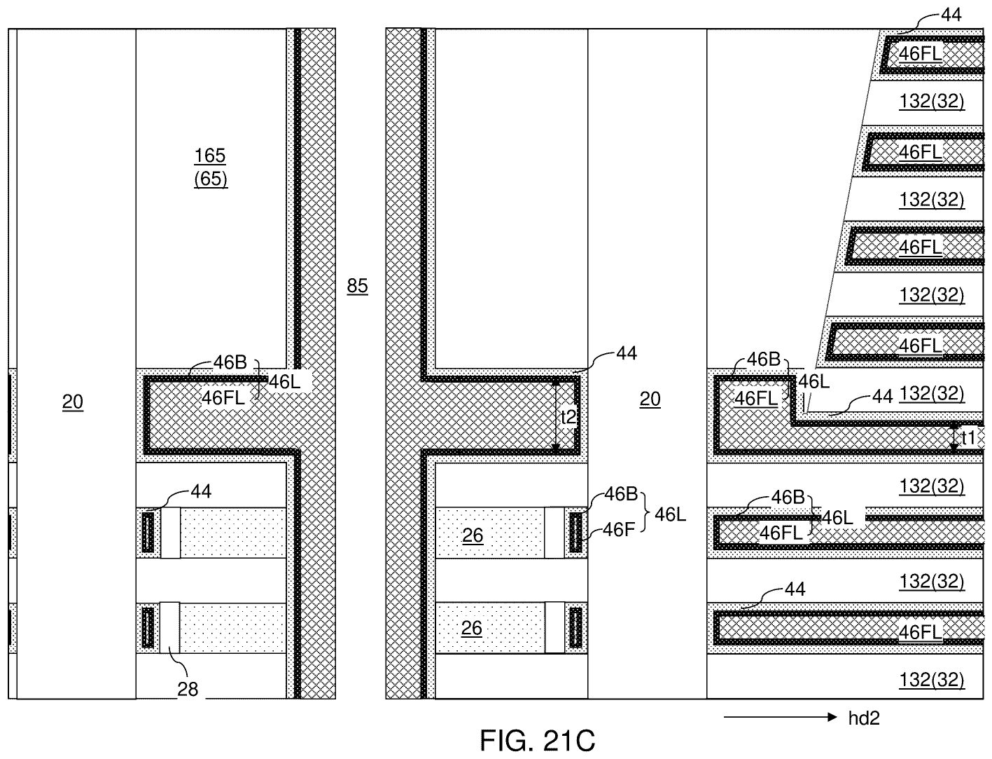

Referring to FIGS. 21A-21C, the sacrificial material layers 42 may be isotropically etched selective to the insulating layers 32 and the retro-stepped dielectric material portions 65 by supplying an isotropic etchant into the lateral isolation trenches 79. Specifically, the sacrificial material layers 42 may be isotropically etched selective to the insulating layers 32, the retro-stepped dielectric material portions (165, 265, 365), and the substrate 9 by supplying an isotropic etchant into the lateral isolation trenches 79 and into the contact via cavities 85. Thus, both the lateral isolation trenches 79 and into the contact via cavities 85 can be employed as conduits for supplying the isotropic etchant of the selective isotropic etch process. In one embodiment, an etchant that selectively etches the materials of the sacrificial material layers 42 with respect to the materials of the insulating layers 32, the retro-stepped dielectric material portions (165, 265, 365), and the material of the outermost layer of the memory films 50 may be introduced into the lateral isolation trenches, for example, using an isotropic etch process.

The isotropic etch process may be a wet etch process using a wet etch solution, or may be a gas phase (dry) etch process in which the etchant is introduced in a vapor phase into the lateral isolation trench. For example, if the sacrificial material layers 42 comprise silicon nitride, and if the insulating layers 32, the retro-stepped dielectric material portions (165, 265, 365), and the outermost layer of the memory films 50 comprise silicon oxide materials, the etch process may comprise a wet etch tank employing hot phosphoric acid, which etches silicon nitride selective to silicon oxide, silicon, and various other materials used in the art.

Lateral recesses 43 are formed in volumes from which the sacrificial material layers 42 are removed. The lateral recesses 43 include first lateral recesses 143 that are formed in volumes from which the first-tier sacrificial material layers 142 are removed, second lateral recesses 243 that are formed in volumes from which the second-tier sacrificial material layers 242 are removed, and third lateral recesses 343 that are formed in volumes from which the third-tier sacrificial material layers 342 are removed. Each of the lateral recesses 43 may be a laterally extending cavity having a greater lateral dimension that is greater than a vertical extent. In other words, the lateral dimension of each of the lateral recesses 43 may be greater than the height of the respective lateral recess. A plurality of lateral recesses 43 may be formed in the volumes from which the material of the sacrificial material layers 42 is removed. Each of the lateral recesses 43 may extend substantially parallel to the top surface of the substrate 9. A lateral recess 43 may be vertically bounded by a top surface of an underlying insulating layer 32 and a bottom surface of an overlying insulating layer 32.

FIGS. 21A-21C are sequential vertical cross-sectional views of a region of the exemplary structure during formation of an outer blocking dielectric layer 44, an optional metal-line metallic barrier liner 46B, and a metal-line metal fill material layer 46FL according to an embodiment of the present disclosure.

Referring to FIG. 21A, an outer blocking dielectric layer 44 may be conformally deposited in peripheral portions of the lateral recesses 43, the contact via cavities 85, and the lateral isolation trenches 79. The outer blocking dielectric layer 44 includes a dielectric material, such as a dielectric metal oxide (e.g., aluminum oxide, hafnium oxide, etc.). The outer blocking dielectric layer 44 may be formed as a continuous material layer by a conformal deposition process, such as an atomic layer deposition process or a chemical vapor deposition process. The combination of the contact via cavities 85 and the lateral isolation trenches 79 may be employed as a conduit for a reactant that deposits the outer blocking dielectric layer 44. The thickness of the outer blocking dielectric layer 44 may be in a range from 2 nm to 10 nm, such as from 3 nm to 8 nm, although lesser and greater thicknesses may also be employed. In one embodiment, the outer blocking dielectric layer 44 extends horizontally from a cylindrical surface segment of a sidewall of each memory opening fill structure 58 to a respective contact via cavity 85 and extends vertically from a first horizontal plane HP1 including a bottommost surface of the alternating stack (32, 46) to a second horizontal plane HP2 including a top surface of the memory opening fill structure 58.

Referring to FIG. 21B, an optional metal-line metallic barrier liner 46B may be conformally deposited on the physically exposed surfaces of the outer blocking dielectric layer 44 in peripheral portions of the lateral recesses 43, the contact via cavities 85, and the lateral isolation trenches 79. The metal-line metallic barrier liner 46B comprises a metallic diffusion barrier material. For example, the metal-line metallic barrier liner 46B comprises a conductive metallic nitride material, such as TiN, TaN, WN, and/or MoN. The metal-line metallic barrier liner 46B may be formed as a continuous material layer by a conformal deposition process, such as an atomic layer deposition process or a chemical vapor deposition process. The combination of the contact via cavities 85 and the lateral isolation trenches 79 may be employed as a conduit for a reactant that deposits the metal-line metallic barrier liner 46B. The thickness of the metal-line metallic barrier liner 46B may be in a range from 1.5 nm to 8 nm, such as from 3 nm to 6 nm, although lesser and greater thicknesses may also be employed. In one embodiment, the metal-line metallic barrier liner 46B extends continuously over the entirety of the outer blocking dielectric layer 44 as a single continuous material layer. Alternatively, the metal-line metallic barrier liner 46B may be omitted if the metal-line metal fill material layer 46FL described below comprises a metal, such as Mo, which does not require a diffusion barrier.

Referring to FIG. 21C, a metal-line metal fill material layer 46FL may be conformally deposited on the physically exposed surfaces of the metal-line metallic barrier liner 46B in remaining unfilled volumes of the lateral recesses 43 and in peripheral regions of the contact via cavities 85 and the lateral isolation trenches 79. The metal-line metal fill material layer 46FL comprises a metal material that provides high electrical conductivity. For example, the metal-line metal fill material layer 46FL comprises and/or consists essentially of an elemental metal such as W, Co, Ru, Mo, Cu, or a combination thereof. The metal-line metal fill material layer 46FL may be formed by a conformal deposition process, such as a chemical vapor deposition process. The combination of the contact via cavities 85 and the lateral isolation trenches 79 may be employed as a conduit for a reactant that deposits the metal-line metal fill material layer 46FL. In one embodiment, the metal-line metal fill material layer 46FL extends continuously over the entirety of the metal-line metallic barrier liner 46B as a single continuous material layer.

The combination of the outer blocking dielectric layer 44, the metal-line metallic barrier liner 46B, and the metal-line metal fill material layer 46FL may fill the entirety of the laterally recesses 43, and may fill peripheral portions of the contact via cavities 85 and the lateral isolation trenches 79 without completely filling the entire contact via cavities 85 and the entire lateral isolation trenches 79. The combination of the metal-line metallic barrier liner 46B and the metal-line metal fill material layer 46FL is herein referred to as a metal-line electrically conductive material layer 46L.

Generally, at least one conformal deposition process can be performed after formation of the outer blocking dielectric layer 44 to deposit at least one first electrically conductive material of the metal-line electrically conductive material layer 46L in remaining volumes of the lateral recesses 43, in a tubular peripheral region of each contact via cavity 85, and in an elongated tubular region of each lateral isolation trench 79. The portions of the metal-line electrically conductive material layer 46L that replace unthickened portions of the sacrificial material layers 42 may have a first thickness t1, and the portions of the metal-line electrically conductive material layer 46L that replace the thickened portions of the sacrificial material layers 42 may have a second thickness t2 which is greater than the first thickness t1.

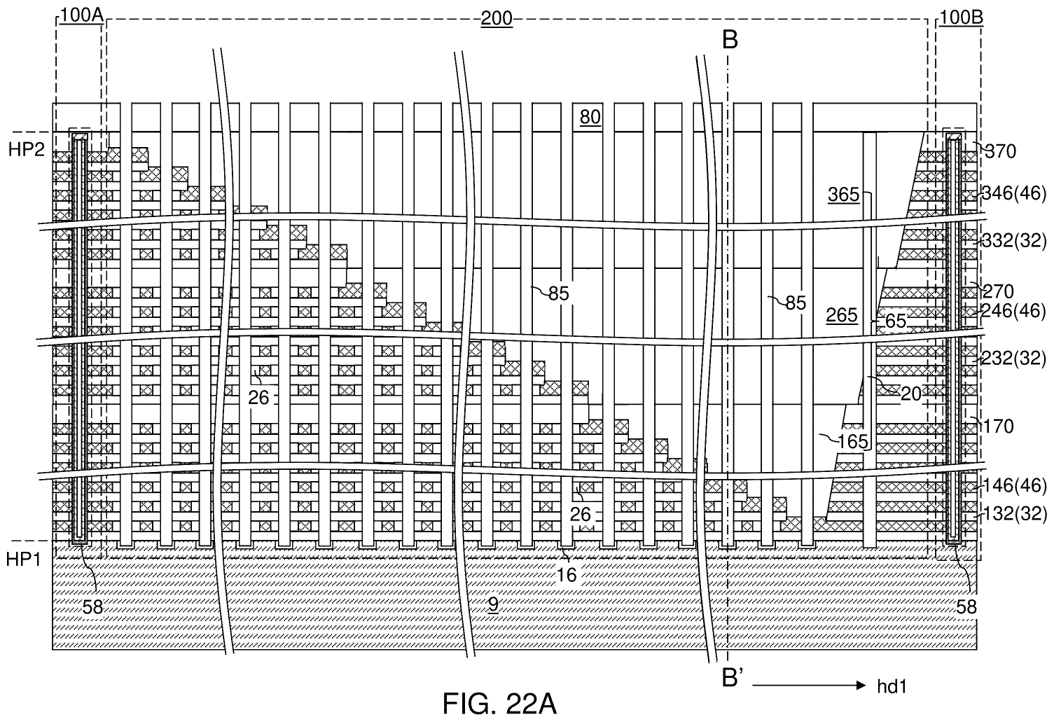

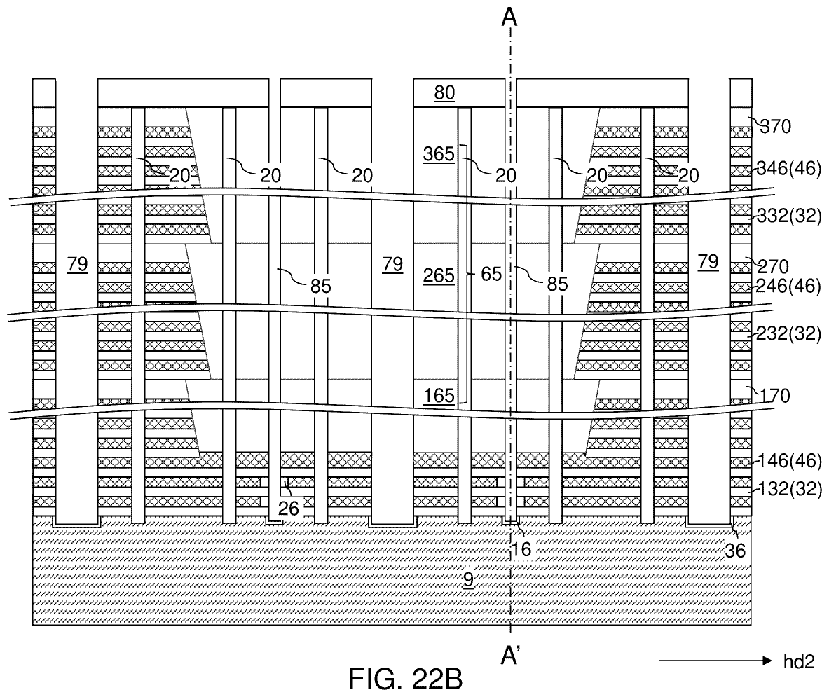

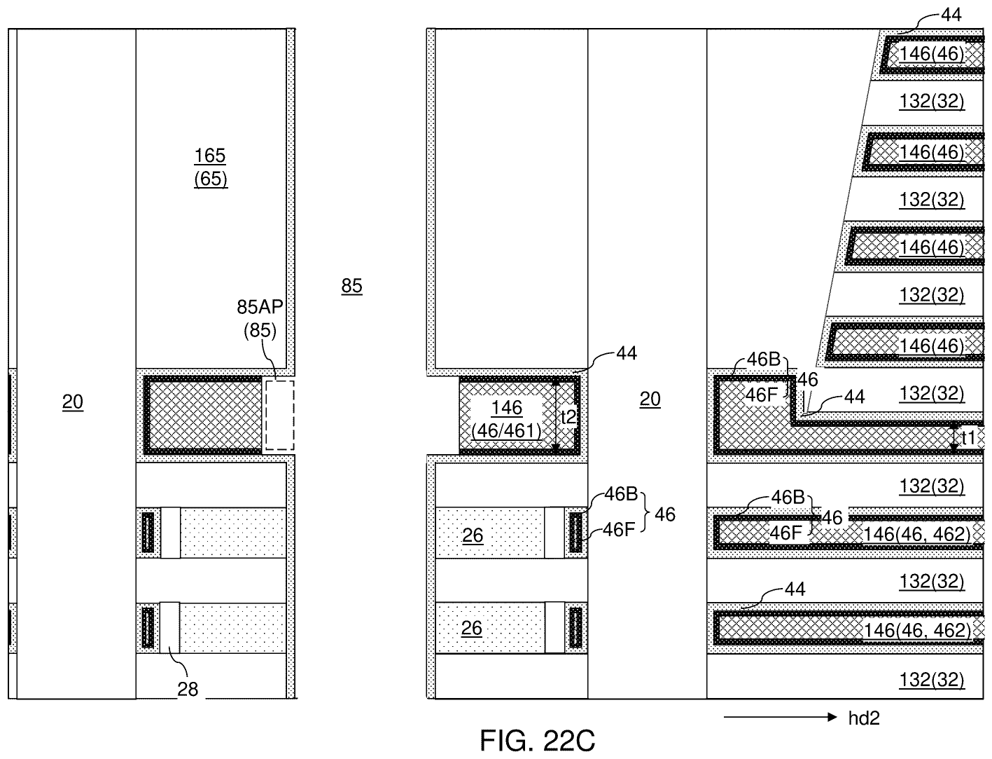

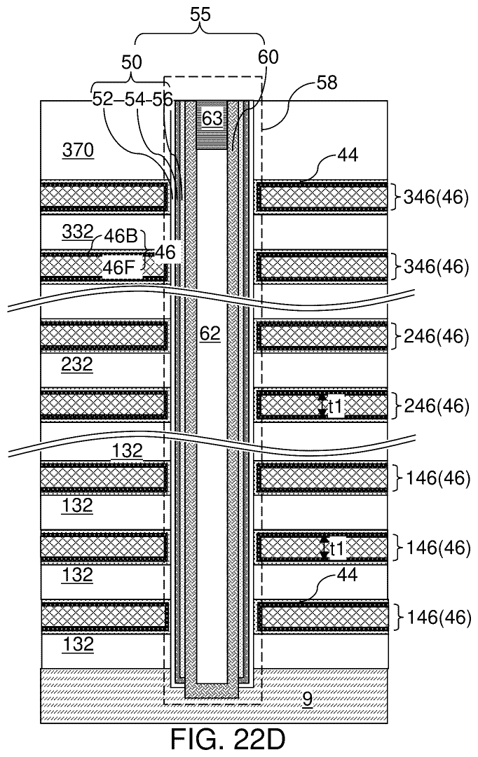

Referring to FIGS. 22A-22D, a selective etch process can be performed to etch back the at least one first electrically conductive material of the metal-line electrically conductive material layer 46L (which may be a combination of the material of the metal-line metallic barrier liner 46B and the material of the metal-line metal fill material layer 46FL) selective to the material of the outer blocking dielectric layer 44. Each portion of the at least one first electrically conductive material of the metal-line electrically conductive material layer 46L can be removed from the peripheral regions of the contact via cavities 85, and from the peripheral regions of the lateral isolation trenches 79.

Remaining portions of at least one first electrically conductive material comprise electrically conductive layers 46. The electrically conductive layers 46 comprise first-tier electrically conductive layers 146, second-tier electrically conductive layers 246, and third-tier electrically conductive layers 346. A plurality of first-tier electrically conductive layers 146 may be formed in the plurality of first lateral recesses 143, a plurality of second-tier electrically conductive layers 246 may be formed in the plurality of second lateral recesses 243, and a plurality of third-tier electrically conductive layers 346 may be formed in the plurality of third lateral recesses 343. Each of the electrically conductive layers 46 may include a respective metal-line metallic barrier liner 46B (which is a patterned portion of the metal-line metallic barrier liner 46B as formed at the processing steps of FIG. 21B) and a respective metal-line metal fill material portion 46F (which is a patterned portion of the metal-line metal fill material layer 46FL as formed at the processing steps of FIG. 21C).

For each contact via cavity 85, a sidewall (which may be a cylindrical sidewall) of an electrically conductive layer 46 can be physically exposed. The electrically conductive layer 46 having a sidewall that is physically exposed to a contact via cavity 85 is herein referred to as a first electrically conductive layer 461 for the contact via cavity 85. Thus, each first electrically conductive layer 461 is defined relative to a respective contact via cavity 85. Generally, for each contact via cavity 85, an electrically conductive layer 46 can be physically exposed the contact via cavity 85. If present, any electrically conductive layer 46 that underlies the first sacrificial material layer 421 for any given contact via cavity 85 is herein referred to as a second electrically conductive layer 462.

In summary, the sacrificial material layers 42 are replaced with replacement material portions that comprise electrically conductive layers 46 employing the contact via cavities 85 and the lateral isolation trenches 79 as a conduit for an etchant that removes the sacrificial material layers 42 and as a conduit for reactants that deposits the electrically conductive layers 46. Each electrically conductive layer 46 can be formed in the volume of a respective one of the sacrificial material layers 42.

In one embodiment, the selective etch process may comprise a selective isotropic etch process or may include an isotropic etch step or component. In this embodiment, for each contact via cavity 85, the first electrically conductive layer 146 may have a cylindrical sidewall that is laterally recessed outward relative to a cylindrical vertical plane including an inner sidewall of a vertically-extending portion of the outer blocking dielectric layer 44 that is located in the contact via cavity 85. The lateral recess distance of the cylindrical sidewall of the first electrically conductive layer 461 relative to the cylindrical vertical plane including the inner sidewall of the vertically-extending portion of the outer blocking dielectric layer 44 that is located in the contact via cavity 85 may be in a range from 1 nm to 60 nm, such as from 3 nm to 30 nm, although lesser and greater lateral recess distances may also be employed. In this case, each contact via cavity 85 may comprise an annular protrusion portion 85AP located at the level of the first electrically conductive layer 461.

Each electrically conductive layer 46 may have the first thickness t1 in each area that underlies any overlying electrically conductive layer 46. Each electrically conductive layer 46 other than the topmost electrically conductive layer 46 may have a second thickness t2 in each area that does not underlie any overlying electrically conductive layer 46. The topmost electrically conductive layer 46 may have the first thickness t1 outside the areas of the retro-stepped dielectric material portions 65, and may have the second thickness t2 within the areas of the retro-stepped dielectric material portions 65. The height of the annular protrusion portions 85AP may be the same as the second thickness t2.

For each contact via cavity 85 that vertically extends through at least three electrically conductive layers 46, a vertical stack of annular dielectric spacers 26 can be located at levels of a subset of the electrically conductive layers 46 that underlies the first electrically conductive layer 461. The annular dielectric spacers 26 may have a respective inner cylindrical sidewall that contacts a lower tubular portion of the outer blocking dielectric layer 44 that vertically extends through for the contact via cavity 85 at the vertical level of the second electrically conductive layers 462 (which underlie the first electrically conductive layer 461). An upper tubular portion of the outer blocking dielectric layer 44 may be in contact with a cylindrical sidewall of one or more of the at least one retro-stepped dielectric material portion 65. Generally, the outer blocking dielectric layer 44 vertically extends continuously from the bottommost surface of the contact via cavity 85 (which underlies the second horizontal plane HP2) to the top surface of the contact-level dielectric layer 80 (which overlies the first horizontal plane HP1).

After the step shown in FIG. 22C, the first electrically conductive layer 461 has a cylindrical sidewall that is physically exposed to the respective contact via cavity 85 (e.g., that is exposed to the annular protrusion portions 85AP of the respective contact via cavity). The first electrically conductive layer 461 comprises a metal-line metallic barrier liner 46B and a metal-line metal fill material portion 46F that is embedded within the metal-line metallic barrier liner 46B. The electrically conductive layers 46 within the at least one alternating stack (32, 46) has a first thickness t1 around each memory opening 49. In one embodiment, each of the annular dielectric spacers 26 may have a vertical thickness that equals the sum of the first thickness t1 and twice a thickness of the outer blocking dielectric layer 44.

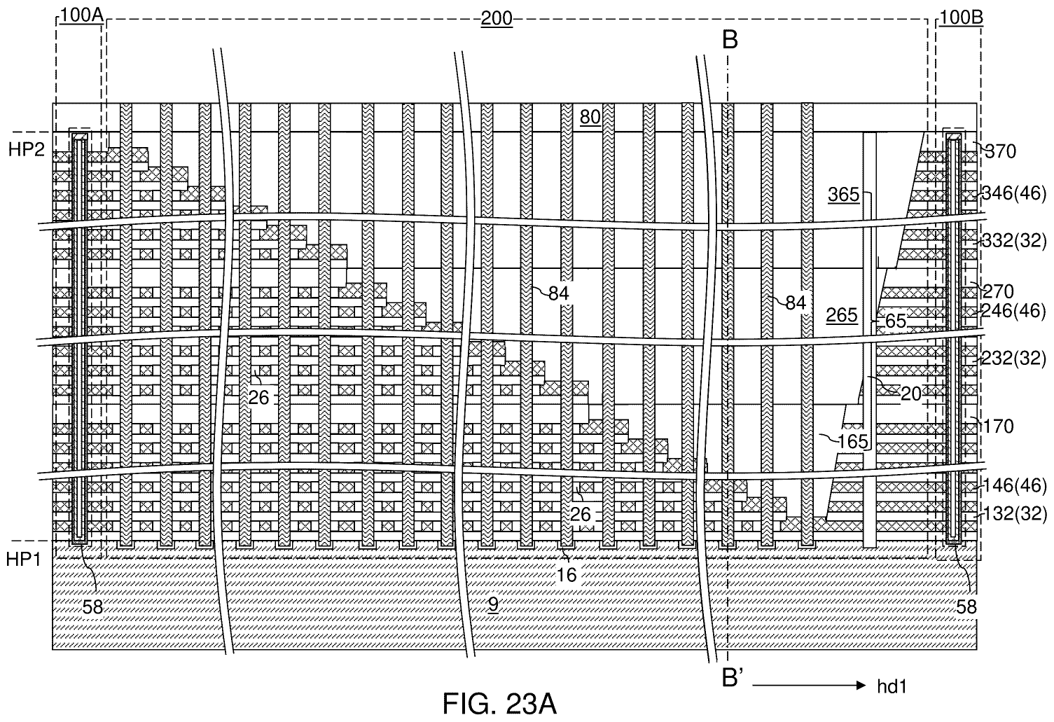

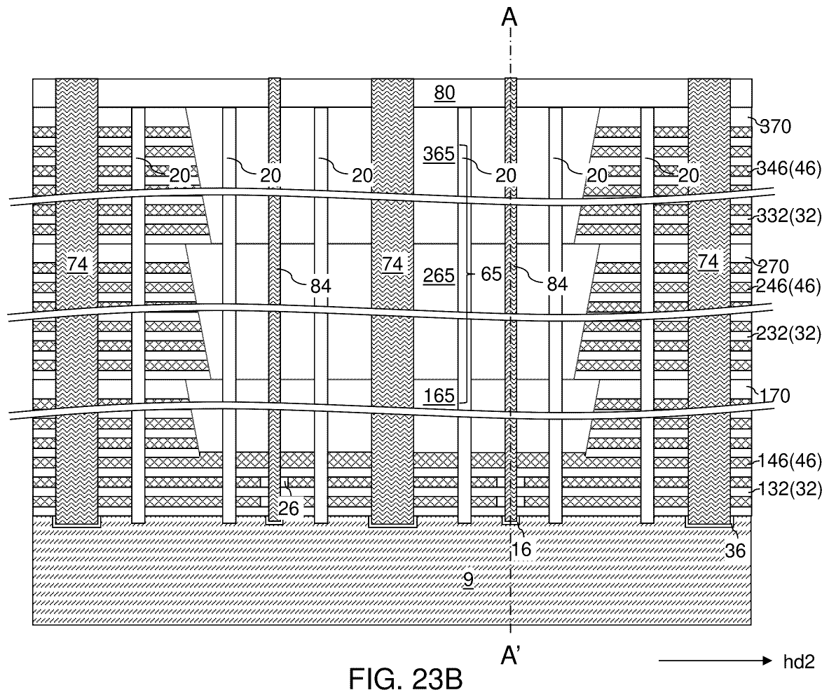

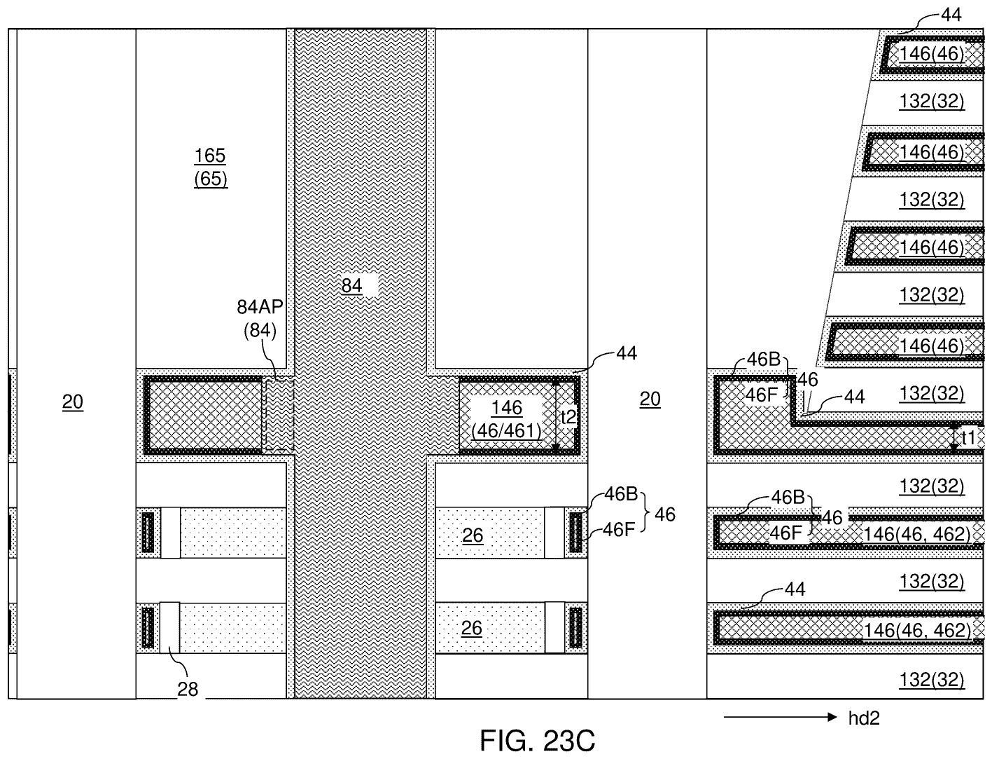

Referring to FIGS. 23A-23C, a sacrificial via fill material can be deposited in the contact via cavities 85 and the lateral isolation trenches 79, and excess portions of the sacrificial via fill material can be removed from above the horizontal plane including the top surface of the contact-level dielectric layer 80. The sacrificial via fill material may comprise a semiconductor material, such as amorphous silicon or polysilicon, or may comprise a carbon-based material, such as amorphous carbon. Each remaining portion of the sacrificial via fill material that fills a contact via cavity 85 comprises a sacrificial contact via structure 84. Each remaining portion of the sacrificial via fill material that fills a lateral isolation trench 79 comprises a sacrificial lateral isolation trench fill structure 74. Each sacrificial contact via structure 84 may comprise a cylindrical portion and an annular protrusion portion 84AP that laterally protrudes from the cylindrical portion and having the height that equals the second thickness t2.

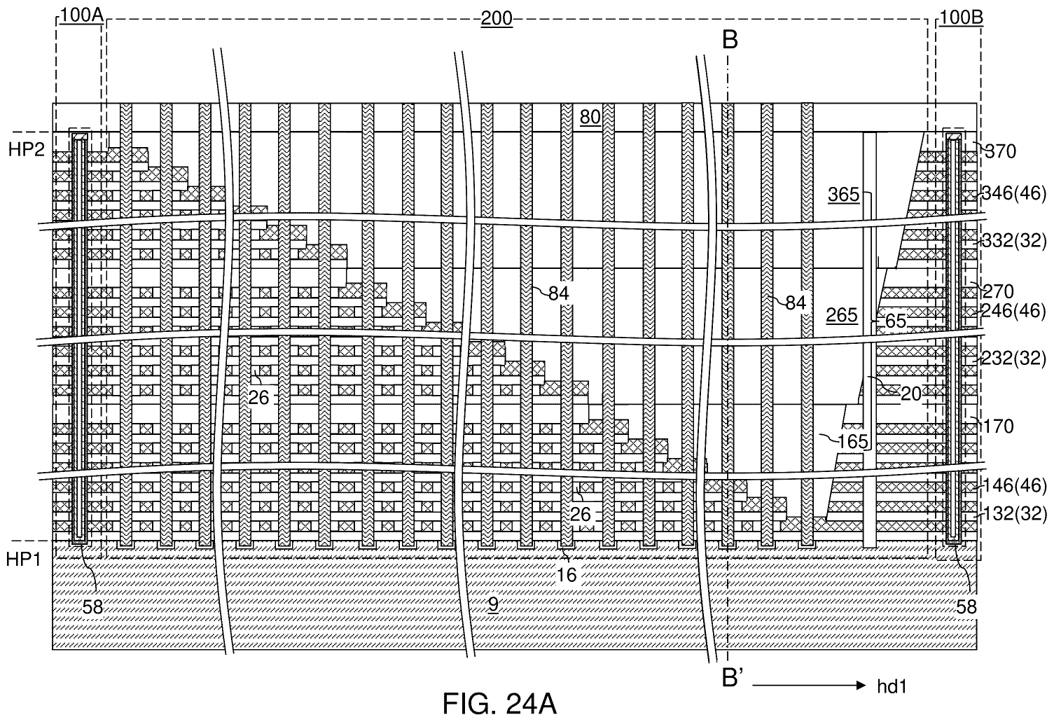

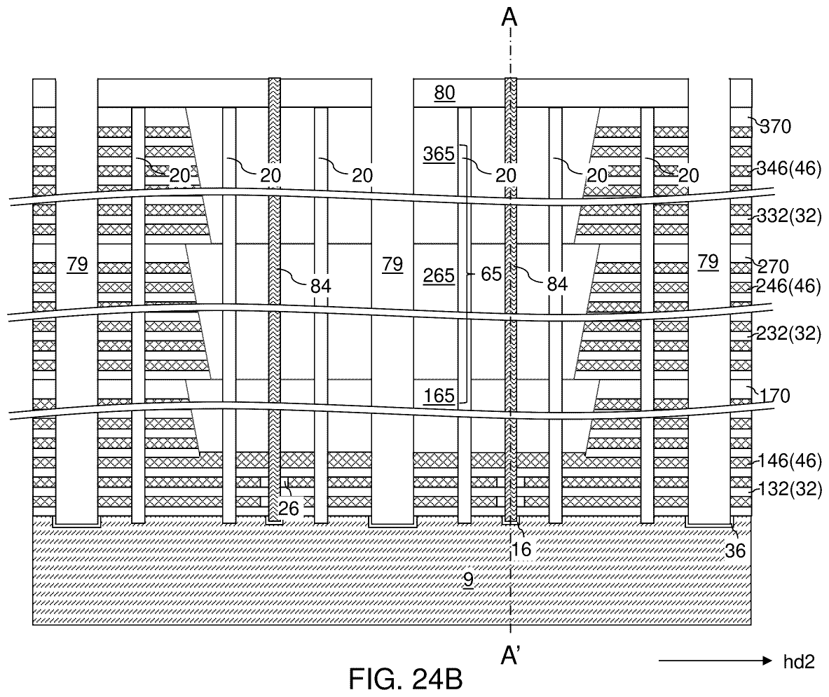

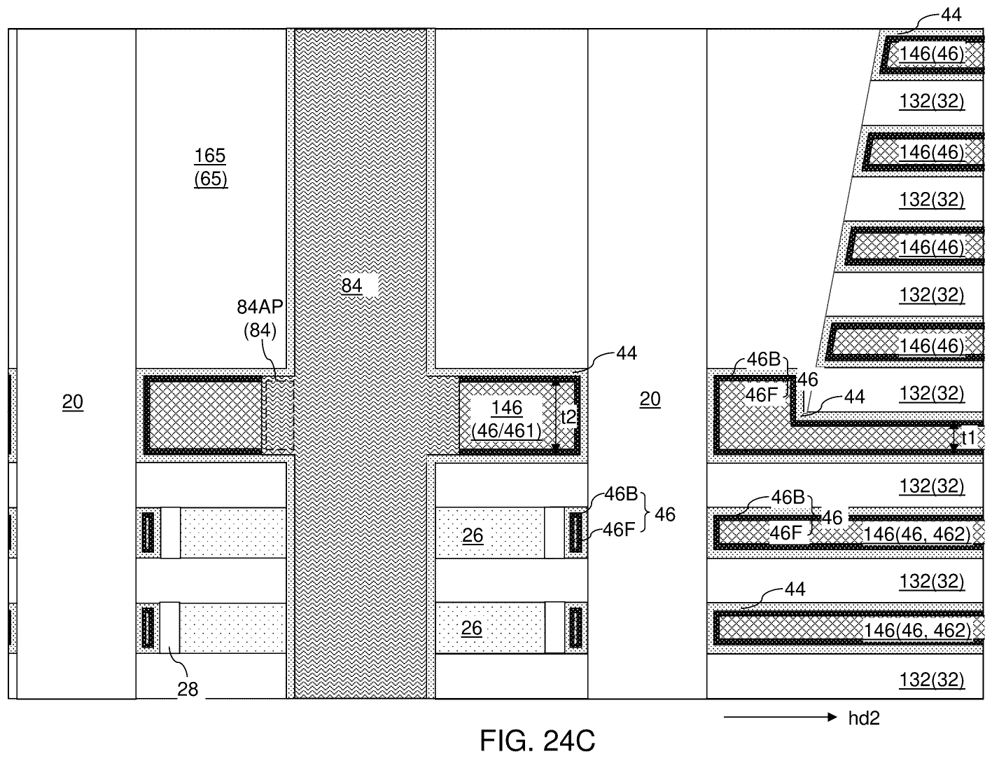

Referring to FIGS. 24A-24C, a masking material layer (not shown) can be applied over the contact-level dielectric layer 80, and can be lithographically patterned to cover the sacrificial contact via structures 84 without covering the sacrificial lateral isolation trench fill structures 74. The sacrificial lateral isolation trench fill structures 74 can be removed selective to the at least one alternating stack (32, 46), the contact-level dielectric layers 80, the various insulating cap layers (170, 270, 370), and the semiconductor oxide trench spacer liners 36 by performing a selective removal process. Voids are formed in the volumes of the lateral isolation trenches 79. The selective removal process may comprise a selective etch process or an ashing process (for carbon sacrificial material). The patterned masking material layer can be subsequently removed selective to the sacrificial contact via structures 84, the at least one alternating stack (32, 46), the contact-level dielectric layers 80, the various insulating cap layers (170, 270, 370), and the semiconductor oxide trench spacer liners 36.

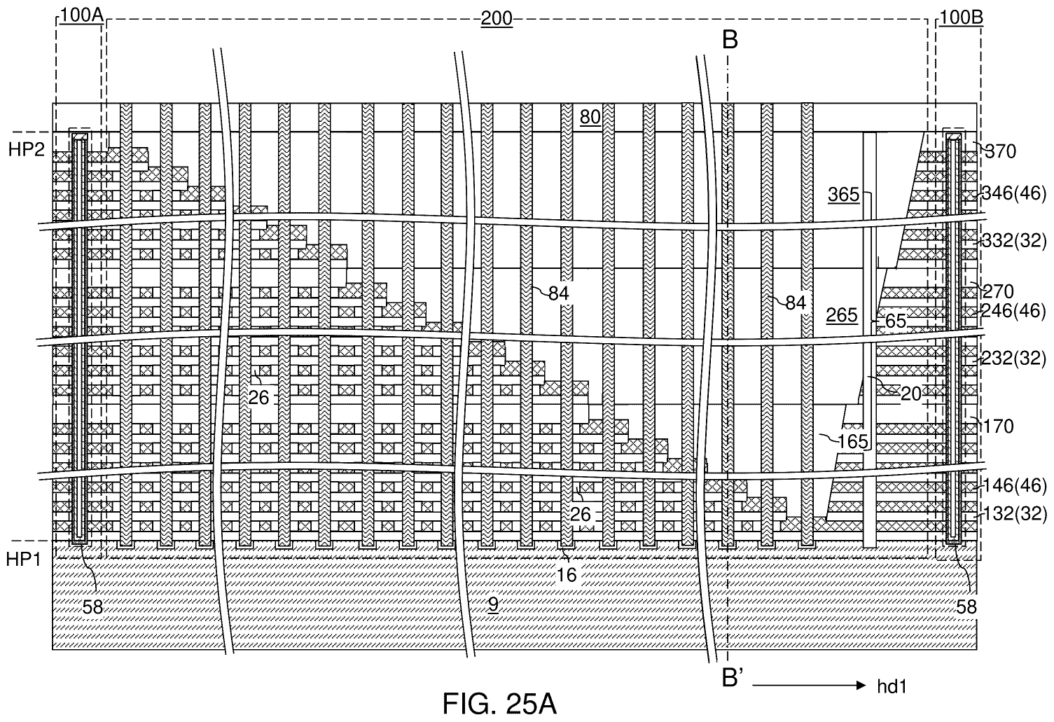

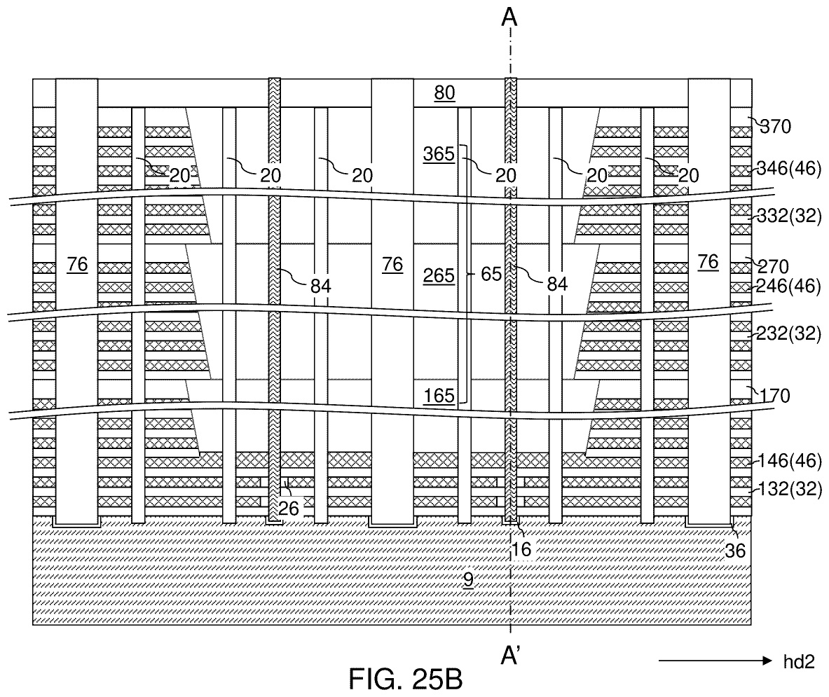

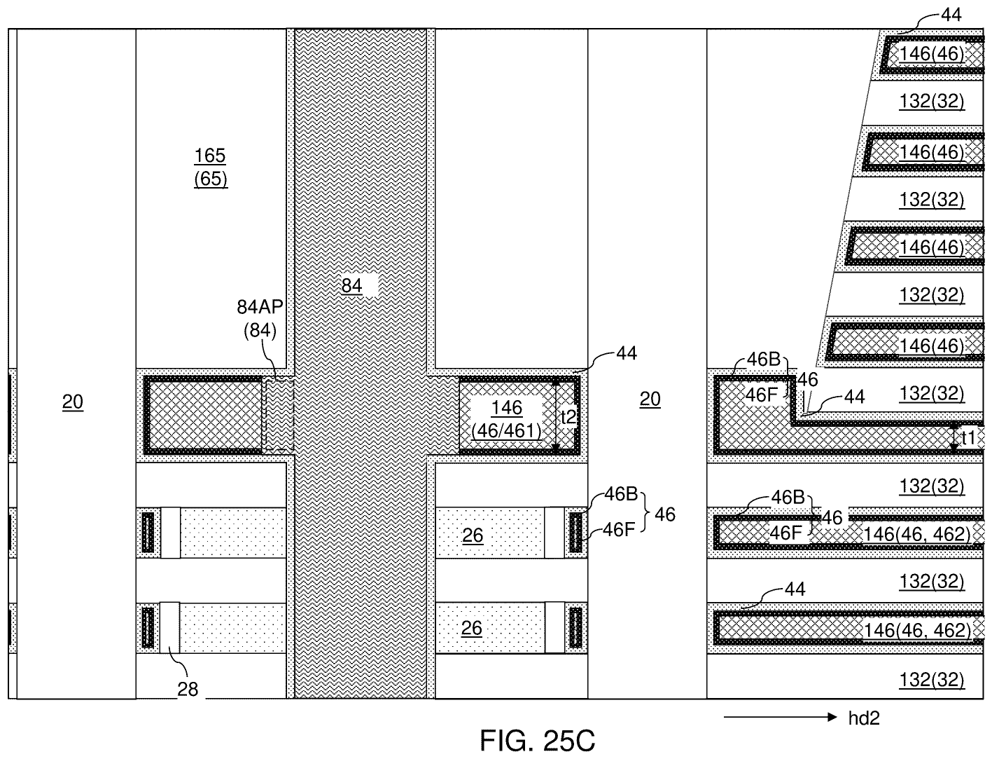

Referring to FIGS. 25A-25C, a dielectric fill material, such as undoped silicate glass or a doped silicate glass can be deposited in the lateral isolation trenches 79 by a conformal deposition process. A planarization process can be performed to remove the portion of the deposited dielectric fill material from above the horizontal plane including the top surface of the contact-level dielectric layer 80. The planarization process may comprise a recess etch process and/or a chemical mechanical polishing process. Each remaining portion of the dielectric fill material that fills a respective one of the lateral isolation trenches 79 constitute a lateral isolation trench fill structure 76.

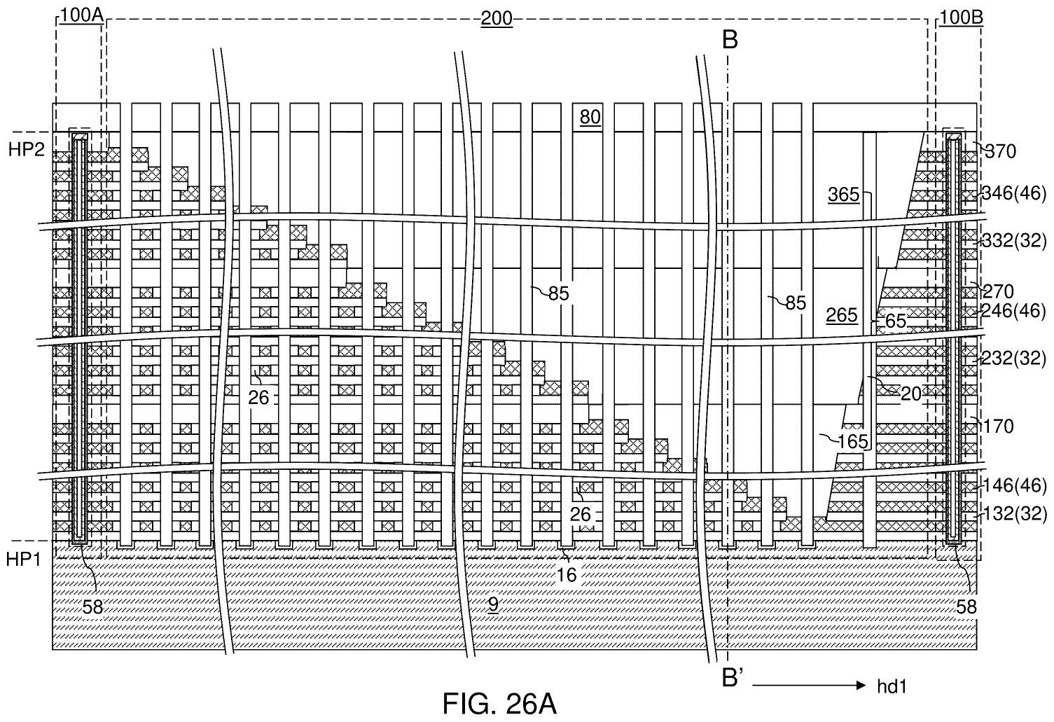

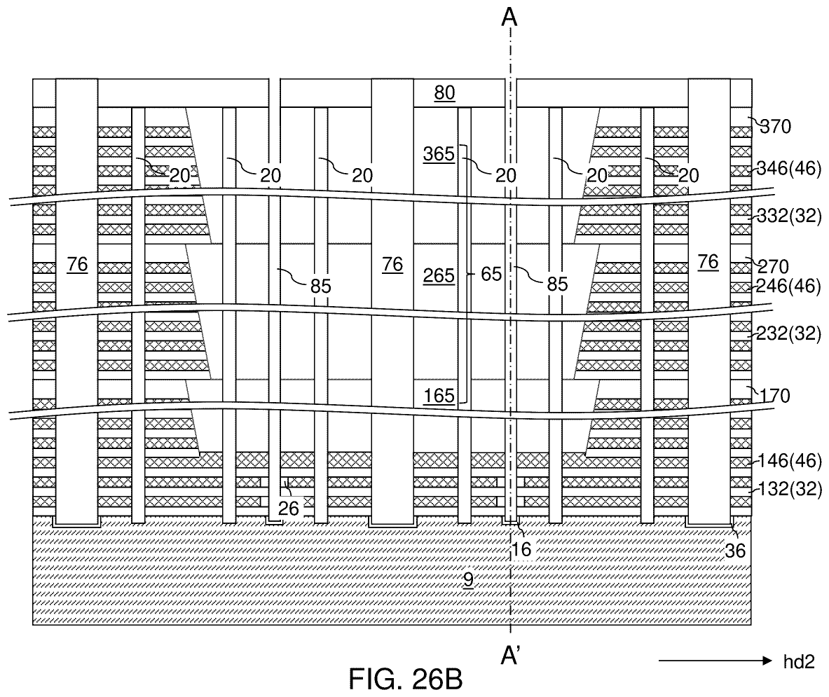

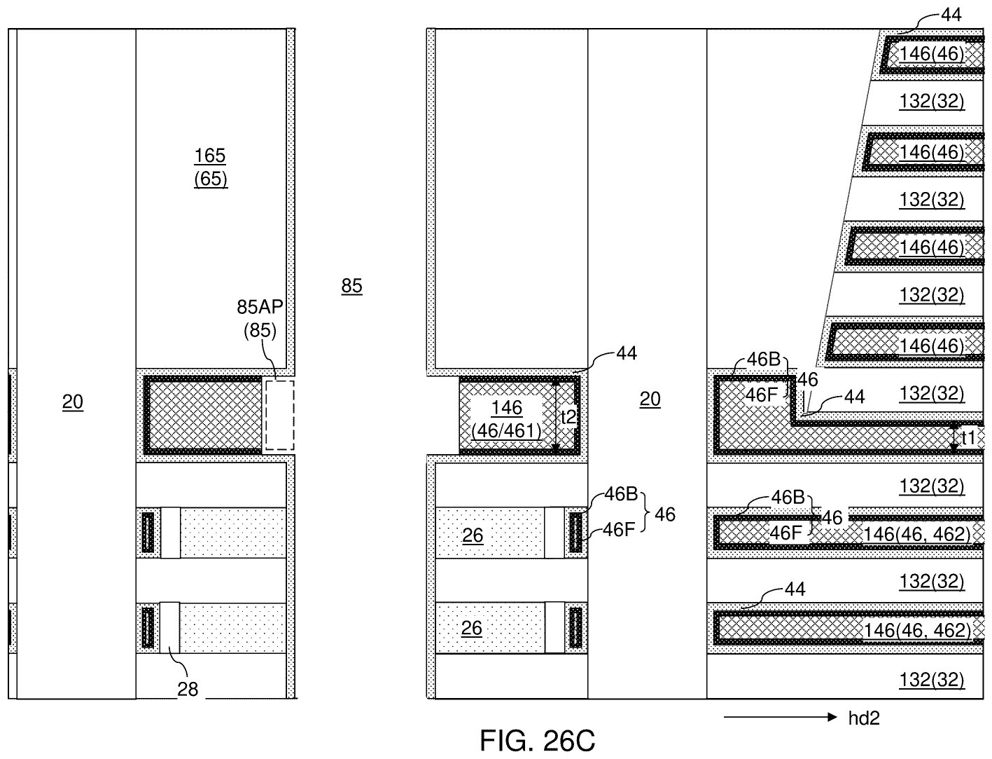

Referring to FIGS. 26A-26C, the sacrificial contact via structures 84 can be removed selective to the contact-level dielectric layers 80 and the lateral isolation trench fill structures 76 by performing a selective removal process. Voids are formed in the volumes of the contact via cavities 85. The selective removal process may comprise a selective etch process or an ashing process.

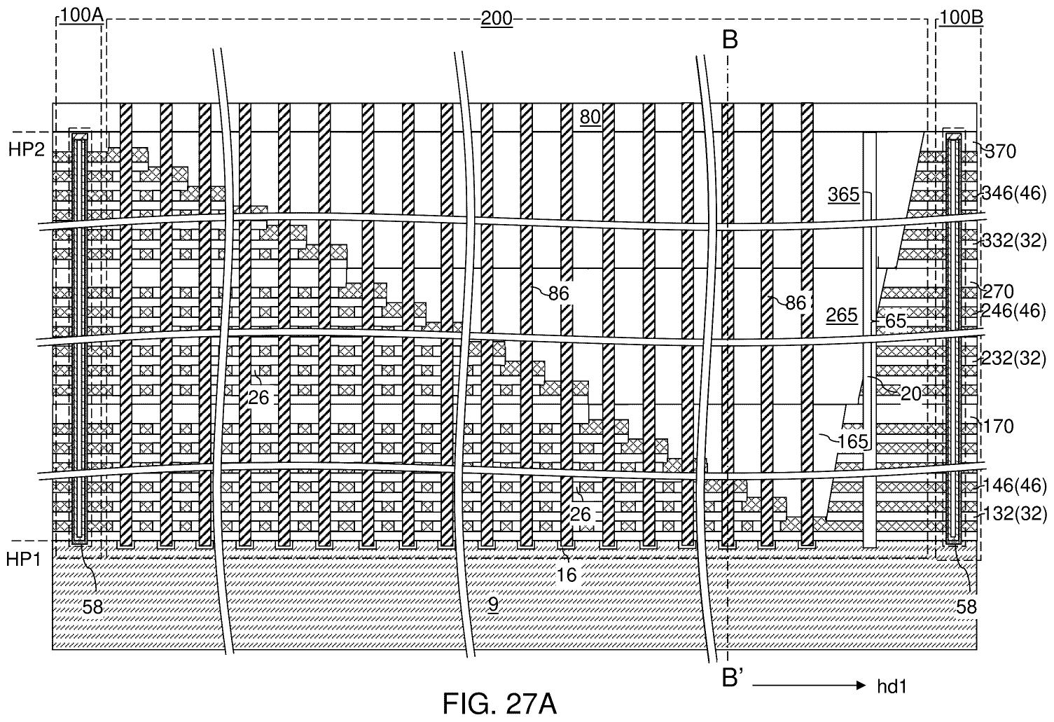

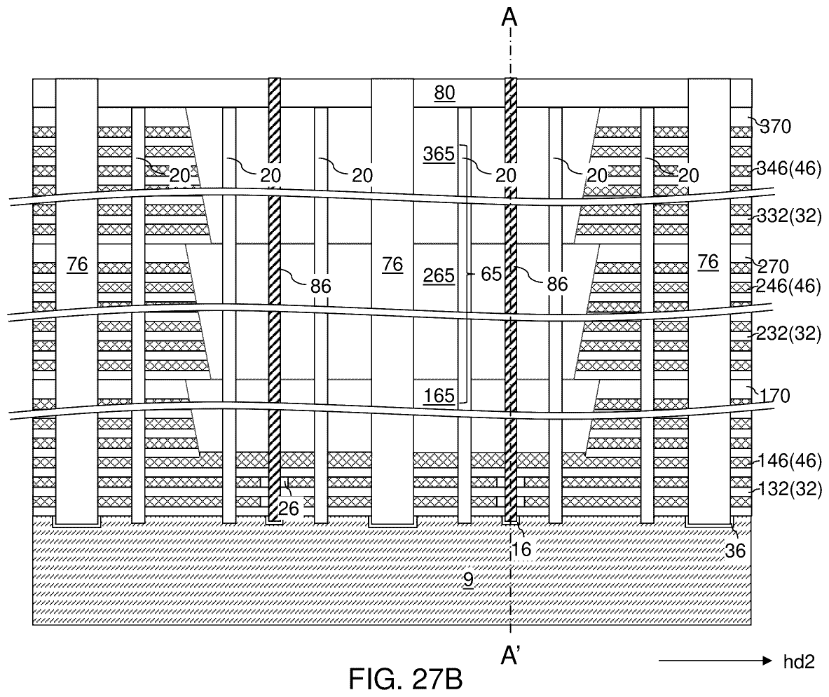

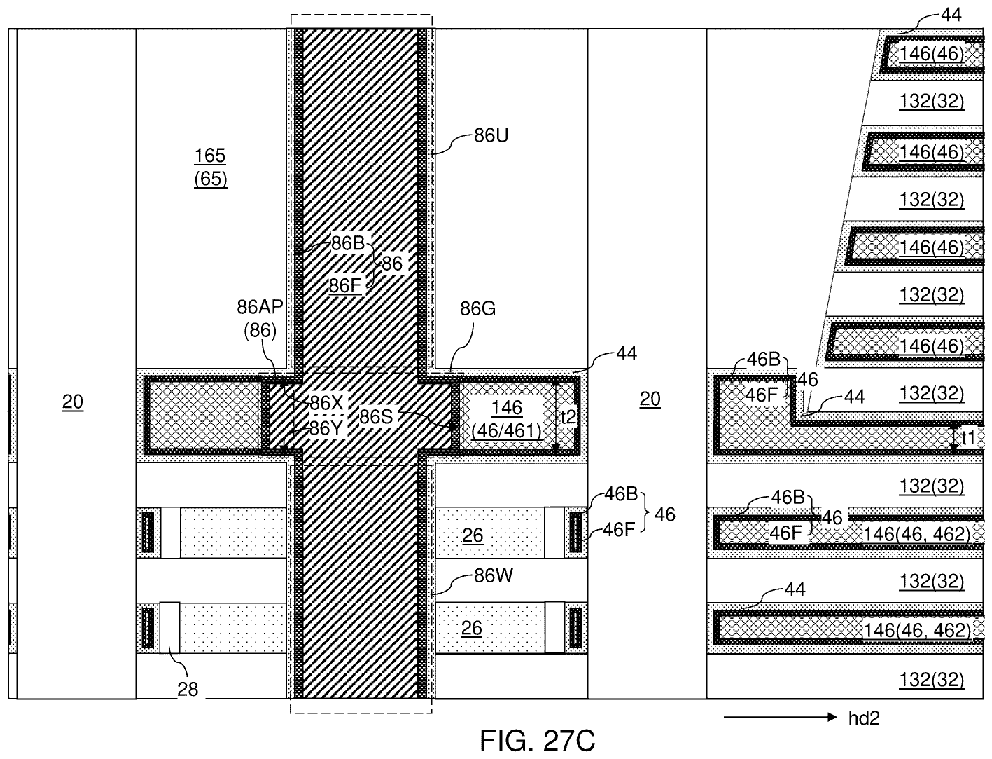

Referring to FIGS. 27A-27C, at least one second electrically conductive material can be deposited in each of the contact via cavities 85. Excess portions of the at least one second electrically conductive material can be removed from above the horizontal plane including the top surface of the contact-level dielectric layer 80. Each remaining portion of the at least one second electrically conductive material that fills a respective one of the contact via cavities 85 constitutes a contact via structure that contacts a respective first electrically conductive layer 461 among the electrically conductive layers 46. Each such contact via structure is herein referred to as a layer contact via structure 86.

In one embodiment, the at least one second electrically conductive material may comprise a contact-via metallic barrier material and a contact-via metal fill material. In this case, each layer contact via structure 86 may comprise a metallic barrier liner (which is herein referred to as a contact-via metallic barrier liner 86B) and a metal fill material portion (which is herein referred to as a contact-via metal fill material portion 86F) that is laterally surrounded by the contact-via metallic barrier liner 86B. The contact-via metallic barrier liner 86B comprises the contact-via metallic barrier material, and the contact-via metal fill material portion 86F comprises the contact-via metal fill material. Alternatively, the contact-via metallic barrier liner 86B may be omitted if the contact-via metal fill material portion 86F comprises a metal, such as Mo, which may be used without a metal nitride diffusion barrier.

The contact-via metallic barrier material comprises a metallic diffusion barrier material. For example, the contact-via metallic barrier material comprises a conductive metallic nitride material such as TiN, TaN, WN, and/or MoN. The contact-via metallic barrier material may be deposited as a continuous material layer having a uniform thickness throughout by a conformal deposition process such as a chemical vapor deposition process. The thickness of the contact-via metallic barrier material may be in a range from 3 nm to 60 nm, such as from 6 nm to 30 nm, although lesser and greater thicknesses may also be employed.

The contact-via metal fill material comprises a metal fill material that provides high electrical conductivity. For example, the contact-via metal fill material comprises, and/or consists essentially of, an elemental metal such as W, Co, Ru, Mo, Cu, or a combination thereof. The contact-via metal fill material may be formed by a conformal deposition process such as a chemical vapor deposition process.

Each layer contact via structure 86 contacts a cylindrical sidewall surface of a respective one of the electrically conductive layers 46. Thus, for each layer contact via structure 86, a first electrically conductive layer 461 is the electrically conductive layer 46 that is contacted by the layer contact via structure 86. In other words, each layer contact via structure 86 can be formed in a respective contact via cavity 85 directly on a cylindrical surface of a respective first electrically conductive layer 461. In case any electrically conductive layer 46 underlies the first electrically conductive layer 461, any such underlying electrically conductive layer 46 is herein referred to as a second electrically conductive layer 462.

The exemplary structure illustrated in FIGS. 27A-27C comprises a device structure that includes: at least one alternating stack (32, 46) of respective insulating layers 32 and respective electrically conductive layers 46; a memory opening 49 vertically extending through each layer within the at least one alternating stack (32, 46); and a memory opening fill structure 58 located in the memory opening 49 and comprising a vertical stack of memory elements (which may comprise portions of a memory material layer 54) and a vertical semiconductor channel 60. Each of the electrically conductive layers 46 is laterally spaced from the memory opening fill structure 58 by an outer blocking dielectric layer 44. A layer contact via structure 86 is in contact with a first electrically conductive layer 461 of the electrically conductive layers 46 within the at least one alternating stack (32, 46), wherein an outer blocking dielectric layer 44 contacts the first electrically conductive layer 461, laterally surrounds the layer contact via structure 86, and vertically extends continuously at least from a first horizontal plane HP1 including a bottommost surface of the at least one alternating stack (32, 46) and at least to a second horizontal plane HP2 including a topmost surface of the memory opening fill structure 58.

In one embodiment, the layer contact via structure 86 vertically extends continuously at least from the first horizontal plane HP1 and at least to the second horizontal plane HP2. In one embodiment, the layer contact via structure 86 comprises: an upper cylindrical portion 86U located above a horizontal plane including a topmost surface of the first electrically conductive layer 461; a lower cylindrical portion 86W located below a horizontal plane including a bottom surface of the first electrically conductive layer 461; and a laterally bulging portion 86G located between the upper cylindrical portion 86U and the lower cylindrical portion 86W and laterally protruding outward from a bottom periphery of the upper cylindrical portion 86U and from a top periphery of the lower cylindrical portion 86W.

In one embodiment the at least one alternating stack (32, 46) comprises a staircase region (e.g., portion of the inter-array region 200); and 86 the contact via structure vertically extends through the staircase region.

In one embodiment, the laterally bulging portion 86G includes the annular protrusion portion 86AP and a cylindrical portion, such that the annular protrusion portion 86AP may laterally protrude outward from the cylindrical portion contacts the cylindrical sidewall surface of the first electrically conductive layer 461.

In one embodiment, the laterally bulging portion 86G comprises a cylindrical sidewall 86S, an entirety of which is in direct contact with a cylindrical sidewall of an opening in the first electrically conductive layer 461 in the staircase region, and the contact via structure 86 extends through this opening. In one embodiment, the laterally bulging portion 86G also comprises: an upper annular horizontal surface segment 86X, an entirety of which is in contact with a first annular surface segment of the outer blocking dielectric layer 44; and a lower annular horizontal surface segment 86Y, an entirety of which is in contact with a second annular surface segment of the outer blocking dielectric layer 44.

In one embodiment, the first electrically conductive layer 461 has a first thickness t1 around the memory opening 49 outside the staircase region; and the first electrically conductive layer 461 has a second thickness t2 that is greater than the first thickness t1 in the staircase region around the layer contact via structure 86 that does not have an areal overlap with any overlying electrically conductive layer 46 within the at least one alternating stack (32, 46). In one embodiment, the laterally bulging portion 86G has a uniform thickness that equals the second thickness t2 or is greater than the second thickness, such as 0.1 to 20% greater than the first thickness.

In one embodiment, the layer contact via structure 86 comprises a contact-via metallic barrier liner 86B and a contact-via metal fill material portion 86F that is laterally surrounded by the contact-via metallic barrier liner 86B; and the cylindrical sidewall, the upper annular surface segment, and the lower annular surface segment of the laterally bulging portion 86G are surface segments of the contact-via metallic barrier liner 86B.

In one embodiment, the first electrically conductive layer 461 comprises a metal-line metallic barrier liner 46B and a metal-line metal fill material portion 46F that is embedded within the metal-line metallic barrier liner 46B; and the cylindrical sidewall of the laterally bulging portion 86G is in contact with the metal-line metallic barrier liner 46B and with the metal-line metal fill material portion 46F.

In one embodiment, the outer blocking dielectric layer 44 comprises: an upper tubular portion that contacts an entirety of a sidewall of the upper cylindrical portion 86U of the layer contact via structure 86; and a lower tubular portion that contacts an entirety of a sidewall of the lower cylindrical portion 86W of the layer contact via structure 86. In one embodiment, the device structure further comprises a vertical stack of annular dielectric spacers 26 located at levels of a subset of the electrically conductive layers 46 that underlies the first electrically conductive layer 461 and having a respective inner cylindrical sidewall that contacts the lower tubular portion of the outer blocking dielectric layer 44.

In one embodiment, the electrically conductive layers 46 within the at least one alternating stack (32, 46) has a first thickness t1 around the memory opening 49; and each of the annular dielectric spacers 26 within the vertical stack of annular dielectric spacers 26 has a vertical thickness that equals a sum of the first thickness t1 and twice a thickness of the outer blocking dielectric layer 44. In one embodiment, at least one retro-stepped dielectric material portion 65 overlies portions of the at least one alternating stack (32, 46) in the staircase region, and the upper tubular portion of the outer blocking dielectric layer 44 is in contact with a cylindrical sidewall of one of the at least one retro-stepped dielectric material portion 65.

In one embodiment, all portions of the outer blocking dielectric layer 44 in contact with the at least one alternating stack (32, 46) may be interconnected among one another such that the outer blocking dielectric layer of the device structure is a single continuous material layer contacting each insulating layer 32 and each electrically conductive layer 46 and each layer contact via structure 86.

In one embodiment, each layer contact via structure 86 may comprise a cylindrical portion that vertically extends at least from the first horizontal plane HP1 and at least to the second horizontal plane HP2 (e.g., to the horizontal plane including the top surface of the contact-level dielectric layer 80). The annular protrusion portion 86AP may laterally protrude outward from the cylindrical portion, and may contact the first electrically conductive layer 461 for the layer contact via structure 86. The height of the annular protrusion portion 86AP may be the same as the second thickness t2.

In one embodiment, the device structure may comprise a contact-level dielectric layer 80 overlying the at least one alternating stack (32, 46). A topmost surface of the layer contact via structure 86 and each topmost surface of the outer blocking dielectric layer 44 are located within a horizontal plane including a top surface of the contact-level dielectric layer 80.

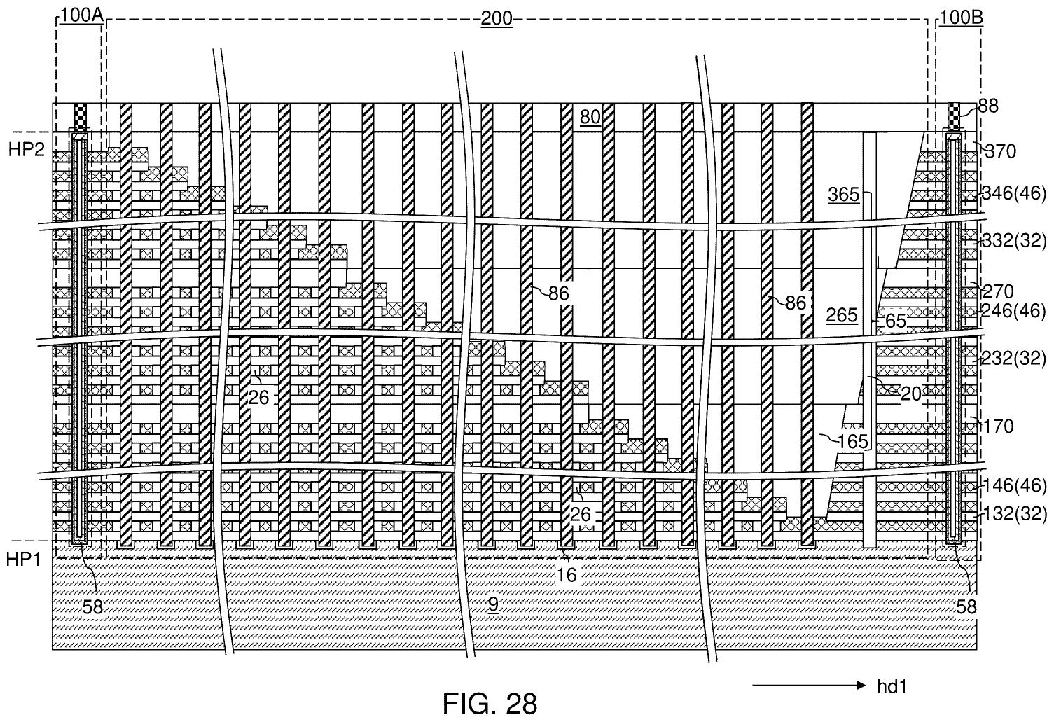

Referring to FIG. 28, additional dielectric material layers can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The dielectric material layers that are formed above the contact-level dielectric layer 80 are herein collectively referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In summary, the memory die 900 comprises a memory array (32, 46, 58), memory-side metal interconnect structures 980, and memory-side bonding pads 988 embedded within memory-side dielectric material layers 960. The memory array may comprise a three-dimensional memory array including an alternating stack of insulating layers 32 and electrically conductive layers 46, and further comprises a two-dimensional array of NAND strings (e.g., memory opening fill structures 58) vertically extending through the alternating stack (32, 46). In one embodiment, the electrically conductive layers 46 comprise word lines and select gate electrodes of the two-dimensional array of NAND strings. In one embodiment, the memory-side metal interconnect structures 980 comprise bit lines for the two-dimensional array of NAND strings.

Referring to FIG. 29, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900. Particularly, the peripheral circuit 720 comprises word line driver transistors configured to drive the word lines in the memory die 900.

The logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-die bonding process, or by a die-to-wafer bonding process. The logic-side bonding pads 788 within each logic die 700 can be bonded to the memory-side bonding pads 988 within a respective memory die 900.

The substrate 9 can be removed, for example, by grinding, polishing, cleaving, an isotropic etch process, an anisotropic etch process, and/or a combination thereof. In one embodiment, at least a terminal step of at least one removal process that is employed to remove the substrate 9 may comprise a selective wet etch process that etches the material of the substrate 9 (such as a semiconductor material of the substrate 9) selective to dielectric materials of the memory films 50. In an illustrative example, if the substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the substrate 9 can be removed by the selective wet etch process. Backside end surfaces of the support pillar structures 20 can be physically exposed upon removal of the substrate 9.

An end portion of each memory opening fill structure 58 can be removed. In one embodiment, an end portion of each memory film 50 may be removed by performing a sequence of wet etch processes. A horizontal end portion of each vertical semiconductor channel 60 may be physically exposed. In one embodiment, the sequence of wet etch processes may be selective to the material of the vertical semiconductor channels 60.

At least one source structure 2 (e.g., a source region and/or source line) can be formed in contact vertical semiconductor channels 60. The at least one source structure 2 may comprise a heavily doped semiconductor material and/or a metallic material (e.g., a metal and/or an electrically conductive metal nitride or silicide). A backside dielectric layer 4 and backside contact structures 6 can be subsequently formed.

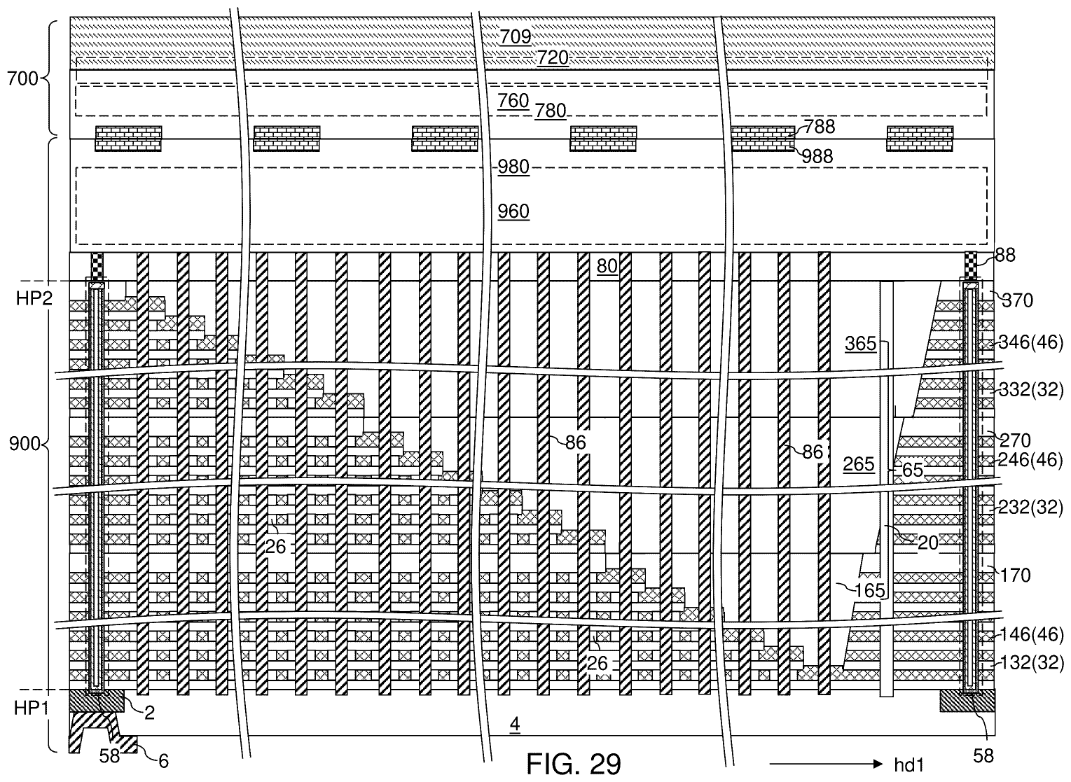

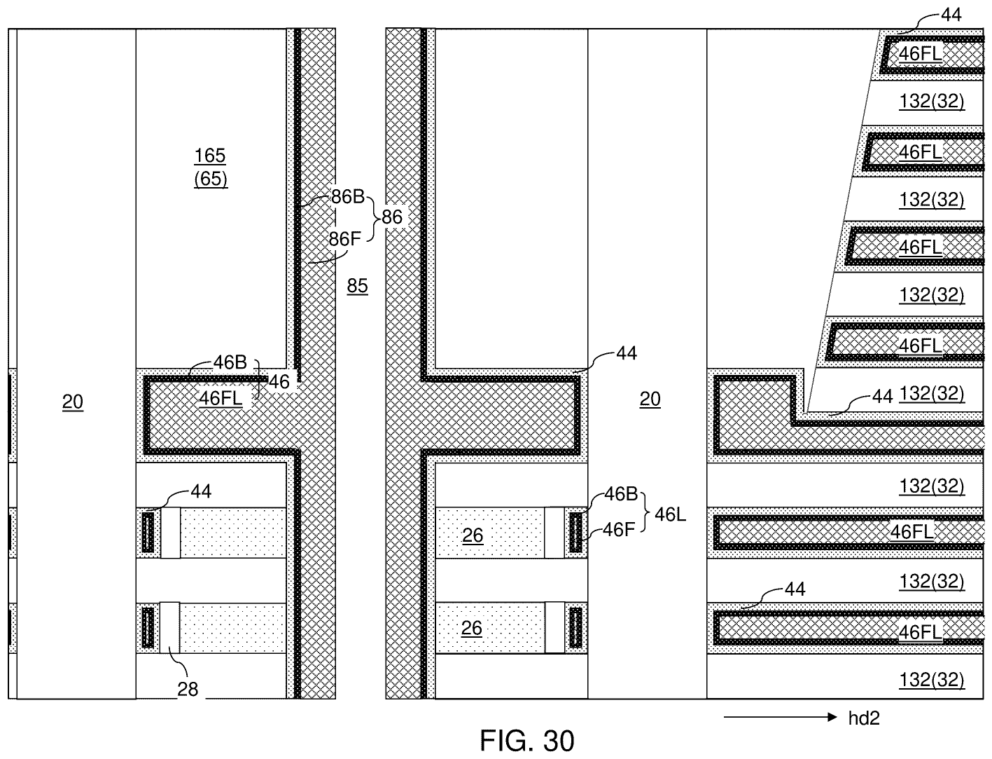

FIGS. 30, 31 and 32 are schematic vertical cross-sectional views steps of forming an alternative exemplary structure according to an alternative embodiment of the present disclosure. In the alternative embodiment, portions of the electrically conductive layers 46L are not removed from the contact via cavities 85, and instead remain to form the contact via structures 86.

The alternative exemplary structure of FIG. 30 is the same as the exemplary structure shown in FIG. 21C. However, the vertically extending portions of the electrically conductive layers 46L located in the contact via cavities 85 comprise the contact via structures 86.

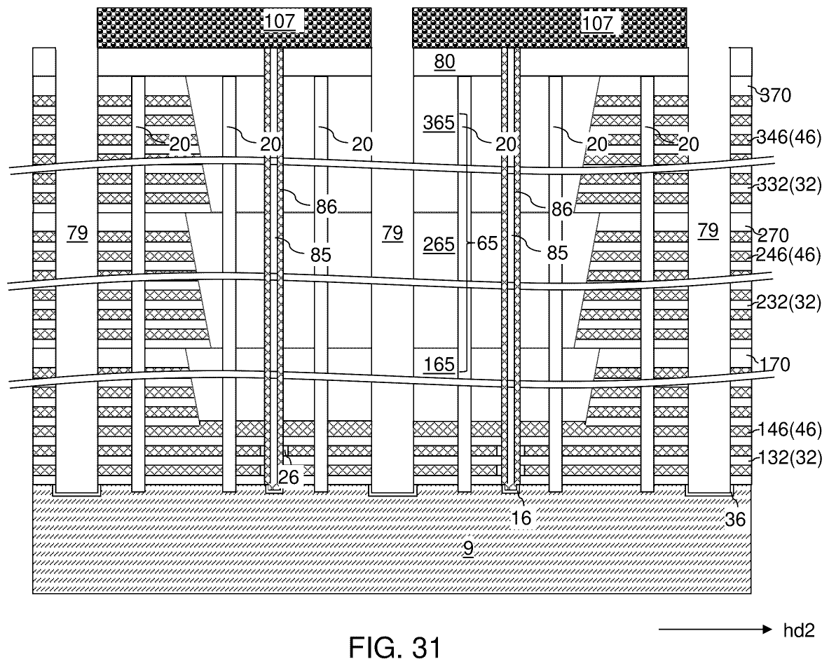

Referring to FIG. 31, a mask layer 107, such as a photoresist layer, is formed over the contact via cavities 85 which are at least partially filled with the contact via structures 86. The mask layer 107 is patterned to form openings over the lateral isolation trenches 79. The vertically extending portions of the electrically conductive layers 46L are removed from the lateral isolation trenches 79, as described above with respect to FIGS. 22A-22C.

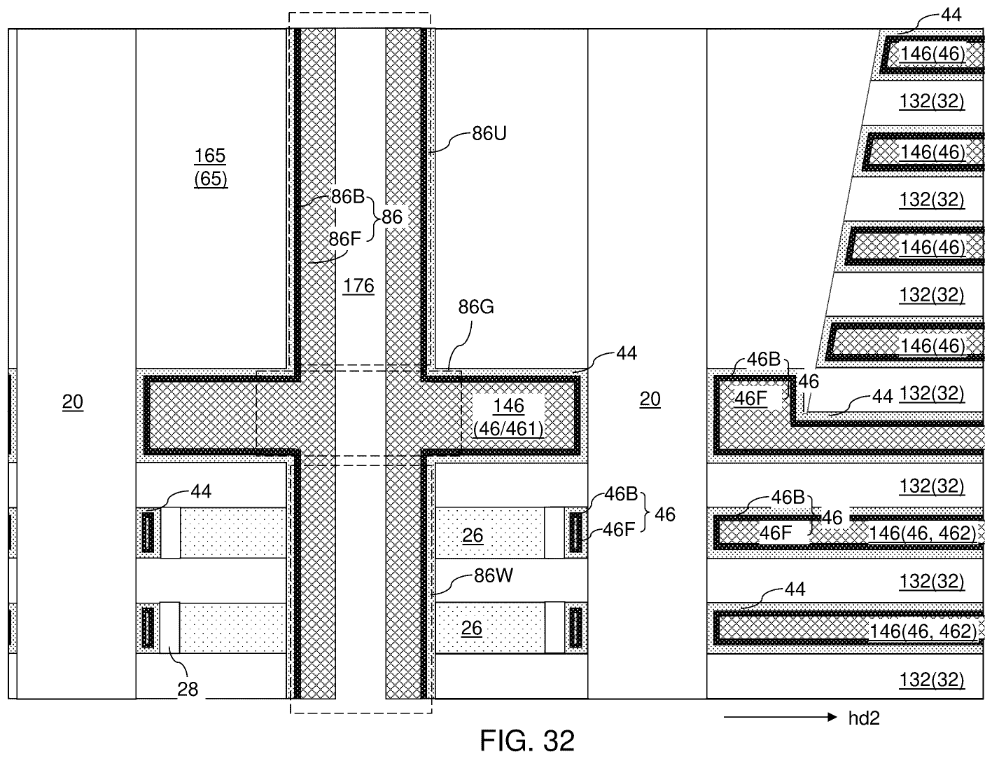

Referring to FIG. 32, the mask layer 107 is removed by selective etching or ashing to expose the contact via cavities 85 which are at least partially filled with the contact via structures 86. If voids are present in the central portions of the contact via cavities 85, then they are filled with dielectric pillars 176 which extend from the bottom to the top of the alternating stack (32, 46). The dielectric pillars 176 may be formed at the same time as the lateral isolation trench fill structures 76, and may comprise the same material (e.g., silicon oxide) as the lateral isolation trench fill structures 76. Alternatively, the voids in the central portions of the contact via cavities 85 can be filled with either a dielectric material or an electrically conductive material during a separate deposition step from the step that forms then lateral isolation trench fill structures 76.

In the alternative embodiment, each of the contact via structures 86 may comprise a hollow cylinder having a central portion that is filled with a respective dielectric pillar 176. The contact via structures 86 are continuous with the respective first electrically conductive layers 461, and there is no discernable boundary between the laterally bulging portion 86G of the respective contact via structure 86 with the respective first electrically conductive layer 461. In one embodiment, the contact via structure 86 comprises a contact-via metallic barrier liner 86B and a contact-via metal fill material portion 86F that is laterally surrounded by the contact-via metallic barrier liner, and the first electrically conductive layer 461 comprises a metal-line metallic barrier liner 46B and a metal-line metal fill material portion 46F that is embedded within the metal-line metallic barrier liner. The contact-via metal fill material portion 86F is continuous with the metal-line metal fill material portion 86F and there is no discernable boundary between them. This reduces the contact resistance between the respective contact via structure 86 and respective first electrically conductive layer 461. Thus, the lateral extent of the laterally bulging portion 86G in this alternative embodiment is arbitrary.

In another alternative embodiment, the electrically conductive layers 46L are simultaneously formed through lateral isolation trenches 79 and at least one additional opening. The at least one additional opening may comprise a support pillar cavity that is not filled with a support pillar structure 20 in addition to or instead of the contact via cavities 85.

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A device structure, comprising:
at least one alternating stack of insulating layers and electrically conductive layers,
a memory opening vertically extending through each layer within the at least one alternating stack;
a memory opening fill structure located in the memory opening and comprising a vertical stack of memory elements and a vertical semiconductor channel, wherein each of the electrically conductive layers is laterally spaced from the memory opening fill structure by an outer blocking dielectric layer; and
a contact via structure in contact with a first electrically conductive layer of the electrically conductive layers within the at least one alternating stack, wherein the outer blocking dielectric layer contacts the first electrically conductive layer, laterally surrounds the contact via structure, and vertically extends continuously at least from a first horizontal plane including a bottommost surface of the at least one alternating stack and at least to a second horizontal plane including a topmost surface of the memory opening fill structure.

2. The device structure of claim 1, wherein the contact via structure vertically extends continuously at least from the first horizontal plane and at least to the second horizontal plane.

3. The device structure of claim 1, wherein the contact via structure comprises:
an upper cylindrical portion located above a horizontal plane including a topmost surface of the first electrically conductive layer;
a lower cylindrical portion located below a horizontal plane including a bottom surface of the first electrically conductive layer; and
a laterally bulging portion located between the upper cylindrical portion and the lower cylindrical portion and laterally protruding outward from a bottom periphery of the upper cylindrical portion and from a top periphery of the lower cylindrical portion.

4. The device structure of claim 3, wherein:
the at least one alternating stack comprises a staircase region; and
the contact via structure vertically extends through the staircase region.

5. The device structure of claim 4, wherein:
the first electrically conductive layer has a first thickness around the memory opening outside the staircase region;
the first electrically conductive layer has a second thickness that is greater than the first thickness in the staircase region around the contact via structure that does not have an areal overlap with any overlying electrically conductive layer within the at least one alternating stack; and
the laterally bulging portion has a uniform thickness that equals the second thickness or is greater than the second thickness.

6. The device structure of claim 5, wherein the laterally bulging portion further comprises:
an upper annular surface segment, an entirety of which is in contact with a first annular surface segment of the outer blocking dielectric layer; and
a lower annular surface segment, an entirety of which is in contact with a second annular surface segment of the outer blocking dielectric layer.

7. The device structure of claim 4, wherein the outer blocking dielectric layer comprises:
an upper tubular portion that contacts an entirety of a sidewall of the upper cylindrical portion of the contact via structure; and
a lower tubular portion that contacts an entirety of a sidewall of the lower cylindrical portion of the contact via structure.

8. The device structure of claim 7, further comprising a vertical stack of annular dielectric spacers located at levels of a subset of the electrically conductive layers that underlies the first electrically conductive layer and having a respective inner cylindrical sidewall that contacts the lower tubular portion of the outer blocking dielectric layer.

9. The device structure of claim 8, wherein:
the electrically conductive layers within the at least one alternating stack have a first thickness around the memory opening; and
each of the annular dielectric spacers within the vertical stack of annular dielectric spacers has a vertical thickness that equals a sum of the first thickness and twice a thickness of the outer blocking dielectric layer.

10. The device structure of claim 7, further comprising at least one retro-stepped dielectric material portion overlies portions of the at least one alternating stack in the staircase region, wherein the upper tubular portion of the outer blocking dielectric layer is in contact with a cylindrical sidewall of one of the at least one retro-stepped dielectric material portion.

11. The device structure of claim 1, wherein the contact via structure is continuous with the first electrically conductive layer, and there is no discernable boundary between the contact via structure and the first electrically conductive layer.

12. The device structure of claim 11, wherein the contact via structure comprises a hollow cylinder having a central portion that is filled with a dielectric pillar.

13. The device structure of claim 11, wherein:
the contact via structure comprises a contact-via metallic barrier liner and a contact-via metal fill material portion that is laterally surrounded by the contact-via metallic barrier liner;
the first electrically conductive layer comprises a metal-line metallic barrier liner and a metal-line metal fill material portion that is embedded within the metal-line metallic barrier liner; and
the contact-via metal fill material portion is continuous with the metal-line metal fill material portion and there is no discernable boundary between them.

14. The device structure of claim 1, further comprising a contact-level dielectric layer overlying the at least one alternating stack, wherein a topmost surface of the contact via structure and a topmost surface of the outer blocking dielectric layer are located within a horizontal plane including a top surface of the contact-level dielectric layer.

15. A method of forming a device structure, comprising:
forming an alternating stack of insulating layers and sacrificial material layers over a substrate;
forming stepped surfaces by patterning the alternating stack in a staircase region;
forming a memory opening through the alternating stack;
forming a memory opening fill structure in the memory opening, wherein the memory opening fill structure comprises a vertical stack of memory elements and a vertical semiconductor channel;
forming a contact via cavity through the retro-stepped dielectric material portion and a subset of the sacrificial material layers within the alternating stack, wherein the subset of the sacrificial material layers comprises a first sacrificial material layer which is a topmost sacrificial material layer of the subset of the sacrificial material layers and further comprises second sacrificial material layers that underlie the first sacrificial material layer;
forming lateral isolation trenches through the alternating stack;
replacing the sacrificial material layers with replacement material portions that comprise electrically conductive layers employing both the lateral isolation trenches and at least one additional opening as conduits for an etchant that removes the sacrificial material layers and as conduits for a reactant that deposits the electrically conductive layers, wherein a first electrically conductive layer is formed in a volume of the first sacrificial material layer; and
forming a contact via structure in the contact via cavity in contact with the first electrically conductive layer.

16. The method of claim 15, wherein:
the at least one additional opening comprises at least one of the contact via cavity or a support pillar cavity;
lateral recesses are formed in volumes from which the sacrificial material layers are removed; and
the method further comprises forming an outer blocking dielectric layer in peripheral portions of the lateral recesses, the lateral isolation trenches and the contact via cavity, wherein the outer blocking dielectric layer extends horizontally from a cylindrical surface segment of a sidewall of the memory opening fill structure to the contact via cavity and extends vertically from a first horizontal plane including a bottommost surface of the alternating stack to a second horizontal plane including a top surface of the memory opening fill structure.

17. The method of claim 16, wherein:
the at least one additional opening comprises the contact via cavity; and
the method further comprises:
forming a retro-stepped dielectric material portion overlying the stepped surfaces in the staircase region;
performing a conformal deposition process that deposits at least one first electrically conductive material in remaining volumes of the lateral recesses and in a tubular peripheral region of the contact via cavity and the lateral isolation trenches after forming the outer blocking dielectric layer; and
removing a portion of the at least one first electrically conductive material from the peripheral region of the lateral isolation trenches, wherein remaining portions of the at least one first electrically conductive material comprise the first electrically conductive layer and the contact via structure.

18. The method of claim 15, further comprising forming a vertical stack of annular dielectric spacers around the contact via cavity at each level of the second sacrificial material layers.

19. The method of claim 18, further comprising locally thickening physically exposed portions of the sacrificial material layers after formation of the stepped surfaces, wherein the contact via cavity is formed through a locally thickened portion of the first sacrificial material layer.

20. The method of claim 19, further comprising:
isotropically recessing the subset of the sacrificial material layers around the contact via cavity by performing a first isotropic recess etch process;
forming sacrificial annular plates within first annular recess regions at levels of the second sacrificial material layers;
forming an etch-stop annular plate within a second annular recess at a level of the first sacrificial material layer;
forming third annular recess regions by performing a second isotropic recess etch process, wherein the second isotropic recess etch process removes the sacrificial annular plates and isotropically recesses proximal portions of the second sacrificial material layers without removing the etch-stop annular plate or the insulating layers;
filling the third annular recess regions with a recess-fill dielectric material to form the vertical stack of annular dielectric spacers is formed; and
forming lateral isolation trench fill structures in the lateral isolation trenches.
